(19) United States
(12) Patent Application Publication
(10) Pub. No.: US 2025/0386587 A1
(43) Pub. Date: Dec. 18, 2025

(54) SEMICONDUCTOR DEVICE

(71) Applicant: FUJI ELECTRIC CO., LTD., Kanagawa (JP)

(72) Inventor: Motoyoshi KUBOUCHI, Matsumoto-city (JP)

(21) Appl. No.: 19/218,336

(22) Filed: May 25, 2025

(30) Foreign Application Priority Data
Jun. 17, 2024 (JP) 2024-097189

(51) Int. Cl. H10D 84/00; H10D 12/00; H10D 64/27

(52) U.S. Cl. CPC H10D 84/161; H10D 12/481; H10D 64/27

(57) ABSTRACT

Provided is a semiconductor device including: an emitter electrode which is provided above an upper surface of a semiconductor substrate; and a first active gate runner which is provided above the upper surface of the semiconductor substrate so as to be sandwiched between the emitter electrodes and extend in a first direction, in which the first active gate runner includes two or more separation parts arranged with at least one spacing portion sandwiched therebetween in the first direction, the emitter electrode includes a bridge portion arranged in the spacing portion, and at least one of trench portions provided in a diode portion extends below the bridge portion.

The contents of the following patent application(s) are incorporated herein by reference:
NO. 2024-097189 filed in JP on Jun. 17, 2024.

### BACKGROUND

### 1. Technical Field

The present invention relates to a semiconductor device.

### 2. Related Art

Conventionally, a semiconductor device such as an IGBT is known (see, for example, Patent Documents 1 and 2).
Patent Document 1: Japanese Patent Application Publication No. 2019-068036
Patent Document 2: International Publication No. 2020/189053

The summary clause does not necessarily describe all necessary features of the embodiments of the present invention. In addition, the present invention may also be a sub-combination of the features described above.

### BRIEF DESCRIPTION OF THE DRAWINGS

FIG. 1 is a top view illustrating an example of a semiconductor device 100 according to one embodiment of the present invention.

FIG. 2 is an enlarged view of a region A in FIG. 1.

FIG. 3 is a view illustrating an example of a cross section e-e in FIG. 2.

FIG. 4 is an enlarged view of a region B in FIG. 1.

FIG. 5 is a view illustrating an example of a cross section h-h in FIG. 4.

FIG. 6 is a view illustrating another example of the cross section h-h.

FIG. 7 is a view illustrating another example of the cross section h-h.

FIG. 8 is a view illustrating an arrangement example of a gate pad 164, a first metal gate runner 131, and a spacing portion 170.

FIG. 9 is a view illustrating another arrangement example of the gate pad 164, the first metal gate runner 131, and the spacing portion 170.

FIG. 10 is a view illustrating another arrangement example of the gate pad 164, the first metal gate runner 131, and the spacing portion 170.

FIG. 11 is a view illustrating another arrangement example of the gate pad 164, the first metal gate runner 131, and the spacing portion 170.

FIG. 12 is a view illustrating another arrangement example of the gate pad 164, the first metal gate runner 131, and the spacing portion 170.

FIG. 13 is a view illustrating another arrangement example of the gate pad 164, the first metal gate runner 131, and the spacing portion 170.

FIG. 14 is a view illustrating another structure example of the region B.

FIG. 15 is a view illustrating another structure example of the region B.

FIG. 16 is a view illustrating another structure example of the region B.

FIG. 17 is a view illustrating a region C and a region D in the semiconductor device 100.

FIG. 18 is an enlarged view of the region C in FIG. 17.

FIG. 19 is a view illustrating an example of a cross section f-f in FIG. 18.

FIG. 20 is a view illustrating another structure example of the region C.

FIG. 21 is a view illustrating a structure example of the region D.

FIG. 22 is a view illustrating another structure example of the region D.

FIG. 23 is a view illustrating another structure example of the region D.

FIG. 24 is a view illustrating another structure example of the region D.

FIG. 25 is a view illustrating another structure example of the region D.

FIG. 26 is a view illustrating another structure example of the region D.

FIG. 27 is a view illustrating another structure example of the region D.

FIG. 28 is a view illustrating another structure example of the region D.

FIG. 29 is a view illustrating another structure example of the region D.

FIG. 30 is a view illustrating a structure example of a region where a trench bottom region 201 can be provided and a first active gate runner.

FIG. 31 is a view illustrating another structure example of the region where the trench bottom region 201 can be provided and the first active gate runner.

FIG. 32 is a view illustrating another structure example of the region where the trench bottom region 201 can be provided and the first active gate runner.

FIG. 33 is a view illustrating another structure example of the region where the trench bottom region 201 can be provided and the first active gate runner.

FIG. 34 is a view illustrating another structure example of the region C.

FIG. 35 is a view illustrating an example of a cross section g-g in FIG. 34.

FIG. 36 is a view illustrating another structure example of the region C.

FIG. 37 is a view illustrating another structure example of the region D.

FIG. 38 is a view illustrating another structure example of the region D.

FIG. 39 is a view illustrating another structure example of the region D.

FIG. 40 is a view illustrating another structure example of the region D.

FIG. 41 is a view illustrating another structure example of the region D.

FIG. 42 is a view illustrating another structure example of the region D.

FIG. 43 is a view illustrating another structure example of the region D.

FIG. 44 is a view illustrating another structure example of the region D.

FIG. 45 is a view illustrating another structure example of the region D.

FIG. 46 is a view illustrating another structure example of the region D.

FIG. 47 is a view illustrating another structure example of the region where the trench bottom region 201 can be provided and the first active gate runner.

FIG. 48 is a view illustrating another structure example of the region where the trench bottom region 201 can be provided and the first active gate runner.

FIG. 49 is a view illustrating another structure example of the region where the trench bottom region 201 can be provided and the first active gate runner.

FIG. 50 is a view illustrating another structure example of the region where the trench bottom region 201 can be provided and the first active gate runner.

FIG. 51 is a view illustrating another structure example of the region where the trench bottom region 201 can be provided and the first active gate runner.

FIG. 52 is a view illustrating another structure example of the region where the trench bottom region 201 can be provided and the first active gate runner.

FIG. 53A is a view illustrating another connection example of the trench bottom region 201.

FIG. 53B is a view illustrating another connection example of the trench bottom region 201.

FIG. 53C is a view illustrating another connection example of the trench bottom region 201.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to a ground. Note that a +Z axis direction and a −Z axis direction are directions opposite to each other. When a Z axis direction is described without describing signs, it means that the direction is parallel to a +Z axis and a −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. As used herein, a direction of the Z axis may be referred to as the depth direction. In addition, as used herein, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. As used herein, the impurities may particularly mean either a donor of the N type or an acceptor of the P type, and may be described as a dopant. As used herein, the doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. As used herein, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}. As used herein, the net doping concentration may be simply described as the doping concentration.

The donor has a function of supplying electrons to the semiconductor. The acceptor has a function of receiving electrons from the semiconductor. The donor and acceptor are not limited to the impurities themselves. For example, a VOH defect in which a vacancy (V), oxygen (O), and hydrogen (H) present in the semiconductor are attached together functions as the donor which supplies electrons. A hydrogen donor may be a donor obtained by combination of at least a vacancy (V) and hydrogen (H). Alternatively, interstitial Si—H in which interstitial silicon (Si-i) in a silicon semiconductor is attached to hydrogen, and CiOi-H in which interstitial carbon (Ci) is attached to interstitial oxygen (Oi) and hydrogen also function as a donor which supplies electrons. In the present specification, the VOH defect, the CiOi-H, or the interstitial Si—H may be referred to as the hydrogen donor.

In the semiconductor substrate in the present specification, bulk donors of the N type are distributed throughout. The bulk donor is a dopant donor substantially uniformly contained in an ingot during manufacturing of the ingot from which the semiconductor substrate is made. The bulk donor in the present example is an element other than hydrogen. A dopant of the bulk donor is, for example, phosphorous, antimony, arsenic, selenium, or sulfur, but is not limited to these. The bulk donor in the present example is phosphorous. The bulk donor is also contained in a region of the P type. The semiconductor substrate may be a wafer cut out from a semiconductor ingot, or may be a chip obtained by singulating the wafer. The semiconductor ingot may be manufactured by any one of a Czochralski method (CZ method), a magnetic field applied Czochralski method (MCZ method), or a float zone method (FZ method). The ingot in the present example is manufactured by the MCZ method. The substrate manufactured by the MCZ method has an oxygen concentration of 1×10¹⁷ to 7×10¹⁷/cm³. The substrate manufactured by the FZ method has an oxygen concentration of 1×10¹⁵ to 5×10¹⁶/cm³. When the oxygen concentration is high, the hydrogen donor tends to be easily generated. A bulk donor concentration may use a chemical concentration of the bulk donors distributed throughout the semiconductor substrate, or may be a value between 90% and 100% of the chemical concentration. In addition, as the semiconductor substrate, a non-doped substrate not containing a dopant such as phosphorous may be used. In that case, a bulk donor concentration (DO) of the non-doped substrate is, for example, from 1×10¹⁰/cm³ or more and to 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Note that each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. In addition, as used herein, a description of a P++ type or an N++ type means a higher doping concentration than that of the P+ type or the N+ type. As used herein, a unit system is an SI unit system unless otherwise noted. Although a unit of a length may be expressed in cm, various calculations may be performed after conversion to meters (m).

In the present specification, the chemical concentration refers to an atomic density of impurities measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be defined as the donor concentration. Similarly, in a region of the P type, the carrier concentration of the region may be defined as the acceptor concentration. As used herein, the doping concentration of the region of the N type may be referred to as the donor concentration, and the doping concentration of the region of the P type may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor, or net doping is substantially uniform in a region, or the like, an average value of the concentration of the donor, acceptor, or net doping in the region may be defined as the concentration of the donor, acceptor, or net doping. In the present specification, atoms/cm³ or/cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. A decrease in carrier mobility occurs when carriers are scattered due to disorder of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron serving as an acceptor is about 99% of chemical concentrations of these. On the other hand, in the silicon semiconductor, a donor concentration of hydrogen serving as a donor is about 0.1% to 10% of a chemical concentration of hydrogen. The semiconductor substrate may be silicon, silicon carbide, gallium nitride, diamond, or gallium oxide.

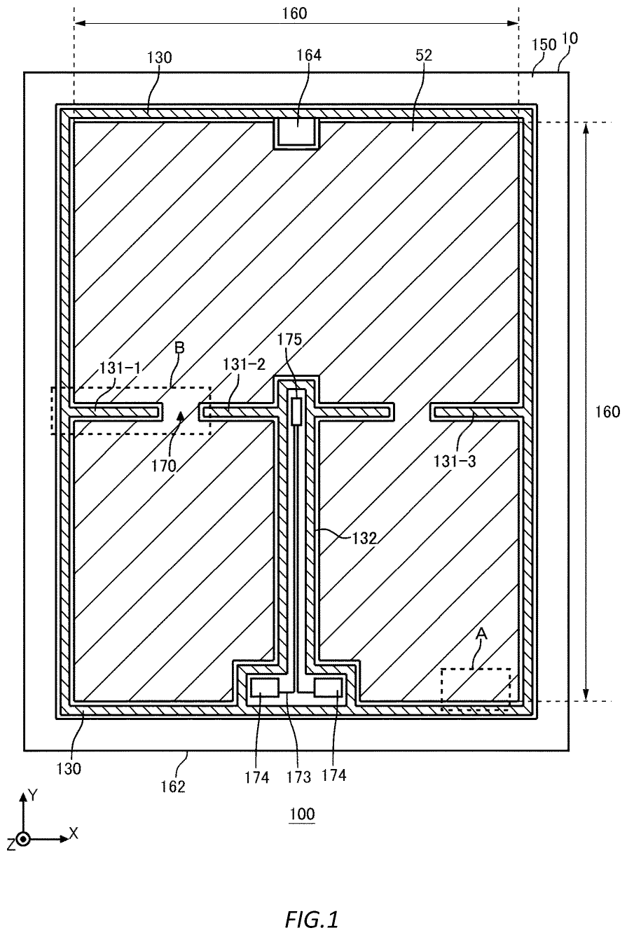

FIG. 1 is a top view illustrating an example of a semiconductor device 100 according to one embodiment of the present invention. FIG. 1 illustrates a position at which each member is projected on an upper surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in top view. When merely referred to as the top view in the present specification, it means that the semiconductor substrate 10 is viewed from an upper surface side. The semiconductor substrate 10 in the present example has two sets of end sides 162 facing each other in top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region through which a main current flows in the depth direction between the upper surface and a lower surface of the semiconductor substrate 10 when the semiconductor device 100 operates. An emitter electrode 52 is provided above the active portion 160. The active portion 160 may refer to a region which overlaps the emitter electrode 52 in top view. In addition, a region sandwiched between the emitter electrodes 52 in top view may also be included in the active portion 160. In FIG. 1, a region where the emitter electrode 52 is provided is indicated by low-density hatching.

The active portion 160 is provided with at least one of a transistor portion or a diode portion. The transistor portion includes a transistor element such as an insulated gate bipolar transistor (IGBT). The diode portion includes a diode element such as a freewheeling diode (FWD). The active portion 160 may be provided with both the transistor portion and the diode portion.

In the active portion 160, the transistor portions and the diode portions may be alternately arranged along a predetermined array direction (for example, an X axis direction) at the upper surface of the semiconductor substrate 10. The semiconductor device 100 of the present example is a reverse conducting IGBT (RC-IGBT). The transistor portion and the diode portion of the present example are connected in antiparallel to each other. That is, an emitter of a transistor portion 70 and an anode of a diode portion 80 are electrically connected, and a collector of the transistor portion 70 and a cathode of the diode portion 80 are electrically connected.

In the present specification, a direction perpendicular to the array direction in top view may be referred to as an extending direction (a Y axis direction in FIG. 1). Each of the transistor portion and the diode portion may have a longitudinal length in the extending direction. That is, a length of the transistor portion in the Y axis direction is larger than its width thereof in the X axis direction. Similarly, a length of the diode portion in the Y axis direction is larger than its width in the X axis direction. The extending direction of the transistor portion and the diode portion may be the same as a longitudinal direction or the extending direction of each trench portion described below.

The diode portion has a cathode region of the N+ type in a region in contact with the lower surface of the semiconductor substrate 10. In the present specification, a region where the cathode region is arranged is referred to as a diode portion. At the lower surface of the semiconductor substrate 10, a collector region of the P type may be provided in a region other than the diode portion.

The transistor portion has a collector region of the P type in a region in contact with the lower surface of the semiconductor substrate 10. In addition, in the transistor portion, an emitter region of the N type, a base region of the P type, and a gate structure including a gate conductive portion and a gate dielectric film are periodically arranged on the upper surface side of the semiconductor substrate 10.

The semiconductor device 100 may include one or more pads above the semiconductor substrate 10. The semiconductor device 100 of the present example includes a gate pad 164. The semiconductor device 100 may include a pad such as a temperature sense pad 174 or a current detection pad. Each pad is arranged in a vicinity of the end side 162. The vicinity of the end side 162 refers to a region between the end side 162 and the emitter electrode 52 in top view. When the semiconductor device 100 is mounted, each pad and the emitter electrode 52 may be connected to an external circuit via wirings such as a lead frame or a wire.

A gate potential is applied to the gate pad 164. The gate pad 164 is electrically connected to a conductive portion of a gate trench portion of the active portion 160. The semiconductor device 100 includes a gate runner which connects the gate pad 164 and the gate trench portion. In FIG. 1, the gate runner is hatched with oblique lines having a relatively high density.

The gate runner of the present example includes an outer circumferential gate runner 130, a first metal gate runner 131, and a second active gate runner 132. The outer circumferential gate runner 130 is arranged between the active portion 160 and the end side 162 of the semiconductor substrate 10 in top view. The outer circumferential gate runner 130 of the present example surrounds the active portion 160 in top view. A region surrounded by the outer circumferential gate runner 130 in top view may be the active portion 160. In addition, a ground well region is formed below the outer circumferential gate runner 130. The ground well region is a region of the P type having a higher concentration than a base region described below, and is formed from the upper surface of the semiconductor substrate 10 to a position deeper than the base region. A region surrounded by the ground well region in top view may be the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like, or a polysilicon wiring, or may be a laminated wiring in which these wirings are laminated.

The first metal gate runner 131 is arranged to be sandwiched between the emitter electrodes 52 in top view. The first metal gate runner 131 is an example of a first active gate runner provided in the active portion 160. The first metal gate runner 131 may be formed of a same material as that of the emitter electrode 52, or may be formed of a different material therefrom. The first metal gate runner 131 may contain aluminum. At least a part of the first metal gate runner 131 may be arranged at a same height as that of the emitter electrode 52. The first metal gate runner 131 is provided to extend in a first direction (the X axis direction in the present example). The first metal gate runner 131 may have a longitudinal length in the X axis direction. By providing the first metal gate runner 131 in the active portion 160, a variation in a gate runner length from the gate pad 164 is reduced for each region of the active portion 160, whereby variations in an attenuation amount and a delay amount of a gate signal can be reduced.

The second active gate runner 132 is electrically connected to the gate pad 164. The second active gate runner 132 of the present example is connected to the gate pad 164 via the outer circumferential gate runner 130. The second active gate runner 132 may be a metal wiring containing aluminum or the like, or a polysilicon wiring, or may be a laminated wiring in which these wirings are laminated. Note that the second active gate runner 132 may not be provided.

The second active gate runner 132 is provided above an upper surface 21 of the semiconductor substrate 10. The second active gate runner 132 is arranged to be sandwiched between the emitter electrodes 52 in top view. In the present specification, for example, when it is described that a first member is sandwiched between second members or the first member is between the second members, another member may be interposed between the first member and the second member. At least a part of the second active gate runner 132 of the present example is provided between a temperature sense wiring 173 and the emitter electrode 52.

The second active gate runner 132 includes a part provided to extend in a second direction intersecting the first direction. The second direction may be a direction orthogonal to the first direction. In the present example, the Y axis direction is defined as the second direction, but the second direction may not be the Y axis direction. The second active gate runner 132 of the present example may include a part provided in parallel with the temperature sense wiring 173.

The first metal gate runner 131 of the present example includes a plurality of separation parts discretely provided along the X axis direction. In the example of FIG. 1, a first metal gate runner 131-1, a first metal gate runner 131-2, and a first metal gate runner 131-3 correspond to the plurality of separation parts discretely provided. Any separation part of the first metal gate runner 131 is connected to at least one of the outer circumferential gate runner 130 or the second active gate runner 132. With this configuration, a gate potential can be applied to any separation part of the first metal gate runner 131 via the outer circumferential gate runner 130 or the second active gate runner 132. The outer circumferential gate runner 130, the first metal gate runner 131, and the second active gate runner 132 may be connected to the gate trench portion of the active portion 160.

Among a plurality of the first metal gate runners 131 discretely arranged along the X axis direction, two first metal gate runners 131-1 and 131-3 arranged at both ends may be connected to the outer circumferential gate runner 130. The first metal gate runner 131-2 arranged at a position other than both ends may be connected to the second active gate runner 132. As described above, the second active gate runner 132 may not be provided, but by providing the second active gate runner 132, a gate signal to the first metal gate runner 131-2 can be quickly transmitted with low resistance.

The first metal gate runners 131 of the present example are discretely provided along the X axis direction so as to cross the active portion 160 at substantially a center in the Y axis direction. When the active portion 160 is divided in the Y axis direction by the first metal gate runner 131 as in the present example, the transistor portions and the diode portions may be alternately arranged in the X axis direction in each divided region.

A part sandwiched between two first metal gate runners 131 aligned in the X axis direction is referred to as a spacing portion 170. The spacing portion 170 in the present example is provided with the emitter electrode 52. The emitter electrode 52 provided in the spacing portion 170 may be referred to as a bridge portion. The bridge portion connects two emitter electrodes 52 divided in the Y axis direction by the first metal gate runner 131. By providing the bridge portion, it is possible to suppress a variation in potential in an upper surface of the emitter electrode 52.

The semiconductor device 100 may include a temperature sense portion 175, the temperature sense wiring 173, and the temperature sense pad 174. The temperature sense portion 175 may be a PN junction diode formed of polysilicon or the like. The temperature sense portion 175 is arranged above the upper surface of the semiconductor substrate 10. The temperature sense portion 175 may be provided in the active portion 160.

The temperature sense wiring 173 is a wiring which connects the temperature sense portion 175 and the temperature sense pad 174. The temperature sense wiring 173 may be a metal wiring containing aluminum or the like, or a polysilicon wiring, or may be a laminated wiring in which these wirings are laminated. The temperature sense wiring 173 of the present example has a part extending from the temperature sense portion 175 in the Y axis direction. The temperature sense wiring 173 and the temperature sense pad 174 may be provided for each of an anode and a cathode of the temperature sense portion 175. The second active gate runner 132 may be provided on one side or both sides of the temperature sense wiring 173 in the X axis direction.

The semiconductor device 100 of the present example includes an edge termination structure portion 150 between the active portion 160 and the end side 162 in top view. The edge termination structure portion 150 of the present example is arranged between the outer circumferential gate runner 130 and the end side 162. The edge termination structure portion 150 reduces an electric field strength on the upper surface side of the semiconductor substrate 10. The edge termination structure portion 150 may include at least one of a guard ring, a field plate, or a RESURF which is annularly provided to enclose the active portion 160.

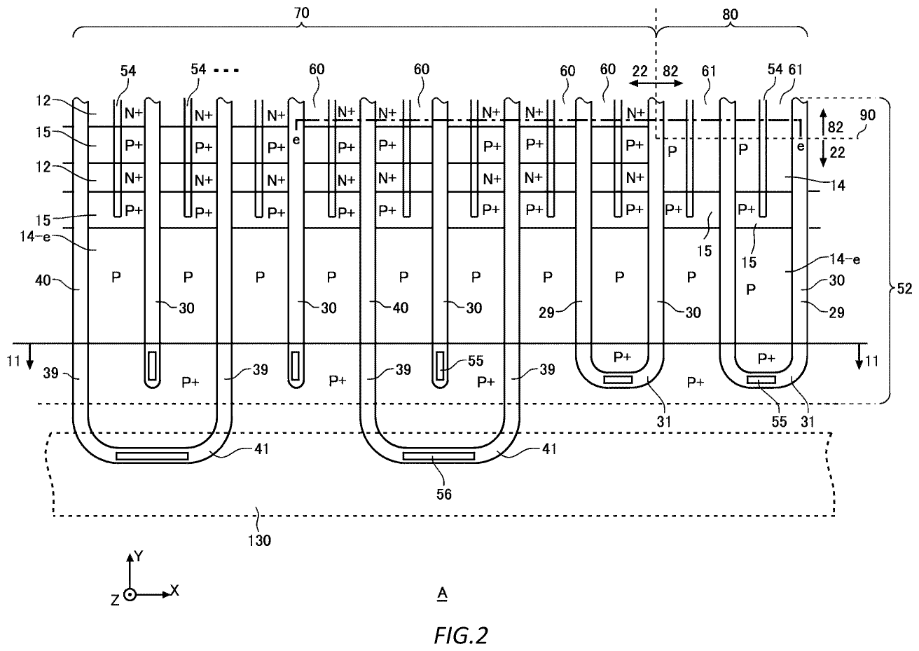

FIG. 2 is an enlarged view of a region A in FIG. 1. The region A is a region including the transistor portion 70, the diode portion 80, and the outer circumferential gate runner 130 extending in the X axis direction. The semiconductor device 100 of the present example includes a gate trench portion 40, a dummy trench portion 30, a ground well region 11, an emitter region 12, a base region 14, and a contact region 15 which are provided inside the upper surface side of the semiconductor substrate 10. Each of the gate trench portion 40 and the dummy trench portion 30 is an example of the trench portion. In addition, the emitter electrode 52 and the outer circumferential gate runner 130 are provided above the upper surface of the semiconductor substrate 10. The emitter electrode 52 and the outer circumferential gate runner 130 are provided separately from each other.

An interlayer dielectric film is provided between the emitter electrode 52 and the outer circumferential gate runner 130, and the upper surface of the semiconductor substrate 10, but illustration of the interlayer dielectric film is omitted in FIG. 2. In the interlayer dielectric film of the present example, a contact hole 54, a contact hole 55, and a contact hole 56 are provided to penetrate the interlayer dielectric film. Each contact hole is filled with a conductive material. The contact hole 54 connects a mesa portion described below and the emitter electrode 52. The contact hole 55 connects the dummy trench portion 30 and the emitter electrode 52. The contact hole 56 connects the gate trench portion 40 and the gate runner such as the outer circumferential gate runner 130.

The emitter electrode 52 is provided above the gate trench portion 40, the dummy trench portion 30, the ground well region 11, the emitter region 12, the base region 14, and the contact region 15. The emitter electrode 52 is in contact with the emitter region 12, the contact region 15, and the base region 14 at the upper surface of the semiconductor substrate 10 through the contact hole 54. In addition, the emitter electrode 52 is connected to a dummy conductive portion in the dummy trench portion 30 through the contact hole 55 provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and the gate conductive portion, or may be controlled to a potential different from a potential of the emitter electrode 52 and a potential of the gate conductive portion.

The outer circumferential gate runner 130 is connected to the gate trench portion 40 through the contact hole 56 provided in the interlayer dielectric film. The outer circumferential gate runner 130 may be connected to the gate conductive portion of the gate trench portion 40 at an edge portion 41 of the gate trench portion 40 in the Y axis direction. The outer circumferential gate runner 130 is not connected to the dummy conductive portion in the dummy trench portion 30. When each electrode or wiring is connected to the conductive portion of each trench portion, a connection portion formed of polysilicon may be provided between the electrode or wiring and the conductive portion. In each drawing of the present specification, illustration of the connection portion is omitted. The outer circumferential gate runner 130 of the present example is a metal wiring, and is insulated from the emitter electrode 52. The outer circumferential gate runner 130 of the present example may be formed using the same material as that of the emitter electrode 52.

The emitter electrode 52 is formed of a material containing metal. FIG. 2 illustrates a range where the emitter electrode 52 is provided. For example, at least a partial region of the emitter electrode 52 is formed of aluminum or an aluminum-silicon alloy, for example, a metal alloy such as AlSi or AlSiCu, copper, or the like. The emitter electrode 52 may have a barrier metal formed of titanium, tantalum, nickel, cobalt, a compound thereof, or the like in a lower layer of the region formed of aluminum or the like. Furthermore, the emitter electrode 52 may have, in the contact hole, a plug, which is formed by embedding tungsten, copper, or the like so as to be in contact with the barrier metal, aluminum, or the like. In addition, in the emitter electrode 52, nickel, gold, or the like may be laminated in an upper layer of the region formed of aluminum or the like.

The ground well region 11 is provided to overlap the outer circumferential gate runner 130. The ground well region 11 is provided to extend with a predetermined width also in a range not overlapping the outer circumferential gate runner 130. The ground well region 11 of the present example is provided apart from an end of the contact hole 54 in the Y axis direction toward the outer circumferential gate runner 130. The ground well region 11 is a region of a second conductivity type which has a higher doping concentration than the base region 14. The base region 14 in the present example is the P type, and the ground well region 11 is the P+ type. The ground well region 11 may be electrically connected to the emitter electrode 52. The ground well region 11 may be in contact with the emitter electrode 52, or may be connected to the emitter electrode 52 via the base region 14 or the like.

Each of the transistor portion 70 and the diode portion 80 has a plurality of trench portions arrayed in the array direction. In the transistor portion 70 of the present example, one or more gate trench portions 40 and one or more dummy trench portions 30 are alternately provided along the array direction. In the diode portion 80 of the present example, a plurality of dummy trench portions 30 is provided along the array direction. The diode portion 80 of the present example is not provided with the gate trench portion 40.

The gate trench portion 40 of the present example may include two linear parts 39 extending along an extending direction perpendicular to the array direction (trench parts which are linear along the extending direction), and the edge portion 41 connecting the two linear parts 39. The extending direction in FIG. 2 is the Y axis direction.

At least a part of the edge portion 41 is preferably provided in a curved shape in top view. By the edge portion 41 connecting end portions of two linear parts 39 in the Y axis direction to each other, it is possible to reduce the electric field strength at the end portions of the linear parts 39.

In the transistor portion 70, the dummy trench portions 30 are provided in spaces between the linear parts 39 of the gate trench portions 40. In a space between the linear parts 39, one dummy trench portion 30 may be provided or a plurality of dummy trench portions 30 may be provided. The dummy trench portion 30 may have a linear shape extending in an extending direction, or may have a linear part 29 and an edge portion 31 similarly to the gate trench portion 40. The semiconductor device 100 illustrated in FIG. 2 includes both the linear dummy trench portion 30 not having the edge portion 31 and the dummy trench portion 30 having the edge portion 31.

A diffusion depth of the ground well region 11 may be deeper than depths of the gate trench portion 40 and the dummy trench portion 30. End portions of the gate trench portion 40 and the dummy trench portion 30 in the Y axis direction are provided in the ground well region 11 in top view. That is, a bottom portion of each trench portion in the depth direction is covered with the ground well region 11 at an end portion of each trench portion in the Y axis direction. With this configuration, the electric field strength at the bottom portion of each trench portion can be reduced.

The mesa portion is provided between the trench portions in the array direction. The mesa portion refers to a region sandwiched between the trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion of the present example is provided in the upper surface of the semiconductor substrate 10, so as to extend in the extending direction (Y axis direction) along the trench. In the present example, the transistor portion 70 is provided with a mesa portion 60, and the diode portion 80 is provided with a mesa portion 61. When merely referred to as the mesa portion in the present specification, it may refer to each of the mesa portion 60 and the mesa portion 61.

The base region 14 is provided in each mesa portion. In the base region 14 exposed on the upper surface of the semiconductor substrate 10 in the mesa portion, a region arranged closest to the gate runner is defined as a base region 14-e. In FIG. 2, the base region 14-e arranged at one end portion of each mesa portion in the extending direction is illustrated, but the base region 14-e is also arranged at another end portion of each mesa portion. In each mesa portion, a region sandwiched between the base regions 14-e in top view may be provided with at least one of the emitter region 12 of the first conductivity type or the contact region 15 of the second conductivity type. The emitter region 12 of the present example is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 includes the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact regions 15 and the emitter regions 12 of the mesa portion 60 are alternately arranged along the extending direction of the trench portion (Y axis direction).

In another example, the contact region 15 and the emitter region 12 of the mesa portion 60 may be provided in a stripe shape along the extending direction of the trench portion (Y axis direction). For example, the emitter region 12 is provided in a region in contact with the trench portion, and the contact region 15 is provided in a region sandwiched between the emitter regions 12.

The emitter region 12 is not provided in the mesa portion 61 of the diode portion 80. The base region 14 and the contact region 15 may be provided in an upper surface of the mesa portion 61. In a region sandwiched between the base regions 14-e at the upper surface of the mesa portion 61, the contact region 15 may be provided in contact with each of the base regions 14-e. In a region sandwiched between the contact regions 15 at the upper surface of the mesa portion 61, the base region 14 may be provided. The base region 14 may be arranged in an entire region sandwiched between the contact regions 15.

The contact hole 54 is provided above each mesa portion. The contact hole 54 is arranged in a region sandwiched between the base regions 14-e. The contact hole 54 of the present example is provided above respective regions of the contact region 15, the base region 14, and the emitter region 12. In the diode portion 80, the contact region 15 may not be provided. The contact hole 54 is not provided in regions corresponding to the base region 14-e and the ground well region 11. The contact hole 54 may be arranged at a center of the mesa portion 60 in the array direction (X axis direction).

In the diode portion 80, a cathode region 82 is provided in a region adjacent to the lower surface of the semiconductor substrate 10. At the lower surface of the semiconductor substrate 10, a collector region 22 of the P type may be provided in a region where the cathode region 82 is not provided. The cathode region 82 and the collector region 22 are provided between a lower surface 23 of the semiconductor substrate 10 and a buffer region described below. The cathode region 82 and the collector region 22 may be in contact with the lower surface 23 of the semiconductor substrate 10.

The cathode region 82 is arranged apart from the ground well region 11 in the Y axis direction. With this configuration, a distance between a region of the P type (ground well region 11) having a relatively high doping concentration and formed up to a deep position and the cathode region 82 of the N+ type can be secured to improve a breakdown voltage. An end portion of the cathode region 82 of the present example in the Y axis direction is arranged farther from the ground well region 11 than an end portion of the contact hole 54 in the Y axis direction. In another example, the end portion of the cathode region 82 in the Y axis direction may be arranged between the ground well region 11 and the contact hole 54.

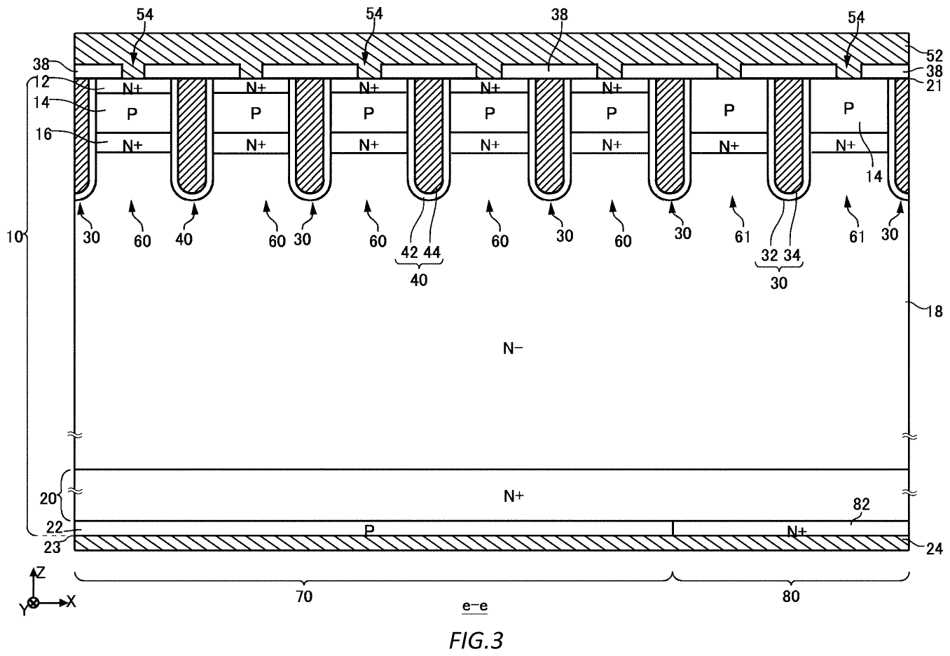

FIG. 3 is a view illustrating an example of a cross section e-e in FIG. 2. The cross section e-e is an XZ plane passing through the emitter region 12 and the cathode region 82. In the cross section, the semiconductor device 100 of the present example includes the semiconductor substrate 10, an interlayer dielectric film 38, the emitter electrode 52, and a collector electrode 24.

The interlayer dielectric film 38 is provided on the upper surface of the semiconductor substrate 10. The interlayer dielectric film 38 is a film including at least one layer of a dielectric film such as silicate glass to which impurities such as boron or phosphorous are added, a thermal oxide film, or other dielectric films. The interlayer dielectric film 38 is provided with the contact hole 54 described with reference to FIG. 2.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided on the lower surface 23 of the semiconductor substrate 10. The emitter electrode 52 and the collector electrode 24 are formed of a metal material such as aluminum. In the present specification, a direction in which the emitter electrode 52 is connected to the collector electrode 24 (Z axis direction) is referred to as the depth direction.

The semiconductor substrate 10 includes a drift region 18 of the N type or the N-type. The drift region 18 is provided in each of the transistor portion 70 and the diode portion 80.

In the mesa portion 60 of the transistor portion 70, the emitter region 12 of the N+ type and the base region 14 of the P type are provided in order from the upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed on the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of the present example is provided in contact with the emitter region 12. The base region 14 may be in contact with the trench portions on both sides of the mesa portion 60.

The accumulation region 16 is provided below the base region 14. The accumulation region 16 is a region of the N+ type having a higher doping concentration than the drift region 18. That is, the accumulation region 16 has a higher donor concentration than the drift region 18. Providing the accumulation region 16, which has a high concentration, between the drift region 18 and the base region 14 can increase a carrier implantation enhancement effect (IE effect) and reduce an on-voltage. The accumulation region 16 may be provided so as to cover an entire lower surface of the base region 14 in each mesa portion 60.

The mesa portion 61 of the diode portion 80 is provided with the base region 14 of the P type in contact with the upper surface 21 of the semiconductor substrate 10. The base region 14 of the diode portion 80 functions as an anode region of the diode portion 80. The drift region 18 is provided below the base region 14. In the mesa portion 61, the accumulation region 16 may be provided below the base region 14. The accumulation region 16 may not be provided in the mesa portion 61.

In each of the transistor portion 70 and the diode portion 80, a buffer region 20 of the N+ type may be provided below the drift region 18. A doping concentration of the buffer region 20 is higher than the doping concentration of the drift region 18. The buffer region 20 may have a concentration peak having a higher doping concentration than the drift region 18. A doping concentration at a concentration peak refers to a doping concentration at a local maximum of the concentration peak. In addition, as the doping concentration of the drift region 18, an average value of doping concentrations in a region where doping concentration distribution is substantially flat may be used.

The buffer region 20 may have two or more concentration peaks in the depth direction (Z axis direction) of the semiconductor substrate 10. The concentration peak of the buffer region 20 may be provided at a same depth position as a chemical concentration peak of hydrogen (proton) or phosphorous, for example. The buffer region 20 may function as a field stop layer which prevents a depletion layer widening from a lower end of the base region 14 from reaching the collector region 22 and the cathode region 82.

In the transistor portion 70, the collector region 22 of the P type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

In the diode portion 80, the cathode region 82 of the N+ type is provided below the buffer region 20. A donor concentration of the cathode region 82 is higher than a donor concentration of the drift region 18. A donor of the cathode region 82 is, for example, arsenic, hydrogen, or phosphorous. Note that an element serving as a donor and an acceptor in each region is not limited to the example described above.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion is provided from the upper surface 21 of the semiconductor substrate 10 to a region below the base region 14, penetrating the base region 14. In a region where at least any of the emitter region 12, the contact region 15, or the accumulation region 16 is provided, each trench portion also penetrates the doping regions of these. A configuration in which the trench portion penetrates the doping region is not limited to a configuration which is manufactured by forming the doping region and forming the trench portion in this order. The configuration in which the trench portion penetrates the doping region includes a configuration in which the trench portions are formed and then the doping region is formed between the trench portions.

As described above, the transistor portion 70 is provided with the gate trench portion 40 and the dummy trench portion 30. The diode portion 80 is provided with the dummy trench portion 30 and is not provided with the gate trench portion 40.

The gate trench portion 40 includes a gate trench provided in the upper surface 21 of the semiconductor substrate 10, a gate dielectric film 42, and a gate conductive portion 44. The gate dielectric film 42 is provided to cover an inner wall of the gate trench. The gate dielectric film 42 may be formed by oxidizing or nitriding a semiconductor at the inner wall of the gate trench. The gate conductive portion 44 is provided farther inward than the gate dielectric film 42 inside the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered with the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portion 30 may have a same structure as the gate trench portion 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided to cover an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of a same material as the gate conductive portion 44. For example, the dummy conductive portion 34 is formed of a conductive material such as polysilicon. The dummy conductive portion 34 may have a same length as the gate conductive portion 44 in the depth direction.

The gate trench portion 40 and the dummy trench portion 30 of the present example are covered with the interlayer dielectric film 38 on the upper surface 21 of the semiconductor substrate 10. Note that the bottom portions of the dummy trench portion 30 and the gate trench portion 40 may be formed in a curved-surface shape (a curved shape in the cross section) convexly downward.

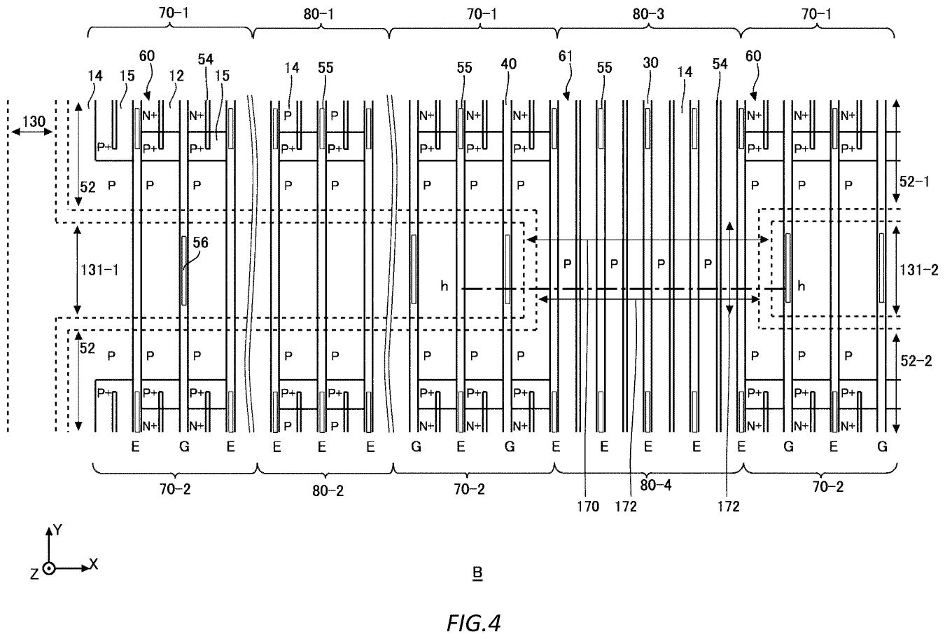

FIG. 4 is an enlarged view of a region B in FIG. 1. The region B includes the spacing portion 170 and the outer circumferential gate runner 130. In addition, the first metal gate runner 131-1 and the first metal gate runner 131-2 are arranged with the spacing portion 170 sandwiched therebetween in the X axis direction. The first metal gate runner 131-1 is connected to the outer circumferential gate runner 130.

The active portion 160 illustrated in FIG. 1 is divided in the Y axis direction by a plurality of first metal gate runners 131 and the spacing portion 170 aligned in the X axis direction. The first metal gate runner 131 and the spacing portion 170 are sandwiched between the transistor portions 70 or the diode portions 80 in the Y axis direction. In the example of FIG. 4, the first metal gate runners 131-1 and 131-2 are sandwiched between a transistor portion 70-1 and a transistor portion 70-2, and between a diode portion 80-1 and a diode portion 80-2. In addition, the spacing portion 170 is sandwiched between a diode portion 80-3 and a diode portion 80-4. The transistor portions 70-1 and the diode portions 80-1 are alternately arranged to be aligned in the X axis direction. In addition, the transistor portions 70-2 and the diode portions 80-2 are alternately arranged to be aligned in the X axis direction. A structure of each of the transistor portion 70 and the diode portion 80 is similar to that of any of the examples described with reference to FIGS. 2 and 3. In FIG. 4, one diode portion 80-3 (alternatively, one diode portion 80-4) is aligned between the two transistor portions 70-1 (alternatively, two transistor portions 70-2) in the X axis direction, but the diode portion 80-3 or 80-4 may be in contact with the diode portion 80-1 or 80-2, respectively.

The emitter electrode 52 is provided above each of the transistor portion 70 and the diode portion 80. The emitter electrode 52 is also divided in the Y axis direction by a plurality of first metal gate runners 131 and the spacing portion 170 aligned in the X axis direction. An emitter electrode 52-1 is arranged above the transistor portion 70-1 and the diode portions 80-1 and 80-3, and an emitter electrode 52-2 is arranged above the transistor portion 70-2 and the diode portions 80-2 and 80-4.

The first metal gate runner 131, the outer circumferential gate runner 130, and the emitter electrode 52 are arranged so as not to overlap each other in top view. Upper surfaces of the first metal gate runner 131, the outer circumferential gate runner 130, and respective electrodes of the emitter electrode 52 may be arranged at a same height. In FIG. 4, the first metal gate runner 131, the outer circumferential gate runner 130, and the emitter electrode 52 are indicated by broken lines.

The emitter electrode 52 is provided to extend above the spacing portion 170. The emitter electrode 52 above the spacing portion 170 is referred to as a bridge portion 172. A part of the emitter electrode 52 sandwiched between the first metal gate runners 131 in the X axis direction is referred to as a bridge portion 172. In FIG. 4, a range of the bridge portion 172 is indicated by an arrow. A length of the bridge portion 172 in the Y axis direction may be the same as a length of the first metal gate runner 131 in the Y axis direction.

The bridge portion 172 connects the emitter electrode 52-1 and the emitter electrode 52-2. By providing the bridge portion 172, two emitter electrodes 52 divided by the first metal gate runner 131 are connected, whereby the variation in potential in the emitter electrode 52 can be suppressed.

At least one of the trench portions provided in the diode portion 80-3 and the diode portion 80-4 extends below the bridge portion 172. In the present example, among the dummy trench portions 30 provided in the diode portion 80-3 and the diode portion 80-4, the dummy trench portion 30 opposing the spacing portion 170 in the Y axis direction extends below the bridge portion 172. In the example of FIG. 4, all the dummy trench portions 30 of the diode portion 80-3 and the diode portion 80-4 extend below the bridge portion 172.

At least one trench portion provided in the diode portion 80-3 may pass below the bridge portion 172 and be connected to the trench portion of the diode portion 80-4. In the present example, at least one dummy trench portion 30 provided in the diode portion 80-3 is connected to any dummy trench portion 30 of the diode portion 80-4. With such a configuration, the common dummy trench portion 30 can be provided in the diode portion 80-3 and the diode portion 80-4, and it is possible to suppress the variation in potential in the dummy trench portion 30 in the diode portion 80-3 and the diode portion 80-4. In the present example, among the dummy trench portions 30 provided in the diode portion 80-3, the dummy trench portion 30 opposing the spacing portion 170 in the Y axis direction passes below the bridge portion 172 and is connected to the dummy trench portion 30 of the diode portion 80-4. In the example of FIG. 4, all the dummy trench portions 30 of the diode portion 80-3 are connected to the dummy trench portions 30 of the diode portion 80-4.

The dummy conductive portion 34 of at least one dummy trench portion 30 may be connected to the bridge portion 172 at a position overlapping the bridge portion 172. In this case, the contact hole 55 is provided in the interlayer dielectric film 38 at a position overlapping the bridge portion 172 and the dummy conductive portion 34.

At least one of the mesa portions 61 provided in the diode portion 80-3 and the diode portion 80-4 may extend below the bridge portion 172. In the present example, among the mesa portions 61 provided in the diode portion 80-3 and the diode portion 80-4, the mesa portion 61 opposing the spacing portion 170 in the Y axis direction extends below the bridge portion 172. In the example of FIG. 4, all the mesa portions 61 of the diode portion 80-3 and the diode portion 80-4 extend below the bridge portion 172. In addition, the trench portion (the dummy trench portion 30 in the present example) and the mesa portion 61 extend below the bridge portion 172, so that potential distribution in the bridge portion 172 can be made continuous, and a local increase in electric field intensity distribution can be suppressed.

At least one mesa portion 61 provided in the diode portion 80-3 may pass below the bridge portion 172 and be connected to the mesa portion 61 of the diode portion 80-4. That is, the mesa portion 61 may also be provided below the bridge portion 172. The base region 14 functioning as an anode region may also be provided in the mesa portion 61 below the bridge portion 172. That is, the diode portion 80 may also be provided below the bridge portion 172. With this configuration, the diode portion 80 can be expanded.

In the present example, among the mesa portions 61 provided in the diode portion 80-3, the mesa portion 61 opposing the spacing portion 170 in the Y axis direction passes below the bridge portion 172 and is connected to the mesa portion 61 of the diode portion 80-4. In the example of FIG. 4, all the mesa portions 61 of the diode portion 80-3 are connected to the mesa portions 61 of the diode portion 80-4. With this configuration, the diode portion 80 can be further expanded. Widths of the diode portion 80-3 and the diode portion 80-4 in the X axis direction may be the same as, smaller than, or larger than the width of the spacing portion 170 in the X axis direction.

The interlayer dielectric film 38 (see FIG. 3) of the mesa portion 61 is provided with the contact hole 54 for connecting the mesa portion 61 and the emitter electrode 52. At least one of the contact holes 54 provided in the mesa portion 61 may extend below the bridge portion 172. In the present example, the contact hole 54 of the mesa portion 61, which opposes the spacing portion 170 in the Y axis direction, among the mesa portions 61 provided in the diode portion 80-3 and the diode portion 80-4 extends below the bridge portion 172. In the example of FIG. 4, the contact holes 54 of all the mesa portions 61 of the diode portion 80-3 and the diode portion 80-4 extend below the bridge portion 172.

The contact hole 54 of at least one mesa portion 61 provided in the diode portion 80-3 may pass below the bridge portion 172 and be connected to the contact hole 54 of the mesa portion 61 of the diode portion 80-4. That is, the contact hole 54 may also be provided in the interlayer dielectric film 38 below the bridge portion 172.

In the spacing portion 170 of another example, the ground well region 11 may be provided instead of the base region 14. The dummy trench portion 30 may also be provided in the spacing portion 170 in this case. The dummy trench portion 30 may penetrate the ground well region 11 in the Y axis direction and may be provided from the diode portion 80-3 to the diode portion 80-4. The ground well region 11 may also be provided below the first metal gate runner 131. The ground well region 11 may be continuously provided so as to cross the active portion 160 in the X axis direction.

At least one of the trench portions provided in the transistor portion 70-1 and the transistor portion 70-2 may extend below the first metal gate runner 131-1. In the present example, the transistor portion 70-1 and the transistor portion 70-2 provided on both sides of the first metal gate runner 131-1 will be described, but the transistor portion 70-1 and the transistor portion 70-2 provided on both sides of the first metal gate runner 131-2 also have a similar structure.

In the present example, some or all of the gate trench portions 40 provided in the transistor portion 70-1 and the transistor portion 70-2 extend below the first metal gate runner 131-1. The gate trench portion 40 may be provided from the transistor portion 70-1 to the transistor portion 70-2 so as to pass below the first metal gate runner 131-1. The gate trench portion 40 may be connected to the first metal gate runner 131-1 via the contact hole 56.

Some or all of the dummy trench portions 30 provided in the transistor portion 70-1 and the transistor portion 70-2 may extend below the first metal gate runner 131-1. The dummy trench portion 30 may be provided from the transistor portion 70-1 to the transistor portion 70-2 so as to pass below the first metal gate runner 131-1. The dummy trench portion 30 is not connected to the first metal gate runner 131-1.

Some or all of the mesa portions 60 provided in the transistor portion 70-1 and the transistor portion 70-2 may extend below the first metal gate runner 131-1. The base region 14 may be provided in the mesa portion 60 below the first metal gate runner 131-1, or the ground well region 11 may be provided therein. The emitter region 12 may not be provided in the mesa portion 60 below the first metal gate runner 131-1.

The mesa portion 60 below the first metal gate runner 131-1 is not connected to the first metal gate runner 131-1. That is, the contact hole 54 is not provided in the interlayer dielectric film 38 below the first metal gate runner 131-1. The contact hole 54 of the transistor portion 70-1 and the contact hole 54 of the transistor portion 70-2 are separated from each other at least below the first metal gate runner 131-1.

At least one of the trench portions provided in the diode portion 80-1 and the diode portion 80-2 may extend below the first metal gate runner 131-1. In the present example, the diode portion 80-1 and the diode portion 80-2 provided on both sides of the first metal gate runner 131-1 will be described, but the diode portion 80-1 and the diode portion 80-2 provided on both sides of the first metal gate runner 131-2 also have a similar structure.

Some or all of the dummy trench portions 30 provided in the diode portion 80-1 and the diode portion 80-2 may extend below the first metal gate runner 131-1. The dummy trench portion 30 may be provided from the diode portion 80-1 to the diode portion 80-2 so as to pass below the first metal gate runner 131-1. The dummy trench portion 30 is not connected to the first metal gate runner 131-1.

Some or all of the mesa portions 61 provided in the diode portion 80-1 and the diode portion 80-2 may extend below the first metal gate runner 131-1. The base region 14 may be provided in the mesa portion 61 below the first metal gate runner 131-1, or the ground well region 11 may be provided therein.

The mesa portion 61 below the first metal gate runner 131-1 is not connected to the first metal gate runner 131-1. That is, the contact hole 54 is not provided in the interlayer dielectric film 38 below the first metal gate runner 131-1. The contact hole 54 of the diode portion 80-1 and the contact hole 54 of the diode portion 80-2 are separated from each other at least below the first metal gate runner 131-1.

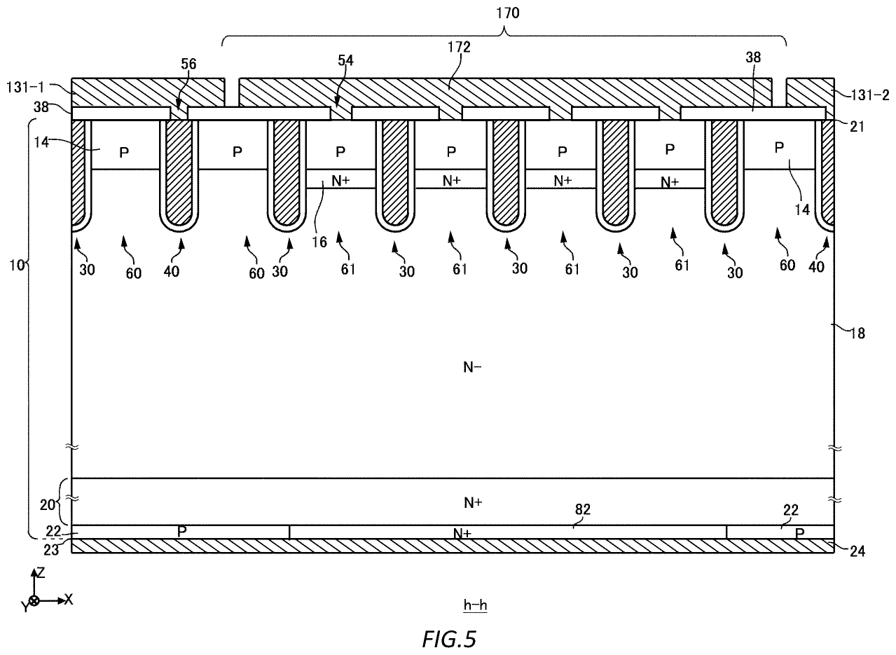

FIG. 5 is a view illustrating an example of a cross section h-h in FIG. 4. The cross section h-h is the XZ plane passing through a part of the first metal gate runner 131-1, the bridge portion 172, and a part of the first metal gate runner 131-2.

The first metal gate runner 131-1, the bridge portion 172, and the first metal gate runner 131-2 are provided separately from each other above the interlayer dielectric film 38. The first metal gate runner 131-1 and the first metal gate runner 131-2 may be connected to the gate conductive portion 44 (see FIG. 3) of the gate trench portion 40 via the contact hole 56.

The base region 14 may be provided in the mesa portion 61 overlapping the bridge portion 172. The bridge portion 172 may be connected to the base region 14 of the mesa portion 61 via the contact hole 54. A barrier metal including a titanium film, a titanium nitride film, or the like may be formed in each contact hole provided in the interlayer dielectric film 38, or a plug formed of tungsten or the like may be provided therein. Alternatively, the contact hole 54 may extend from the upper surface 21 toward the lower surface 23 of the semiconductor substrate 10, and a trench contact portion in which a plug is formed inside the extended contact hole 54 may be further included.

The cathode region 82 may be provided in a part overlapping the bridge portion 172 in a region in contact with the lower surface 23 of the semiconductor substrate 10. With such a configuration, the diode portion 80 can also be formed below the bridge portion 172, and a region of the diode portion 80 can be expanded. The cathode region 82 may be provided below each mesa portion 61 connected to the bridge portion 172 via the contact hole 54. The collector region 22 may be provided in a part overlapping the first metal gate runner 131 in the region in contact with the lower surface 23 of the semiconductor substrate 10. Alternatively, the collector region 22 may be provided to extend in the part overlapping the bridge portion 172 in the region in contact with the lower surface 23 of the semiconductor substrate 10.

A conductive member such as a wiring or an electrode electrically connected to the gate pad 164 is not provided below the bridge portion 172 of the present example. For example, a gate runner made of polysilicon or metal is not provided between the bridge portion 172 and the upper surface 21 of the semiconductor substrate 10. In the present example, no other conductive member is provided between the bridge portion 172 and the upper surface 21 of the semiconductor substrate 10. A conductive member having a gate potential is not provided inside the semiconductor substrate 10 below the bridge portion 172. As described above, the dummy trench portion 30 is provided below the bridge portion 172.

According to the present example, no gate potential wiring or the like is provided below the bridge portion 172. Therefore, a flatness of a surface forming the bridge portion 172 can be improved. Therefore, the semiconductor device 100 can be easily formed with finer detail. In addition, no other wiring may be provided also between the first metal gate runner 131 and the semiconductor substrate 10. With this configuration, the flatness can be further improved.

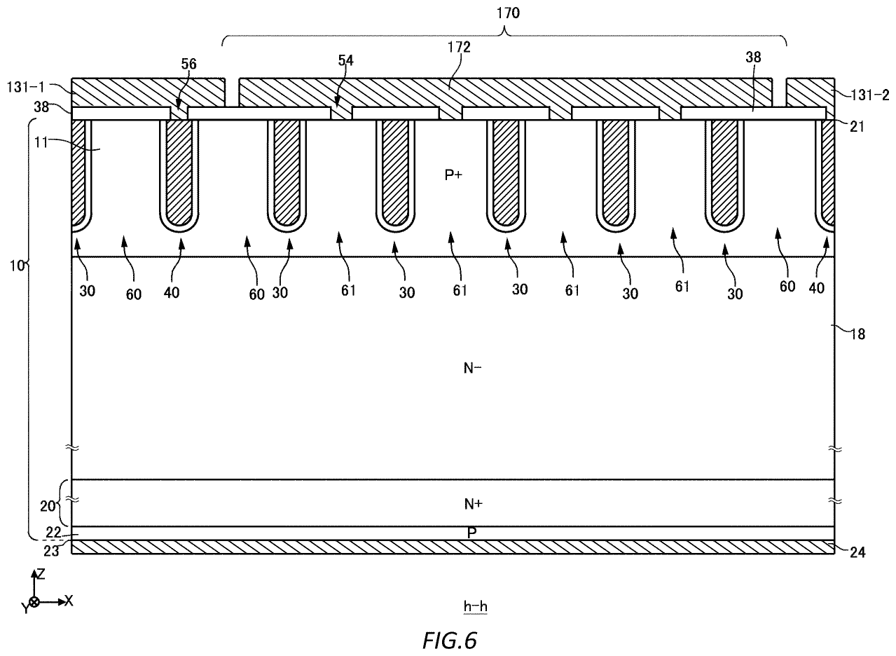

FIG. 6 is a view illustrating another example of the cross section h-h. In the present example, the ground well region 11 is provided below the first metal gate runner 131-1, the bridge portion 172, and the first metal gate runner 131-2. The ground well region 11 is provided from the upper surface 21 of the semiconductor substrate 10 to a depth greater than that of the lower end of the trench portion.

In each mesa portion in the cross section, the ground well region 11 is provided, and the base region 14 is not provided. In addition, the collector region 22 may be provided in a part overlapping the first metal gate runner 131-1, the bridge portion 172, and the first metal gate runner 131-2 in the region in contact with the lower surface 23 of the semiconductor substrate 10.

In the present example, the region of the diode portion 80 is not expanded. However, the dummy trench portions 30 of the diode portion 80-3 and the diode portion 80-4 are connected. Therefore, it is possible to reduce the variation in potential in the dummy trench portion 30. In addition, also in the transistor portion 70-1 and the transistor portion 70-2, the trench portions are connected. Therefore, it is possible to reduce the variation in potential in each trench portion. In addition, the ground well region 11 can reduce the electric field strength at the lower end of each trench portion.

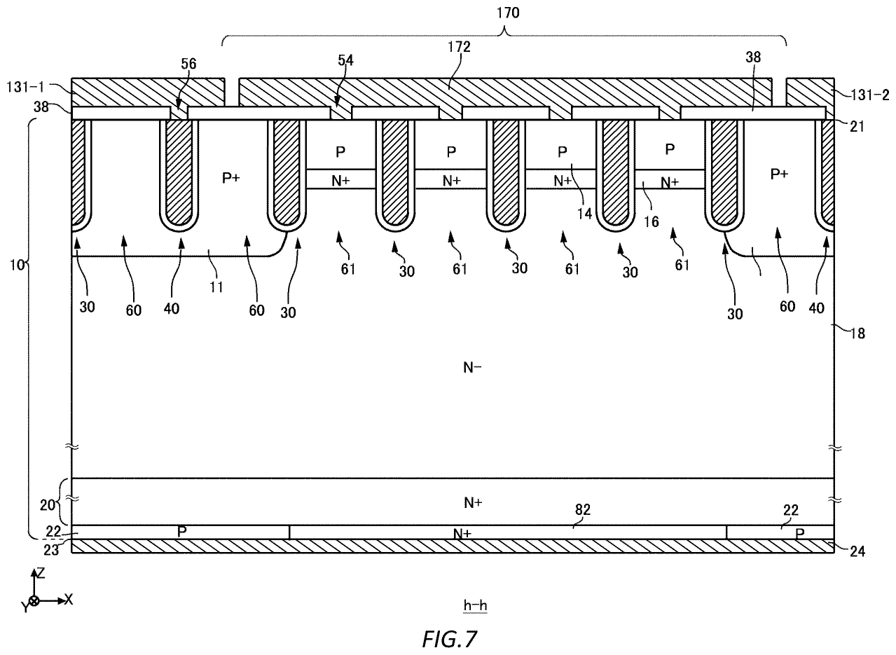

FIG. 7 is a view illustrating another example of the cross section h-h. In the present example, the ground well region 11 is provided below the first metal gate runner 131-1 and the first metal gate runner 131-2. The ground well region 11 may be provided in a range wider than the first metal gate runner 131-1 and the first metal gate runner 131-2 in the X axis direction. A part of the ground well region 11 may be provided below the bridge portion 172. The ground well region 11 may be provided in a range wider than the first metal gate runner 131-1 and the first metal gate runner 131-2 in the Y axis direction.

The base region 14 may be provided in the mesa portion 61 overlapping the bridge portion 172. The bridge portion 172 may be connected to the base region 14 of the mesa portion 61 via the contact hole 54. The cathode region 82 may be provided in the part overlapping the bridge portion 172 in the region in contact with the lower surface 23 of the semiconductor substrate 10. Also in the present example, the region of the diode portion 80 can be expanded. In addition, providing the ground well region 11 can reduce the electric field strength at the lower end of each trench portion. In order to suppress a parasitic diode operation between the ground well region 11 and the cathode region 82, in a region overlapping the first metal gate runner 131-1 and the first metal gate runner 131-2, the ground well region 11 may be separated from the bridge portion 172 to form the base region 14. Alternatively, the collector region 22 may be provided to extend in the part overlapping the bridge portion 172 in the region in contact with the lower surface 23 of the semiconductor substrate 10.

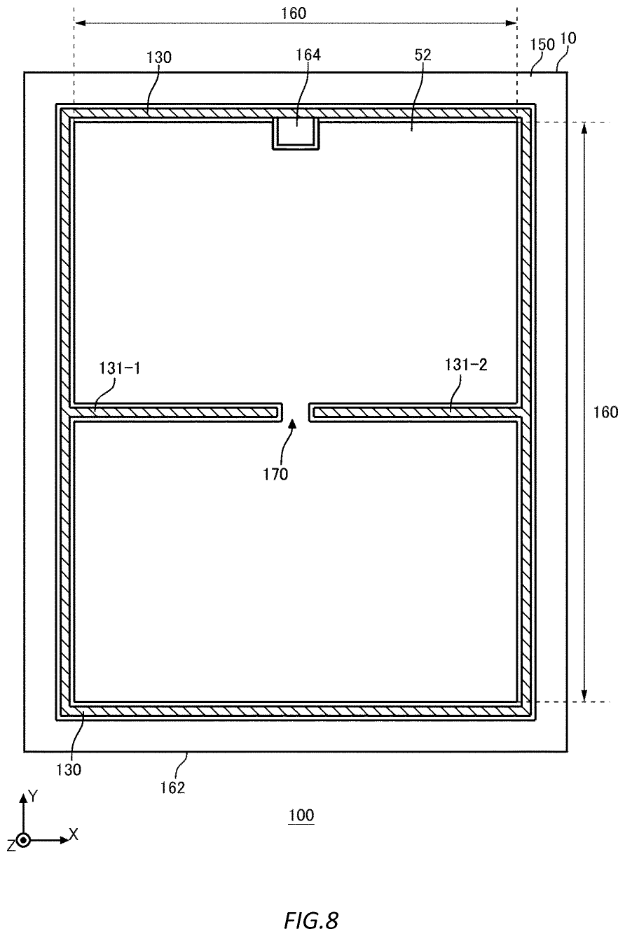

FIG. 8 is a view illustrating an arrangement example of the gate pad 164, the first metal gate runner 131, and the spacing portion 170. A structure other than arrangement of the gate pad 164, the first metal gate runner 131, and the spacing portion 170 is similar to that of any of the examples described with reference to FIGS. 1 to 7.

The gate pad 164 of the present example is arranged at a center of the semiconductor substrate 10 in the X axis direction. The first metal gate runner 131 and the spacing portion 170 are arranged at a center of the active portion 160 in the Y axis direction, and divide the active portion 160 into two in the Y axis direction. The spacing portion 170 is arranged at a center of the active portion 160 in the X axis direction. The spacing portion 170 and the gate pad 164 may be arranged to oppose each other in the Y axis direction.

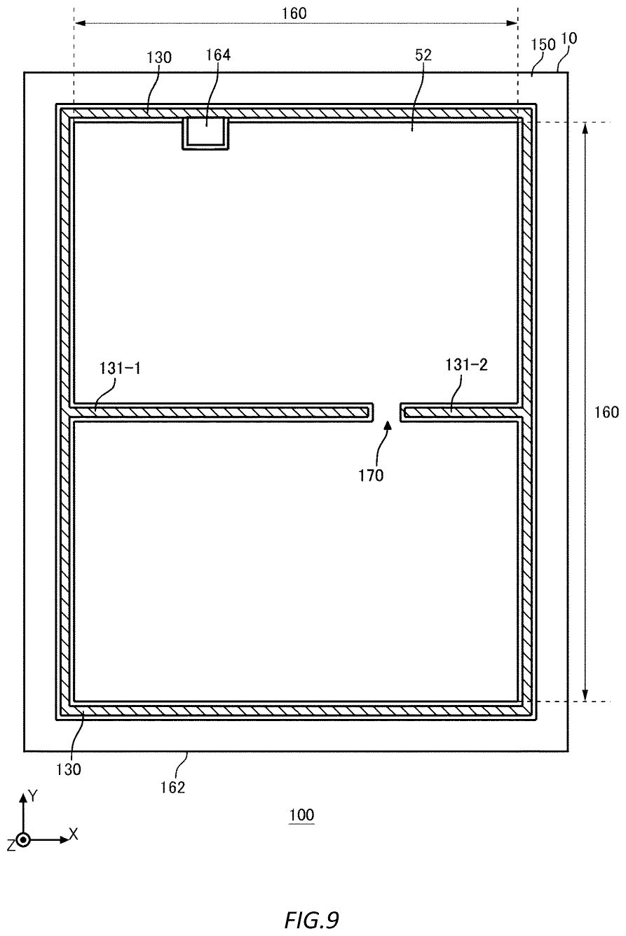

FIG. 9 is a view illustrating another arrangement example of the gate pad 164, the first metal gate runner 131, and the spacing portion 170. The present example is different from the example of FIG. 8 in positions of the gate pad 164 and the spacing portion 170 in the X axis direction. Other structures are similar to those of the example of FIG. 8.

The gate pad 164 and the spacing portion 170 of the present example are not arranged at positions opposing each other in the Y axis direction. The spacing portion 170 may not be arranged at the center of the active portion 160 in the X axis direction. The gate pad 164 may not be arranged at the center of the active portion 160 in the X axis direction. The gate pad 164 may be arranged to be biased to one side in the X axis direction with respect to the center of the active portion 160 in the X axis direction, and the spacing portion 170 may be arranged to be biased to another side with respect thereto.

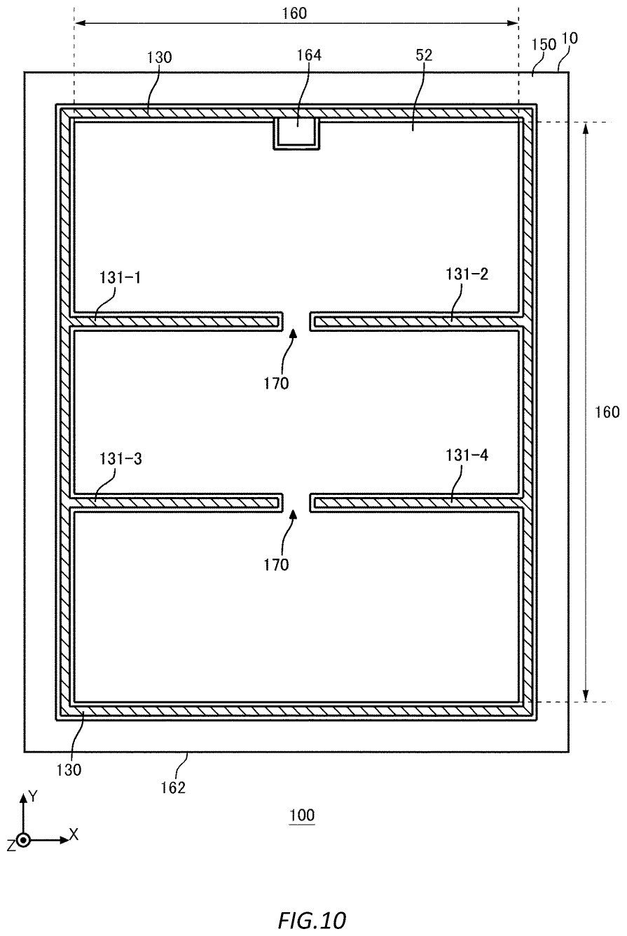

FIG. 10 is a view illustrating another arrangement example of the gate pad 164, the first metal gate runner 131, and the spacing portion 170. In the present example, combinations of the first metal gate runner 131 and the spacing portion 170 are provided at a plurality of positions in the Y axis direction. Other structures are similar to those of the example of FIG. 8. In the example of FIG. 10, two sets of combinations of the first metal gate runners 131 and the spacing portions 170 aligned in the X axis direction are provided. Positions of a plurality of spacing portions 170 in the X axis direction may be the same as or different from each other. In the example of FIG. 10, the plurality of spacing portions 170 and the gate pad 164 are provided at a same position in the X axis direction.

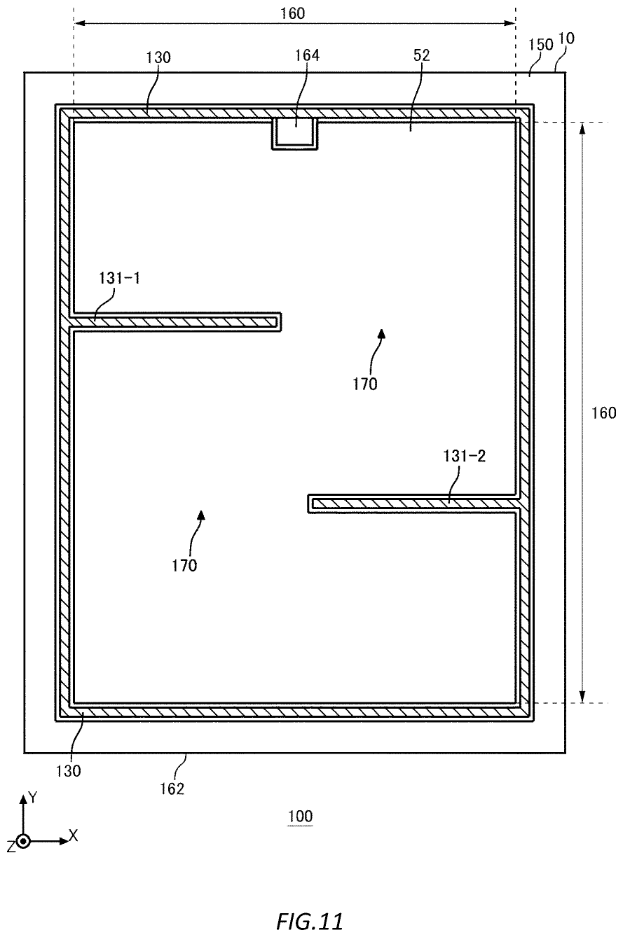

FIG. 11 is a view illustrating another arrangement example of the gate pad 164, the first metal gate runner 131, and the spacing portion 170. The spacing portion 170 of the present example is sandwiched between the first metal gate runner 131 and the outer circumferential gate runner 130 in the X axis direction. Other structures are similar to those of the example of FIG. 8. The spacing portion 170 of the present example may have a length in the X axis direction that is at least half of that of the active portion 160. In addition, similarly to the example of FIG. 10, a plurality of combinations of the first metal gate runners 131 and the spacing portions 170 aligned in the X axis direction may be provided in the Y axis direction. In the present example, two sets of the combinations are provided. The positions of the spacing portions 170 in the X axis direction may be different from each other.

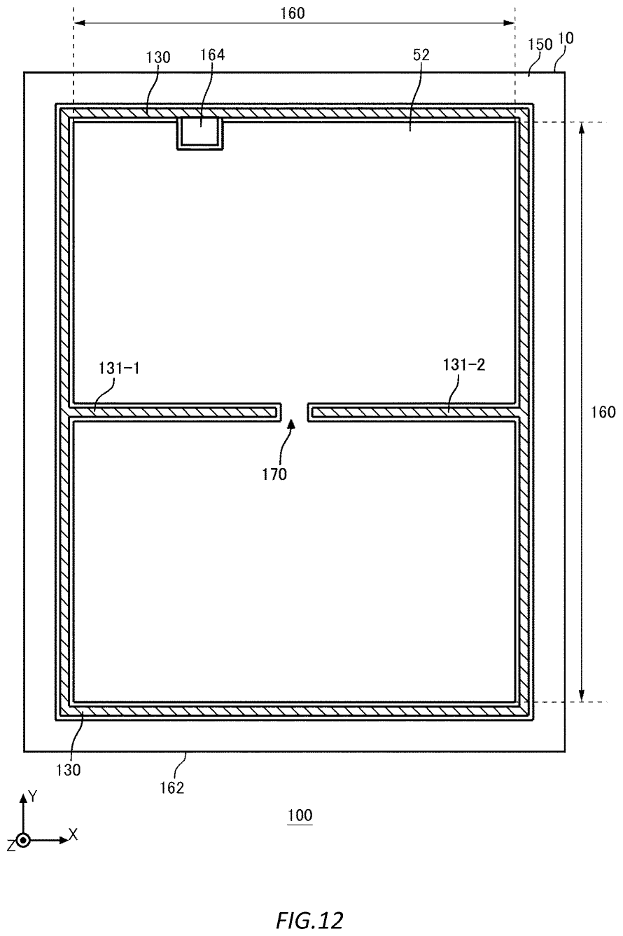

FIG. 12 is a view illustrating another arrangement example of the gate pad 164, the first metal gate runner 131, and the spacing portion 170. The positions of the gate pad 164 and the spacing portion 170 of the present example in the X axis direction are different from each other. Other structures are similar to those of the example of FIG. 8. One of the gate pad 164 and the spacing portion 170 may be arranged at the center of the active portion 160 in the X axis direction. In the example of FIG. 12, the spacing portion 170 is arranged at the center of the active portion 160 in the X axis direction. The gate pad 164 is not arranged at the center of the active portion 160 in the X axis direction.

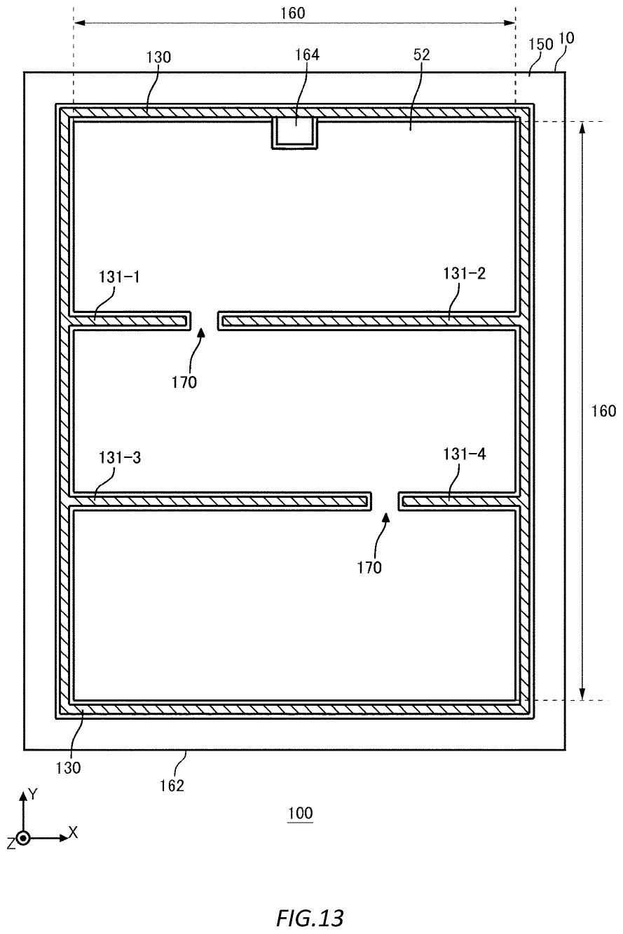

FIG. 13 is a view illustrating another arrangement example of the gate pad 164, the first metal gate runner 131, and the spacing portion 170. In the present example, similarly to the example of FIG. 10, combinations of the first metal gate runners 131 and the spacing portions 170 aligned in the X axis direction are provided at a plurality of positions in the Y axis direction. In the present example, the positions of the plurality of spacing portions 170 in the X axis direction are different from each other. The respective positions of the plurality of spacing portions 170 and the gate pad 164 in the X axis direction may be different from each other. Any of the plurality of spacing portions 170 and the gate pad 164 may be arranged at the center of the active portion 160 in the X axis direction. In the example of FIG. 13, the gate pad 164 is arranged at the center of the active portion 160 in the X axis direction. Any one of the spacing portions 170 may be arranged to be biased to one side in the X axis direction with respect to the center of the active portion 160 in the X axis direction, and another spacing portion 170 may be arranged to be biased to another side in the X axis direction with respect thereto.

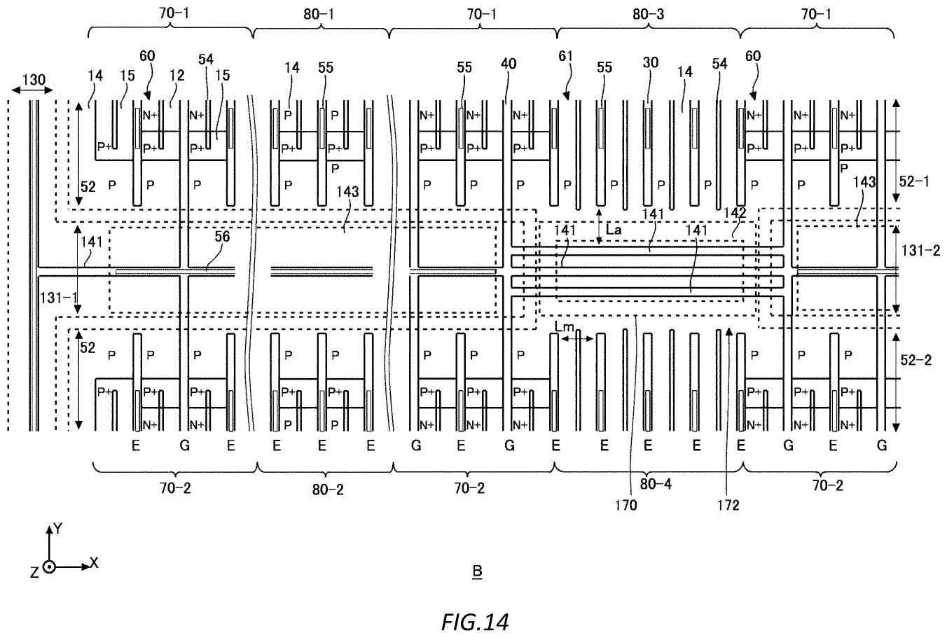

FIG. 14 is a view illustrating another structure example of the region B. A structure other than the structure particularly described in the present example is similar to that of any of the examples described in the present specification. The semiconductor device 100 of the present example includes a trench wiring 141. The trench wiring 141 is an example of the first active gate runner. The first active gate runner of the present example includes the trench wiring 141 and the first metal gate runner 131. In another example, the first metal gate runner 131 may not be provided. The first metal gate runner 131 and the trench wiring 141 may be connected to each other.

The trench wiring 141 is formed from the upper surface 21 of the semiconductor substrate 10 to an inside of the semiconductor substrate 10, and is provided to extend in the X axis direction. The trench wiring 141 may have a structure similar to the gate trench portion 40. The trench wiring 141 may include a trench formed in the upper surface 21 of the semiconductor substrate 10, a dielectric film covering an inner wall of the trench, and a conductive portion surrounded by the dielectric film. The conductive portion of the trench wiring 141 is electrically connected to the outer circumferential gate runner 130. In the present example, a part of the trench wiring 141 is arranged to overlap the first metal gate runner 131. A region which overlaps the first metal gate runner 131 and is formed with the trench wiring 141 is referred to as a second trench wiring region 143. The conductive portion of the trench wiring 141 in the second trench wiring region 143 may be connected to the first metal gate runner 131 via the contact hole 56 provided in the interlayer dielectric film. A region which is formed with the trench wiring 141 and does not overlap the first metal gate runner 131 is referred to as a first trench wiring region 142. The trench wiring 141 in the first trench wiring region 142 does not have a contact hole in the upper interlayer dielectric film.

In the present example, the dummy trench portions 30 of the transistor portion 70 and the diode portion 80 do not extend below the first metal gate runner 131. In addition, the dummy trench portions 30 of the transistor portion 70 and the diode portion 80 do not extend below the bridge portion 172. The dummy trench portions 30 are arranged to be separated by the trench wiring 141 in the Y axis direction. Similarly, the mesa portions 60 of the transistor portion 70, the mesa portions 61 of the diode portion 80, and the contact holes 54 are also arranged to be separated by the trench wiring 141 in the Y axis direction. A distance La from the end portion of the dummy trench portion 30 in the Y axis direction to the trench wiring 141 may be equal to or less than a width Lm of the mesa portion 61 or the mesa portion 60 in the X axis direction, may be equal to the width Lm, or may be 100% or more and 150% or less of the width Lm. With this configuration, it is possible to suppress a local increase in the electric field intensity at the spacing portion 170. Also in another example, a relationship between the distance La and the width Lm may be similar.

The gate conductive portion 44 of each gate trench portion 40 may be connected to the conductive portion of the trench wiring 141. Each gate trench portion 40 may be provided to extend to a position connected to the trench wiring 141 in the Y axis direction. Each gate trench portion 40 is connected to the trench wiring 141 below the first metal gate runner 131. As described with reference to FIGS. 5 to 7, the ground well region 11 may be provided below the first metal gate runner 131 and the bridge portion 172, or the base region 14 may be provided therebelow.

Also in the present example, no other wiring or the like may be provided between the bridge portion 172 and the semiconductor substrate 10. In addition, no other wiring or the like may be provided between the first metal gate runner 131 and the semiconductor substrate 10. With this configuration, a flatness of a structure above the upper surface 21 of the semiconductor substrate 10 can be improved. Therefore, the semiconductor device 100 can be easily formed with finer detail.

One or more trench wirings 141 are provided in each of the first trench wiring region 142 and the second trench wiring region 143. In the present example, a plurality of trench wirings 141 are provided in parallel with each other in the first trench wiring region 142, and one trench wiring 141 is provided in the second trench wiring region 143. In another example, a plurality of trench wirings 141 may be provided in parallel with each other also in the second trench wiring region 143. The plurality of parallel trench wirings 141 are provided at predetermined intervals in the Y axis direction. The interval between the plurality of trench wirings 141 in the first trench wiring region 142 and the interval between the plurality of trench wirings 141 in the second trench wiring region 143 may be the same as or different from each other.

A number of at least one trench wiring 141 in parallel in the first trench wiring region 142 may be larger than a number of at least one trench wiring 141 in parallel in the second trench wiring region 143. In the present example, the number of at least one trench wiring 141 in parallel in the first trench wiring region 142 is three, and the number of at least one trench wiring 141 in parallel in the second trench wiring region 143 is one. In another example, the number of at least one trench wiring 141 in parallel in the first trench wiring region 142 may be the same as the number of at least one trench wiring 141 in parallel in the second trench wiring region 143.

The first trench wiring region 142 may be provided in the spacing portion 170. Since the first metal gate runner 131 is not provided in the spacing portion 170, a resistance value of the first active gate runner increases. On the other hand, increasing the number of at least one trench wirings 141 in the first trench wiring region 142 can suppress an increase in the resistance value of the first active gate runner in the spacing portion 170.

At least a part of the trench wirings 141 is provided continuously from the outer circumferential gate runner 130 over a region including at least one spacing portion 170 and at least two separation parts (for example, the first metal gate runners 131-1 and 131-2) of the first metal gate runner 131. At least one trench wiring 141 in the first trench wiring region 142 is connected to any trench wiring 141 in the second trench wiring region 143. In the example of FIG. 14, among the plurality of trench wirings 141 in the first trench wiring region 142, the trench wiring 141 arranged at a center in the Y axis direction is linearly connected to the trench wiring 141 in the second trench wiring region 143. The trench wiring 141 may be provided so as to cross the active portion 160 in the X axis direction.

In another example, the first active gate runner at the position opposing the diode portions 80-1 and 80-2 may not have the second trench wiring region 143. The first active gate runner may consist only of the first metal gate runner 131 without including the trench wiring 141. When there is only one spacing portion 170, in the spacing portion 170, the bridge portion 172 may be formed without the first trench wiring region 142. At this time, any of the structures described with reference to FIG. 7 and earlier may be partially applied. In addition, the semiconductor device 100 may not include the spacing portion 170, and, in all regions, the first active gate runner may include the first metal gate runner 131 and may not include the first trench wiring region 142. On the other hand, in all the regions, the first active gate runner may consist only of the first trench wiring region 142 without including the first metal gate runner 131.

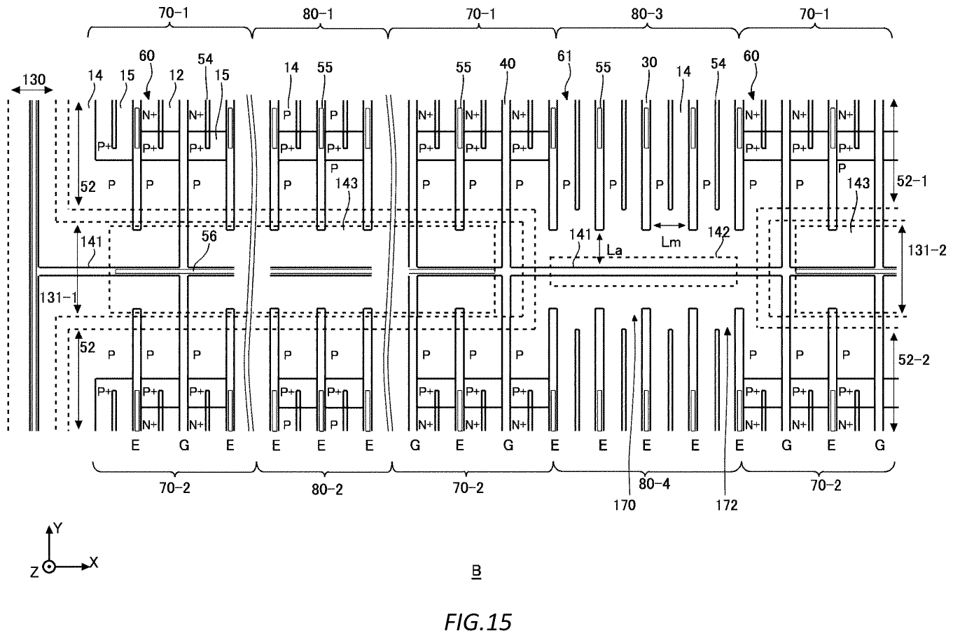

FIG. 15 is a view illustrating another structure example of the region B. The example of FIG. 15 is different from that of FIG. 14 in that the dummy trench portion 30 extends below the first metal gate runner 131. The dummy trench portion 30 extends below the first metal gate runner 131, so that the distance La to the trench wiring 141 decreases, and an electric field is relaxed. Also in the spacing portion 170, the dummy trench portion 30 may be provided to overlap a region where the first metal gate runner 131 extends, and a similar effect can be obtained. In FIG. 15, the number of at least one trench wiring 141 in parallel in the first trench wiring region 142 is one, but the number of at least one trench wiring 141 in parallel in the first trench wiring region 142 and the second trench wiring region 143 may be similar to that of any example described with reference to FIG. 14.

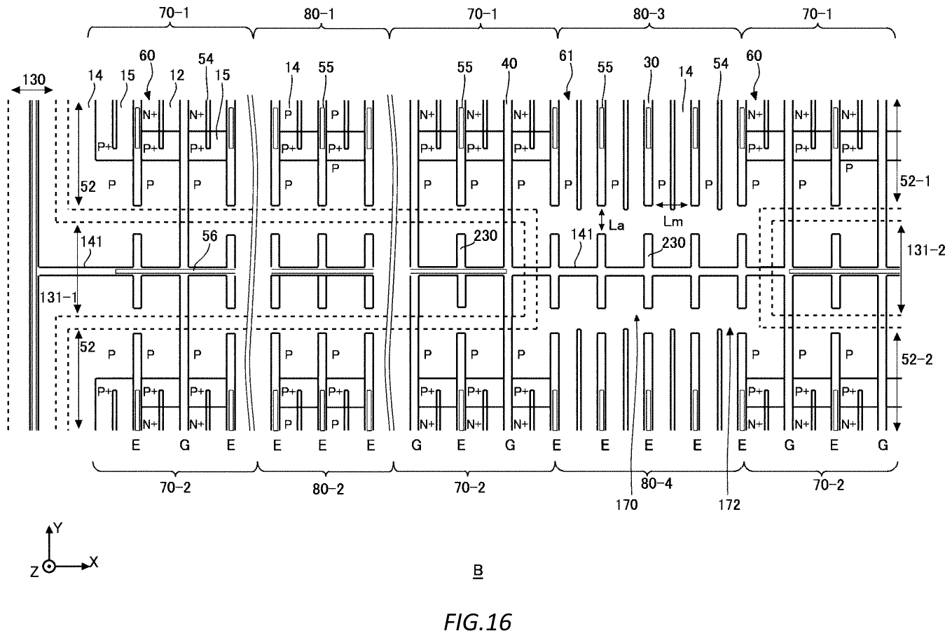

FIG. 16 is a view illustrating another structure example of the region B. In FIG. 16, illustration of the first trench wiring region 142 and the second trench wiring region 143 is omitted. The example of FIG. 16 is different from the example of FIG. 14 or 15 in that an electric field relaxation trench portion 230 extends from the trench wiring 141 toward the dummy trench portion 30.

A structure of the electric field relaxation trench portion 230 is similar to that of the gate trench portion 40. The electric field relaxation trench portion 230 may include a trench provided in the upper surface 21 of the semiconductor substrate 10, a dielectric film covering an inner wall of the trench, and a conductive portion surrounded by the dielectric film. The electric field relaxation trench portion 230 extends toward the dummy trench portion 30, so that the distance La to the dummy trench portion 30 decreases, and the electric field in the Y axis direction is relaxed. Also in the spacing portion 170, the electric field relaxation trench portion 230 may extend toward the dummy trench portion 30. With this configuration, a similar effect is obtained also in the spacing portion 170.

The electric field relaxation trench portion 230 may be provided so as to be in contact with the dummy trench portion 30 or may be provided so as not to be in contact therewith. In the X axis direction, an interval between the gate trench portion 40 and the electric field relaxation trench portion 230 or an interval between the adjacent electric field relaxation trench portions 230 may be the same as or different from an interval between the gate trench portion 40 and the dummy trench portion 30 of the active portion 160 or an interval between the adjacent dummy trench portions 30. Due to presence of the electric field relaxation trench portion 230, the electric field is relaxed also in the X axis direction. In addition, an extending direction of the electric field relaxation trench portion 230 may be the same as or different from the extending direction (y direction) of the dummy trench portion 30. In addition, the electric field relaxation trench portion 230 may be connected to the first metal gate runner 131 and may not be connected to the trench wiring 141 or the gate trench portion 40.

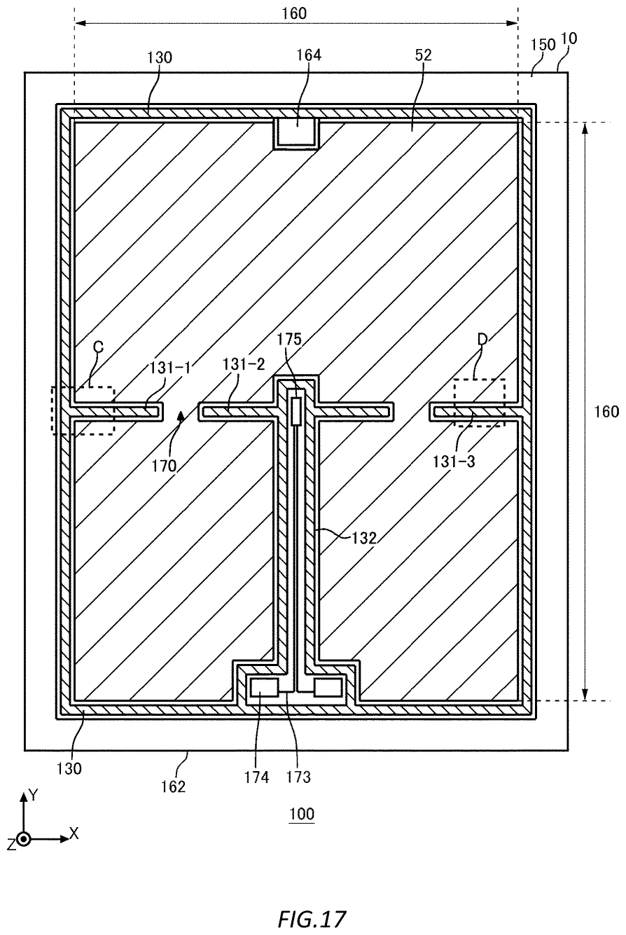

FIG. 17 is a view illustrating a region C and a region D in the semiconductor device 100. A structure of the semiconductor device 100 may be similar to that of any of the examples described with reference to FIGS. 1 to 16. The spacing portion 170 may be provided or may not be provided. That is, a plurality of the first metal gate runners 131 may be discretely provided in the X axis direction, or may be continuously provided so as to cross the active portion 160.

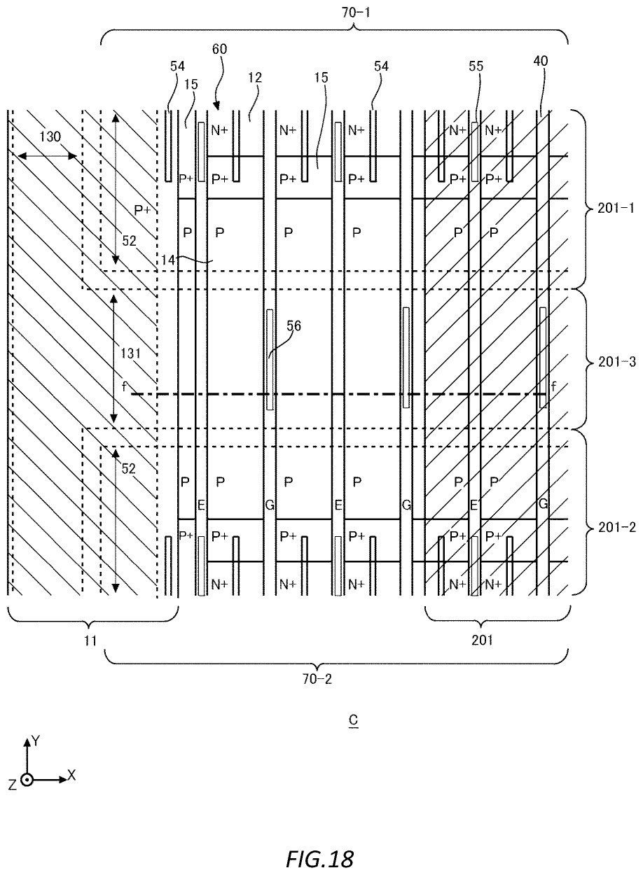

FIG. 18 is an enlarged view of the region C in FIG. 17. The region C includes the outer circumferential gate runner 130 and the first metal gate runner 131-1. The semiconductor device 100 of the present example includes a trench bottom region 201 which is provided for at least one trench portion, is in contact with the lower end of the trench portion, and is of a conductivity type different from that of the drift region or has a doping concentration different from that of the drift region. Other structures are similar to those of any of the examples described with reference to FIGS. 1 to 17. The trench bottom region 201 of the present example is P type. In FIG. 18, a region where the trench bottom region 201 is provided is hatched with oblique lines. In addition, FIG. 18 also illustrates the ground well region 11. In each drawing, the ground well region 11 at the upper surface 21 of the semiconductor substrate 10 may be indicated by a solid line, and the ground well region 11 at the depth position of the lower end of the trench portion may be indicated by a broken line. In addition, a range of the ground well region 11 at the depth position of the lower end of the trench portion is indicated by hatching with oblique lines having a direction different from that of the trench bottom region 201.

The ground well region 11 is provided below the outer circumferential gate runner 130. The ground well region 11 may be provided in a range wider than the outer circumferential gate runner 130 in top view. The ground well region 11 of the present example overlaps the emitter electrode 52 in a region not overlapping the outer circumferential gate runner 130. The ground well region 11 may be connected to the emitter electrode 52 via the contact hole 54.

The trench bottom region 201 is provided in at least a part of the transistor portion 70. The trench bottom region 201 may be provided for some trench portions of the transistor portion 70. The trench bottom region 201 may be provided for all the trench portions. The trench bottom region 201 may or may not be provided in the diode portion 80.

Providing the trench bottom region 201 can reduce the electric field strength at the lower end of the trench portion. In the present example, a trench bottom region 201-1 is provided in the transistor portion 70-1, and a trench bottom region 201-2 is provided in the transistor portion 70-2. The trench bottom region 201-1 and the trench bottom region 201-2 are provided with the first active gate runner sandwiched therebetween in the Y axis direction. The first active gate runner in the present example is the first metal gate runner 131. The first active gate runner may include any of the first metal gate runner 131 and a semiconductor wiring, or may be a combination of any plurality of wirings. The semiconductor wiring is a polysilicon wiring provided above the upper surface 21 of the semiconductor substrate 10. The semiconductor wiring may be arranged between the first metal gate runner 131 and the semiconductor substrate 10.

The trench bottom region 201-1 and the trench bottom region 201-2 are connected below the first active gate runner (the first metal gate runner 131 in the present example) in a region of a same conductivity type as that of the trench bottom region 201. Connecting the trench bottom region 201-1 and the trench bottom region 201-2 can reduce the variation in potential in the trench bottom region 201-1 and the trench bottom region 201-2.

Since the trench bottom region 201 of the present example is P type, the trench bottom region 201-1 and the trench bottom region 201-2 are connected in a region of the P type. In the example of FIG. 18, the trench bottom region 201-1 and the trench bottom region 201-2 are connected by a trench bottom region 201-3. That is, the trench bottom regions 201 are connected to each other below the first metal gate runner 131. The trench bottom regions 201-1, 201-2, and 201-3 may have a same doping concentration and may be arranged at a same depth.

During manufacturing of the trench portion, the trench bottom region 201 can be formed by implanting dopant ions from a trench after forming the trench and before filling a conductive portion in the trench. With this configuration, the trench bottom region 201 in contact with the bottom portion of the trench portion can be formed. By annealing the semiconductor substrate 10 after implanting the dopants, the implanted dopants are diffused. With this configuration, the trench bottom region 201 is also formed in the mesa portion sandwiched between the trench portions.

The trench bottom region 201 may be formed over the entire mesa portion in the X axis direction. The trench bottom region 201 is formed over the entire mesa portion by connecting a region where the dopants diffuse in the X axis direction from one trench portion to a region where the dopants diffuse in the X axis direction from another trench portion. In another example, a distance by which the dopants diffuse in the X axis direction from the trench portion may be smaller than half of a width of the mesa portion in the X axis direction. In this case, the trench bottom region 201 is not formed in a vicinity of the center of the mesa portion in the X axis direction.

In the example of FIG. 18, at least one gate trench portion 40 in the transistor portion 70-1 passes below the first metal gate runner 131 and is connected to the gate trench portion 40 of the transistor portion 70-2. The trench bottom regions 201-1, 201-3, and 201-2 can be formed by forming the trench bottom region 201 for the gate trench portion 40.

The trench bottom region 201 may be formed for at least one dummy trench portion 30 of the transistor portion 70. The dummy trench portion 30 passes below the first metal gate runner 131 and extends to the transistor portion 70-2. With such a configuration, the trench bottom regions 201-1, 201-3, and 201-2 along the dummy trench portion 30 can be formed.

The trench bottom region 201 may be formed with respect to at least one mesa portion 60 of the transistor portion 70. Two trench portions sandwiching the mesa portion 60 pass below the first metal gate runner 131 and extend to the transistor portion 70-2. With such a configuration, the trench bottom regions 201-1, 201-3, and 201-2 along the mesa portion 60 can be formed.

The transistor portion 70 may include a region where the trench bottom region 201 is not provided in top view. The transistor portion 70 may include the gate trench portion 40 in which the trench bottom region 201 is not provided, may include the dummy trench portion 30 in which the trench bottom region 201 is not provided, or may include the mesa portion 60 in which the trench bottom region 201 is not provided.

The trench bottom region 201 of the present example is an electrically floating region. The term “electrically floating” refers to a state where there is no electrical connection to any conductive portion such as a wiring, an electrode, or a pad. A region having a conductivity type different from that of the dielectric film or the trench bottom region 201 is provided between the trench bottom region 201 and the conductive portion. In the present example, the trench bottom region 201 and the ground well region 11 are provided apart from each other in the X axis direction. A plurality of trench bottom regions 201 may be discretely provided in the X axis direction.

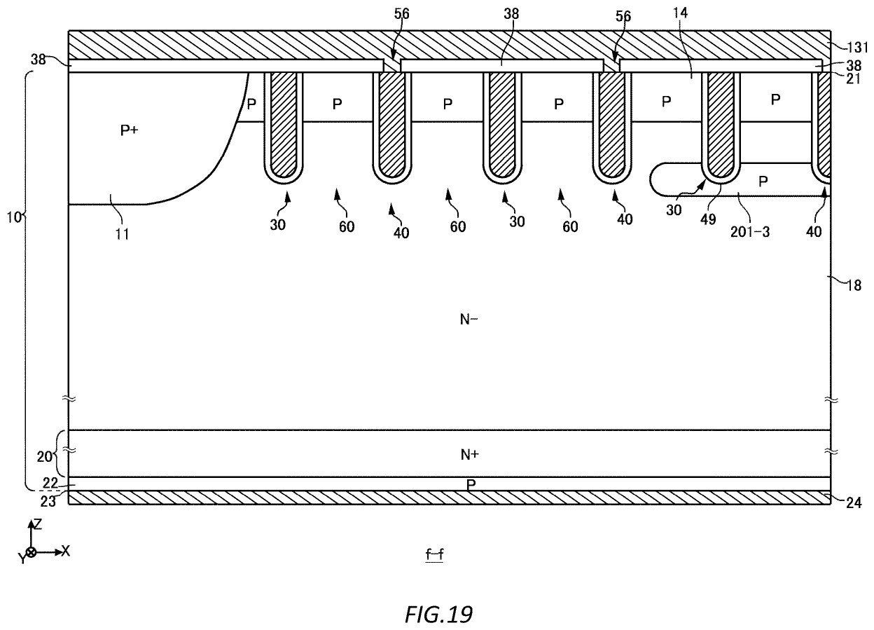

FIG. 19 is a view illustrating an example of a cross section f-f in FIG. 18. The cross section f-f is an XZ cross section passing through the ground well region 11 and the trench bottom region 201-3. As described with reference to FIG. 18, the trench bottom region 201-3 may be provided in contact with a lower end of at least one gate trench portion 40 passing below the first metal gate runner 131. The trench bottom region 201-3 may be provided in contact with a lower end of at least one dummy trench portion 30 passing below the first metal gate runner 131. The trench bottom region 201 may be continuously provided over a plurality of trench portions in the X axis direction. The trench bottom region 201 may be continuously provided over a plurality of mesa portions 60 in the X axis direction. A plurality of trench portions in which the trench bottom region 201 is not provided may be continuously arranged in the X axis direction. A plurality of mesa portions 60 in which the trench bottom region 201 is not provided may be continuously provided in the X axis direction. The trench bottom region 201 may not be provided in the mesa portion 60 closest to the ground well region 11 in the X axis direction. The trench bottom region 201 may not be provided for the trench portion closest to the ground well region 11 in the X axis direction.

The trench bottom region 201-3 is arranged apart from the ground well region 11 in the X axis direction. The trench bottom region 201-3 may be provided in a range overlapping the base region 14 in top view. However, the trench bottom region 201-3 and the base region 14 are arranged apart from each other in the Z axis direction. The drift region 18 may be provided between the trench bottom region 201 and the base region 14, or the accumulation region 16 may be provided therebetween.

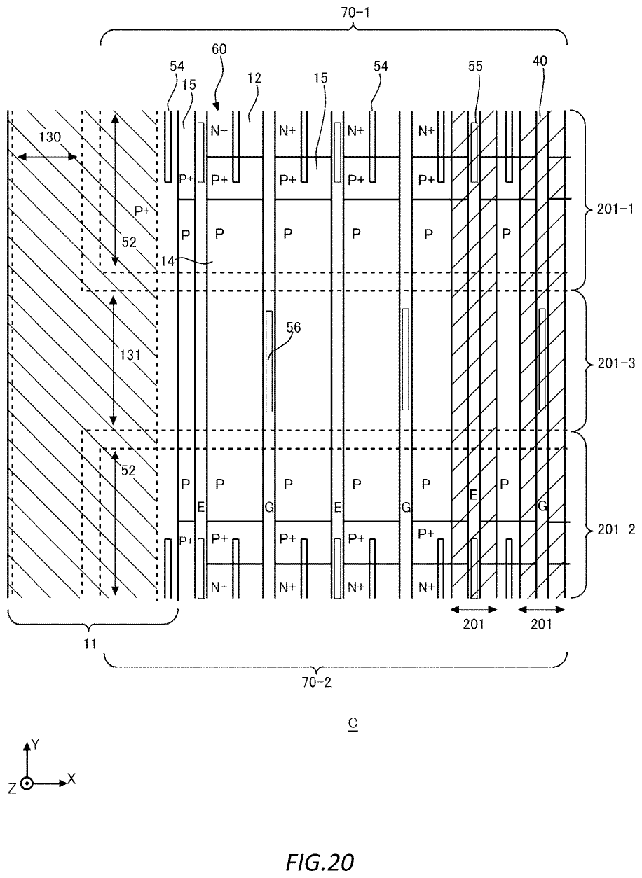

FIG. 20 is a view illustrating another structure example of the region C. In the present example, the trench bottom region 201 is arranged in a vicinity of the trench portion in the X axis direction, and is not arranged at the center of the mesa portion 60 in the X axis direction. As described above, when a diffusion length of the dopants forming the trench bottom region 201 is short, the structure as illustrated in FIG. 20 is obtained. In the present example, the trench bottom regions 201 provided for the respective trench portions are arranged apart from each other. When connecting these, a location where a distance of the trenches is narrower than that of the mesa portion 60 of the active portion or a location where the trenches intersect each other is provided outside or within a range of the drawing, so that the trench bottom region 201 is continuous.

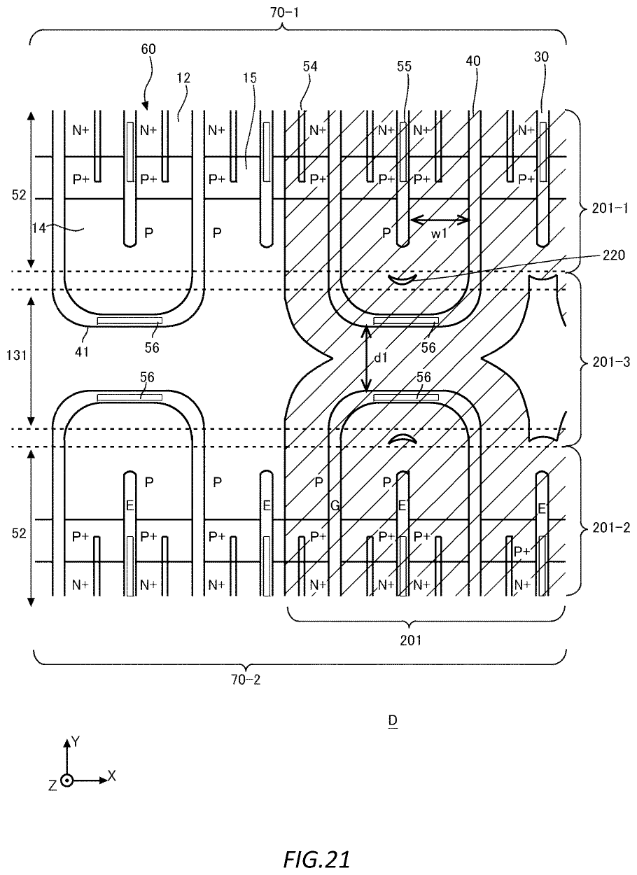

FIG. 21 is a view illustrating a structure example of the region D. The region D is a region including the transistor portion 70-1, the first metal gate runner 131, and the transistor portion 70-2. In the present example, at least one gate trench portion 40 provided in the transistor portion 70-1 is separated from the gate trench portion 40 of the transistor portion 70-2. In the present example, all trench portions of the transistor portion 70-1 are separated below the first metal gate runner 131.

For at least one set of two gate trench portions 40 separated in the Y axis direction, the trench bottom region 201-1 and the trench bottom region 201-2 are provided along the gate trench portions 40. The trench bottom region 201-3 may be provided for a region between the two gate trench portions 40. The trench bottom region 201-3 connects the trench bottom region 201-1 and the trench bottom region 201-2.

A distance between the two gate trench portions 40 separated in the Y axis direction is denoted by d1. When the distance d1 is equal to or less than twice the diffusion distance of the dopants implanted into the bottom portion of the trench portion, the trench bottom region 201 widening in the Y axis direction from one gate trench portion 40 are connected to the trench bottom region 201 widening in the Y axis direction from another gate trench portion 40. The distance d1 may be twice or less the diffusion distance of the dopants. The distance d1 may be equal to or less than a width w1 of the mesa portion 60 in the X axis direction, may be smaller than the width w1, or may be equal to or less than half of the width w1. In the present example, the trench bottom region 201 is formed over the entire mesa portion 60 in the X axis direction. Therefore, the diffusion distance of the dopants is larger than the half of the width w1 of the mesa portion 60. Therefore, by setting the distance d1 to the width w1 or less, the trench bottom region 201 can be formed over the distance d1.

The gate trench portion 40 of the present example has the edge portion 41 similarly to the example described with reference to FIG. 2. End portions in the Y axis direction of two gate trench portions 40 aligned in the X axis direction are connected to each other by the edge portion 41. In addition, the edge portion 41 and the dummy trench portion 30 are arranged to oppose each other in the Y axis direction. A non-formation region 220 in which the trench bottom region 201 is not formed may be provided between the dummy trench portion 30 and the edge portion 41.

When a distance between the dummy trench portion 30 and the edge portion 41 is short, the non-formation region 220 may not be provided. In addition, in the present example, at a position where the dummy trench portions 30 oppose each other, a distance between both dummy trench portions 30 is large, and the non-formation region 220 is provided. When the distance between both dummy trench portions 30 is short, the non-formation region 220 may not be provided. In the present example, since the dummy trench portions 30 are separated from each other, the trench bottom regions 201-1 and 201-2 provided for the dummy trench portion 30 are connected via the trench bottom region 201-3 of the gate trench portion 40, but the trench bottom regions 201 may be directly connected to each other without interposing the gate trench portion 40 by shortening the distance between the dummy trench portions 30 or connecting the dummy trench portions 30. Note that, when the edge portion 41 is not provided at the gate trench portion 40 and when the edge portion 31 is provided at the dummy trench portion 30, similarly, the trench bottom regions 201-1 and 201-2 of the transistor portions 70-1 and 70-2 can be connected via the trench bottom region 201-3. In addition, also in the outer circumferential gate runner 130 and the vicinity thereof, similarly to the first active gate runner of the present example, the trench bottom regions 201 may be connected to each other in the X axis direction without providing the ground well region 11. For example, the trench bottom regions 201 may be connected, for example, by providing the edge portions 41 and 31 at the trench portions in a vicinity of the outer circumferential gate runner 130 to sufficiently reduce a distance between the dummy trench portions 30 or the gate trench portions 40 adjacent to each other also in the X axis direction.

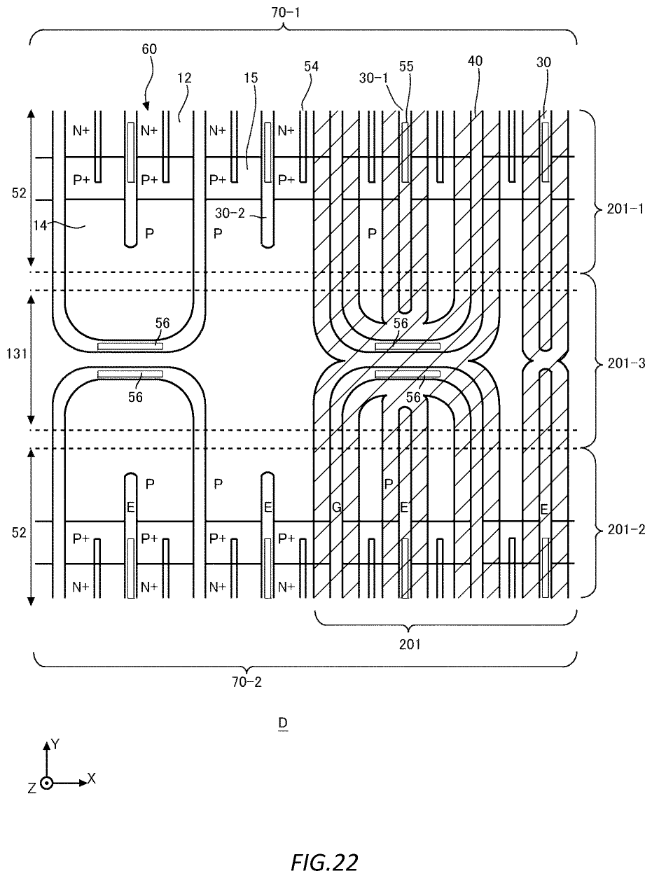

FIG. 22 is a view illustrating another structure example of the region D. In the present example, the trench bottom region 201 is arranged in the vicinity of the trench portion in the X axis direction, and is not arranged at the center of the mesa portion 60 in the X axis direction. As described above, when the diffusion length of the dopants forming the trench bottom region 201 is short, it is necessary to make the distance between the edge portions 41, between the dummy trench portions 30, or between the edge portion 41 and the dummy trench portion 30 smaller than the width w1 of the mesa portion 60, and the structure as illustrated in FIG. 22 is obtained. Note that also in the outer circumferential gate runner 130 and the vicinity thereof, similarly to the first active gate runner of the present example, the trench bottom regions 201 may be connected to each other in the X axis direction without providing the ground well region 11. For example, the trench bottom regions 201 may be connected, for example, by providing the edge portions 41 and 31 in the trench portions in the vicinity of the outer circumferential gate runner 130 to sufficiently reduce the distance between the dummy trench portions 30 or the gate trench portions 40 adjacent to each other also in the X axis direction.

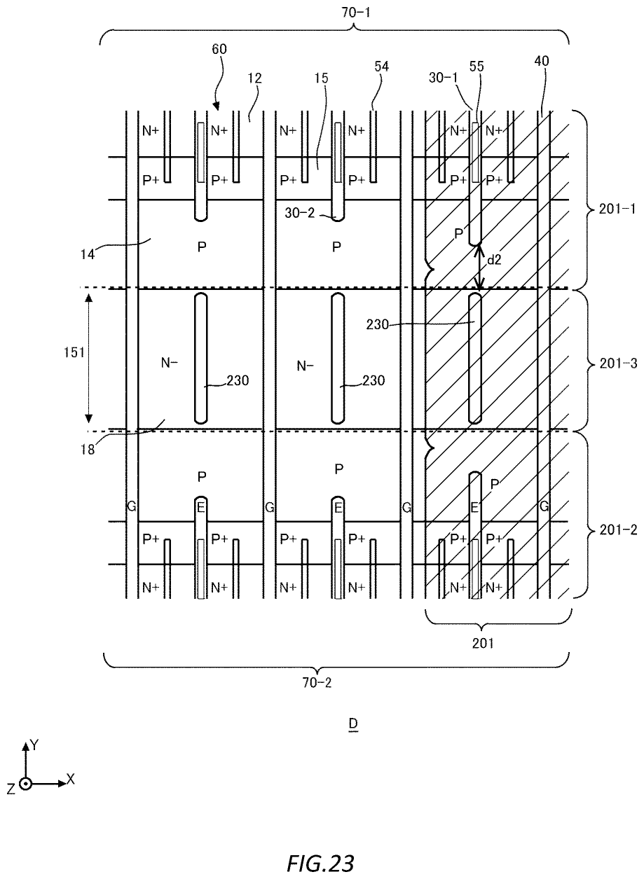

FIG. 23 is a view illustrating another structure example of the region D. The semiconductor device 100 of the present example includes a semiconductor gate runner 151 as the first active gate runner. The first active gate runner may or may not include the first metal gate runner 131. The semiconductor gate runner 151 is provided to extend in the X axis direction. Arrangement of the semiconductor gate runner 151 may be similar to that of the first metal gate runner 131 described with reference to FIGS. 1 to 22. In the present example, the first metal gate runner 131 may not be provided, and an upper portion of the semiconductor gate runner 151 may be covered with the emitter electrode 52 via the interlayer dielectric film 38. A following example including the semiconductor gate runner 151 also will be described as the example without the first metal gate runner 131 unless otherwise specified. When the first metal gate runner 131 is provided, a width of the first metal gate runner 131 may be the same as or different from a width of the semiconductor gate runner 151, or a boundary between the emitter electrode 52 and the first metal gate runner 131 may be either on or outside the semiconductor gate runner 151.

The semiconductor gate runner 151 is a polysilicon wiring provided above the upper surface 21 of the semiconductor substrate 10. The semiconductor gate runner 151 is connected to the conductive portion of the trench portion provided therebelow.

The gate trench portion 40 of the transistor portion 70-1 of the present example passes through the semiconductor gate runner 151 and is connected to the gate trench portion 40 of the transistor portion 70-2. The gate trench portion 40 is connected to the semiconductor gate runner 151 at a position overlapping the semiconductor gate runner 151. In addition, the trench bottom region 201 is provided for at least one gate trench portion 40. Since the gate trench portion 40 is provided to pass below the semiconductor gate runner 151, the trench bottom regions 201-1, 201-3, and 201-2 are provided along the gate trench portion 40.

The dummy trench portion 30 of the transistor portion 70-1 and the dummy trench portion 30 of the transistor portion 70-2 of the present example do not overlap the first active gate runner (the semiconductor gate runner 151 in the present example). With this configuration, the dummy trench portion 30 of the transistor portion 70-1 and the dummy trench portion 30 of the transistor portion 70-2 are separated from each other in the Y axis direction.

The semiconductor device 100 of the present example includes the electric field relaxation trench portion 230 between two dummy trench portions 30 provided with the semiconductor gate runner 151 sandwiched therebetween in the Y axis direction. The structure of the electric field relaxation trench portion 230 is similar to that of the gate trench portion 40. The electric field relaxation trench portion 230 may include a trench provided in the upper surface 21 of the semiconductor substrate 10, a dielectric film covering an inner wall of the trench, and a conductive portion surrounded by the dielectric film. The trench bottom regions 201-1 and 201-2 are provided for at least one set of dummy trench portions 30 aligned in the Y axis direction. Further, the trench bottom region 201-3 is provided for the electric field relaxation trench portion 230 aligned in the Y axis direction with the dummy trench portion 30 provided with the trench bottom region 201. The trench bottom region 201-3 connects the trench bottom region 201-1 and the trench bottom region 201-2. With such a configuration, the trench bottom regions 201-1, 201-3, and 201-2 can be provided along the dummy trench portion 30.

A distance d2 in the Y axis direction between the dummy trench portion 30 and the electric field relaxation trench portion 230 aligned in the Y axis direction may be twice or less the diffusion distance of the dopants implanted into the lower end of the trench portion. The distance d2 may be equal to or less than the width w1 of the mesa portion 60 in the X axis direction, may be smaller than the width w1, or may be equal to or less than the half of the width w1.

The entire electric field relaxation trench portion 230 may overlap the semiconductor gate runner 151. An end portion of the electric field relaxation trench portion 230 in the Y axis direction may overlap an end portion of the semiconductor gate runner 151 in the Y axis direction, or may be arranged on an inner side thereof.

The electric field relaxation trench portion 230 may include a part extending in the Y axis direction. The electric field relaxation trench portion 230 of the present example has a linear shape extending in the Y axis direction. In addition, a feature of the electric field relaxation trench portion 230 described with reference to FIG. 16 may be provided.

The ground well region 11 is not provided below the semiconductor gate runner 151 of the present example. Therefore, when the gate trench portion 40 of the transistor portion 70-1 and the gate trench portion 40 of the transistor portion 70-2 are separated, the electric field at the lower end of the trench portion may increase. In the present example, the increase in the electric field at the lower end of the trench portion can be prevented by connecting the gate trench portions 40. In addition, by adopting a configuration in which the gate trench portions 40 are connected, the trench bottom regions 201 of the transistor portion 70-1 and the transistor portion 70-2 can be connected by performing ion implantation on the bottom portion of the gate trench portion 40 located below the semiconductor gate runner 151.

Since the ground well region 11 is not provided below the semiconductor gate runner 151 of the present example, the distance between the gate trench portions 40 also increases in the X axis direction, and the electric field at the lower end of the trench portion may increase. In the present example, the increase in the electric field is prevented by providing the electric field relaxation trench portion 230. The electric field relaxation trench portion 230 is separated from the dummy trench portion 30 when connected to the semiconductor gate runner 151. In addition, by providing the electric field relaxation trench portion 230, the trench bottom regions 201 of the transistor portion 70-1 and the transistor portion 70-2 can be connected by performing ion implantation on the bottom portion of the electric field relaxation trench portion 230 located below the semiconductor gate runner 151.

The ground well region 11 is not provided below the semiconductor gate runner 151 of the present example. In the present example, this part is the drift region 18. When the base region 14 is formed after formation of the semiconductor gate runner 151, ion implantation of the base region 14 is shielded by the semiconductor gate runner 151, so that such a structure can be obtained.

The electric field relaxation trench portions 230 may be provided for all the dummy trench portions 30. In this case, for the electric field relaxation trench portion 230 with respect to the dummy trench portion 30 where the trench bottom region 201 is not provided, the trench bottom region 201 is not provided. In another example, the electric field relaxation trench portion 230 may be arranged only for the dummy trench portion 30 in which the trench bottom region 201 is provided. When the interval between the trench portions is wide but the electric field is sufficiently small, the electric field relaxation trench portion 230 may be provided only to connect the trench bottom regions 201. In this case, the trench bottom region 201 is provided for all the electric field relaxation trench portions 230. On the other hand, the electric field relaxation trench portion 230 may be arranged only for the dummy trench portion 30 in which the trench bottom region 201 is not provided. Since the trench bottom regions 201-1 and 201-2 of the dummy trench portion 30-1 extend to the lower end of the gate trench portion 40, the trench bottom regions 201-1 and 201-2 are connected even when there is no electric field relaxation trench portion 230 corresponding to the dummy trench portion 30. In this case, it does not matter even if the trench bottom region 201 is not provided for all electric field relaxation trench portions 230.

The dummy trench portion 30-1 provided with the trench bottom region 201 may extend to a vicinity of the semiconductor gate runner 151 in top view as compared with the dummy trench portion 30-2 not provided with the trench bottom region 201. With this configuration, it is easy to connect the trench bottom region 201 of the dummy trench portion 30-1 and the trench bottom region 201 of the electric field relaxation trench portion 230. On the other hand, the dummy trench portion 30-2 not provided with the trench bottom region 201 may extend to the vicinity of the semiconductor gate runner 151 in top view as compared with the dummy trench portion 30-1 provided with the trench bottom region 201. In the dummy trench portion 30-2 not provided with the trench bottom region 201, the electric field at the lower end of the trench portion is large compared with the dummy trench portion 30-1 provided with the trench bottom region 201, and thus, a distance between the dummy trench portion 30-2 and the electric field relaxation trench portion 230 may be reduced to relax the electric field.

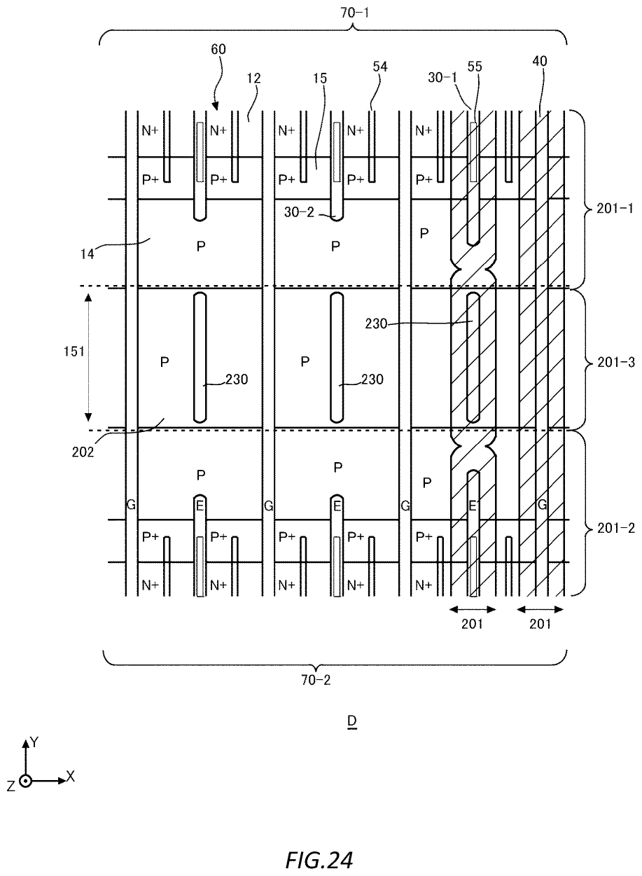

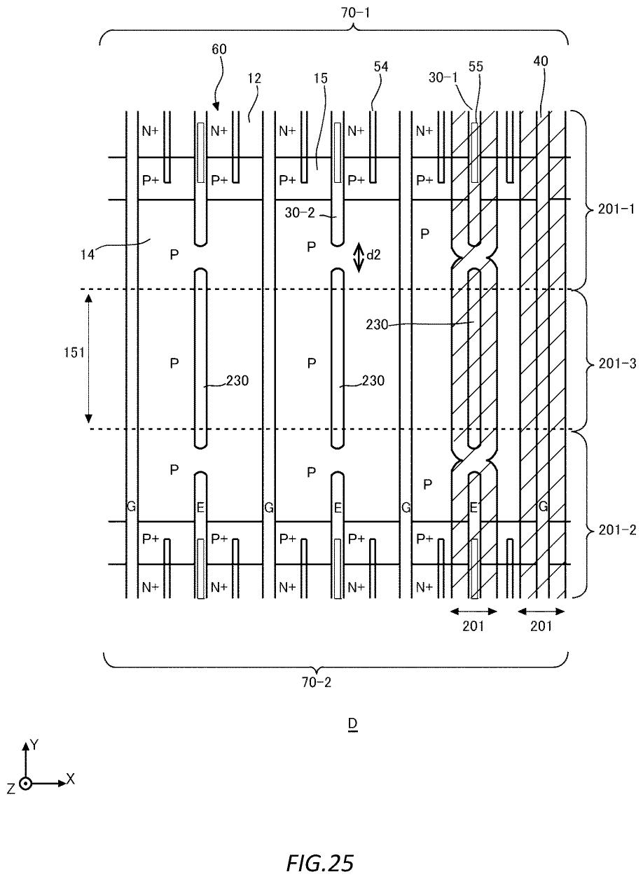

FIG. 24 is a view illustrating another structure example of the region D. In the present example, the trench bottom region 201 is arranged in the vicinity of the trench portion in the X axis direction, and is not arranged at the center of the mesa portion 60 in the X axis direction. Other structures are similar to those of the example of FIG. 23. As described above, when the diffusion length of the dopants forming the trench bottom region 201 is short, the structure as illustrated in FIG. 25 is obtained.

The ground well region 11 is not provided below the semiconductor gate runner 151 of the present example. In the present example, this part is a surface region 202 of the P type. The surface region 202 may be formed by performing, on the upper surface 21, ion implantation when the trench bottom region 201 is formed. When the base region 14 is formed after the formation of the semiconductor gate runner 151, the ion implantation of the base region 14 is shielded by the semiconductor gate runner 151, so that such a structure can be obtained. A region below the semiconductor gate runner 151 may be the drift region 18 as illustrated in FIG. 23. Also in the example illustrated in FIG. 23, the surface region 202 may be formed below the semiconductor gate runner 151 as in the present example.

FIG. 25 is a view illustrating another structure example of the region D. In the present example, the electric field relaxation trench portion 230 extends to an outside of the semiconductor gate runner 151 in the Y axis direction. The electric field relaxation trench portion 230 may extend to the outside of the semiconductor gate runner 151 in both a direction toward the transistor portion 70-1 and a direction toward the transistor portion 70-2. By lengthening the electric field relaxation trench portion 230, the distance d2 is reduced, making it easier to continuously provide the trench bottom region 201. In the examples illustrated in FIGS. 23 and 24, a case has been described in which lengths of the dummy trench portions 30-1 and 30-2 in the Y axis direction are changed, but the electric field at the lower end of the trench portion and the connection of the trench bottom regions 201 may be adjusted by changing the length of the electric field relaxation trench portion 230.

The ground well region 11 is not provided below the semiconductor gate runner 151 of the present example. In the present example, this part is the base region 14. When the base region 14 is formed before the formation of the semiconductor gate runner 151, such a structure can be obtained. As described in the examples illustrated in FIGS. 23 and 24, the region below the semiconductor gate runner 151 may be the drift region 18 or the surface region 202. Also in the examples illustrated in FIGS. 23 and 24, the region below the semiconductor gate runner 151 may be the base region 14 as in the present example. In the example of using the semiconductor gate runner 151 described below, the region below the semiconductor gate runner 151 is described as the base region 14 unless otherwise specified.

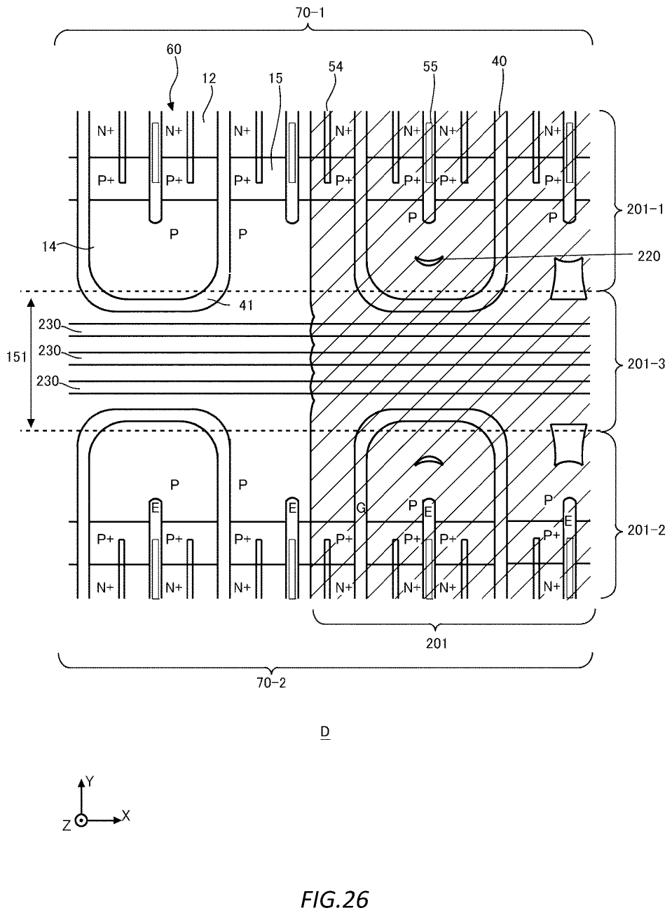

FIG. 26 is a view illustrating another structure example of the region D. In the present example, the electric field relaxation trench portion 230 is provided to extend in the X axis direction. In addition, the semiconductor gate runner 151 is provided as the first active gate runner. The conductive portion of the electric field relaxation trench portion 230 is connected to the semiconductor gate runner 151. Other structures are similar to those of the example of FIG. 21. The trenches of the transistor portion 70-1 and the trenches of the transistor portion 70-2 are separated by the semiconductor gate runner 151 in the Y axis direction. Each gate trench portion 40 may be provided to extend to a position overlapping the semiconductor gate runner 151 and connected to the semiconductor gate runner 151.

The electric field relaxation trench portion 230 of the present example extends in the X axis direction between the edge portions 41 of two gate trench portions 40. The electric field relaxation trench portion 230 may be provided longer than the edge portion 41 in the X axis direction. The electric field relaxation trench portion 230 of the present example may be provided continuously in the X axis direction so as to cross the active portion 160.

The trench bottom region 201-3 is provided below the electric field relaxation trench portion 230. With this configuration, the trench bottom regions 201-1, 201-3 and 201-2 can be continuously provided. A plurality of electric field relaxation trench portions 230 may be arranged to be aligned in the Y axis direction. With this configuration, the trench bottom region 201-3 is easily formed continuously in the Y axis direction. Note that even when the trench portion is terminated without providing the edge portion 41 in a loop shape, such an electric field relaxation trench portion 230 extending in the X axis direction is provided to relax the electric field at the lower end portion of the trench portion, and the trench bottom region 201 can be continuously provided with the first active portion gate runner sandwiched therebetween.

The electric field relaxation trench portion 230 is provided in a range opposing the trench portion not provided with the trench bottom region 201, and may not be provided at a position opposing the trench portion provided with the trench bottom region 201. In the trench portion provided with the trench bottom region 201, the electric field is weakened, so that it is not necessary to place the electric field relaxation trench portion 230 in close proximity to weaken the electric field, and the electric field relaxation trench portion 230 may be provided only near the trench portion not provided with the trench bottom region 201 for relaxation of the electric field. In another example, the electric field relaxation trench portion 230 is provided in a range opposing the trench portion provided with the trench bottom region 201, and may not be provided at a position opposing the trench portion not provided with the trench bottom region 201. When the electric field at the edge of the trench portion is sufficiently weak, the electric field relaxation trench portion 230 may be provided only for purpose of providing the trench bottom region 201-3 to be provided continuously with the trench bottom regions 201-1 and 201-2.

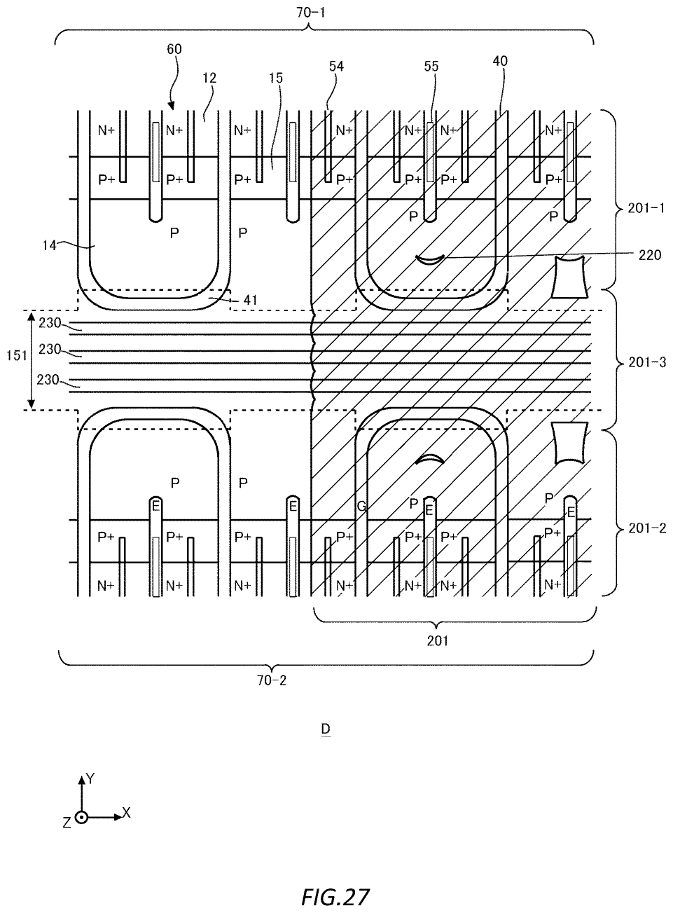

FIG. 27 is a view illustrating another structure example of the region D. In the present example, a shape of the semiconductor gate runner 151 is different from that of the example of FIG. 26. Other structures are similar to those of the example of FIG. 26. In the semiconductor gate runner 151 of the present example, a part opposing the gate trench portion 40 in the Y axis direction protrudes in a direction of the gate trench portion 40 as compared with a part not opposing the gate trench portion 40. Each gate trench portion 40 may be connected to the semiconductor gate runner 151 at a position overlapping a protruding part of the semiconductor gate runner 151. With this configuration, a capacitance of the semiconductor gate runner 151 can be adjusted.

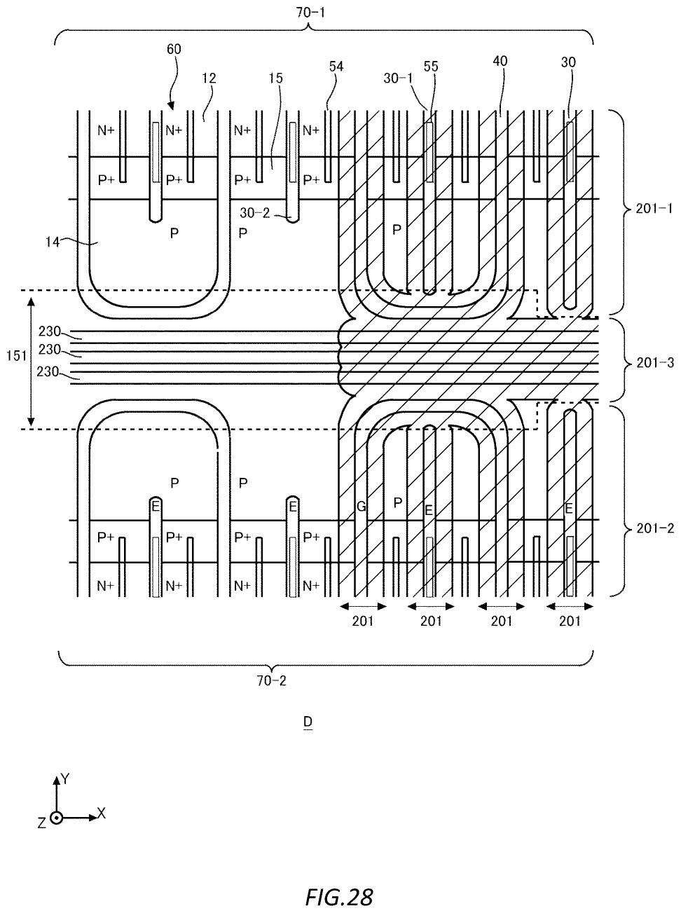

FIG. 28 is a view illustrating another structure example of the region D. In the present example, the trench bottom region 201 is arranged in the vicinity of the trench portion in the X axis direction, and is not arranged at the center of the mesa portion 60 in the X axis direction. Other structures are similar to those of the example of FIG. 26 or FIG. 27. As described above, when the diffusion length of the dopants forming the trench bottom region 201 is short, the structure as illustrated in FIG. 28 is obtained.

Also in the present example, similarly to the example of FIG. 23 or the like, the dummy trench portion 30 provided with the trench bottom region 201 may extend to the edge portion 41 or a vicinity of the electric field relaxation trench portion 230, compared to the dummy trench portion 30 not provided with the trench bottom region 201. With this configuration, the trench bottom region 201 is easily connected between the dummy trench portion 30 and the edge portion 41. In the present example, the non-formation region 220 is not provided between the dummy trench portion 30 and the edge portion 41 or the electric field relaxation trench portion 230. At this time, the semiconductor gate runner 151 may be retracted in the Y axis direction in a vicinity of the dummy trench portion 30, such that the semiconductor gate runner 151 and the dummy trench portion 30 are not connected.

In order to relax the electric field, even the dummy trench portion 30 not provided with the trench bottom region 201 may extend to the edge portion 41 or the vicinity of the electric field relaxation trench portion 230 in the Y axis direction. In a vicinity of the dummy trench portion 30 not provided with the trench bottom region 201, the semiconductor gate runner 151 may be retracted in the Y axis direction. Even in the example described with reference to FIGS. 26 to 28 in which the gate trench portions 40 of the transistor portions 70-1 and 70-2 are not connected, the electric field relaxation trench portion 230 extending in the Y axis direction described with reference to FIGS. 23 to 25 may be used. Even in the example described with reference to FIGS. 23 to 25 in which the gate trench portions 40 of the transistor portions 70-1 and 70-2 are connected, the electric field relaxation trench portion 230 extending in the X axis direction described with reference to FIGS. 26 to 28 may be used.

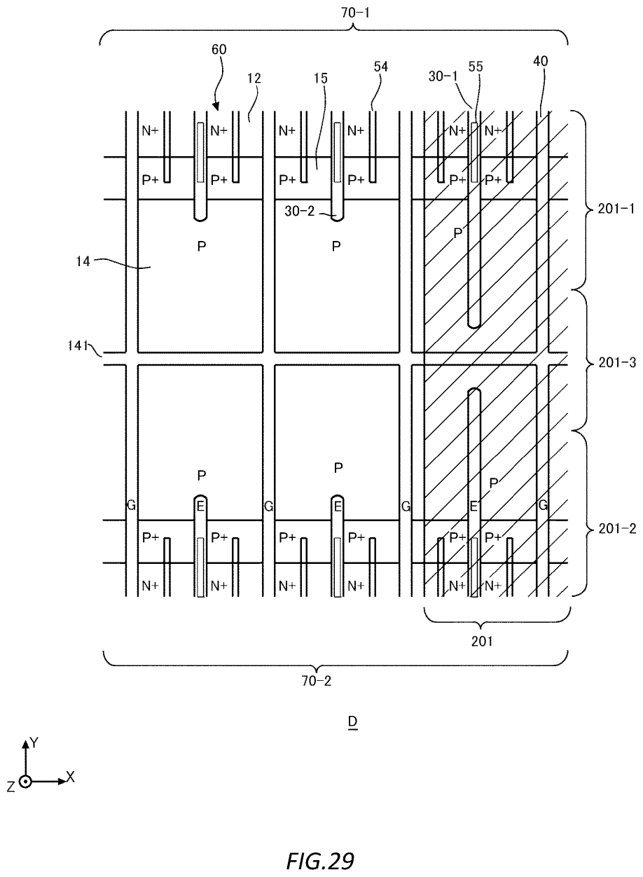

FIG. 29 is a view illustrating another structure example of the region D. In the present example, the trench wiring 141 is provided as the first active gate runner. The trench wiring 141 may be continuously provided in the X axis direction so as to cross the active portion 160.

Each gate trench portion 40 is connected to the trench wiring 141. Each dummy trench portion 30 terminates in the Y axis direction at a position apart from the trench wiring 141.

The trench bottom region 201-1 is provided for at least one gate trench portion 40 of the transistor portion 70-1. In addition, the trench bottom region 201-2 is also provided for at least one gate trench portion 40 of the transistor portion 70-2. These gate trench portions 40 are aligned in the Y axis direction and extend to the trench wiring 141. With this configuration, the trench bottom regions 201-1, 201-3, and 201-2 can be continuously formed in the Y axis direction.

The dummy trench portion 30-1 provided with the trench bottom region 201 may extend to a vicinity of the trench wiring 141 as compared with the dummy trench portion 30-2 not provided with the trench bottom region 201. With this configuration, it is easy to connect the trench bottom region 201 of the dummy trench portion 30 and the trench bottom region 201 of the trench wiring 141. In another example, any of the electric field relaxation trench portions 230 described above may be provided for the dummy trench portion 30.

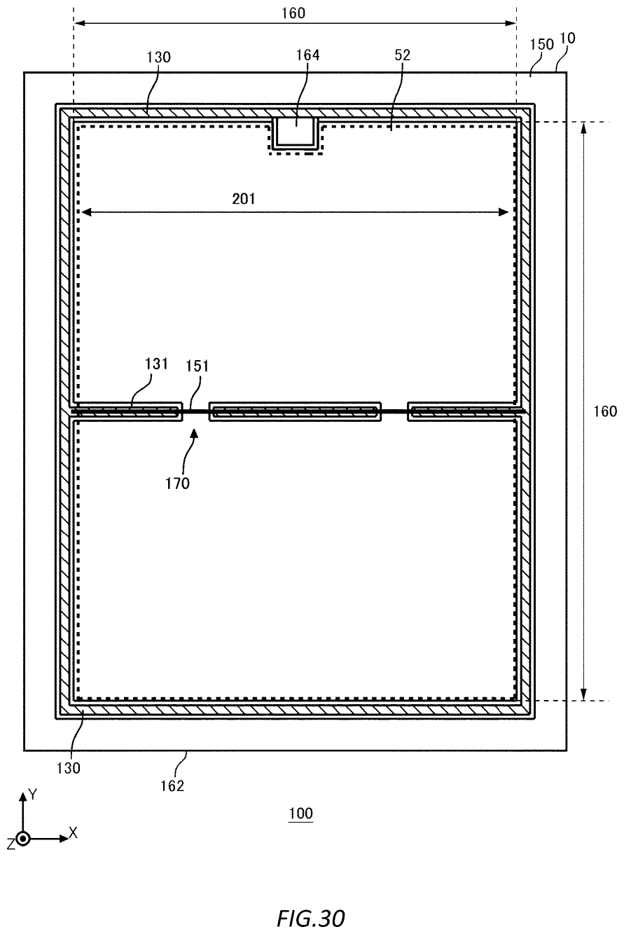

FIG. 30 is a view illustrating a structure example of a region where the trench bottom region 201 can be provided and the first active gate runner. The region where the trench bottom region 201 can be provided is indicated by a broken line. The trench bottom region 201 of the present example may be provided over substantially the entire active portion 160. As described with reference to FIGS. 17 to 29, the trench bottom region 201 may be provided in a part of the transistor portion 70 or may be provided in the entire transistor portion 70. The trench bottom region 201 may or may not be provided in the diode portion 80.

The first active gate runners of the present example include the first metal gate runners 131 discretely arranged in the X axis direction, and the semiconductor gate runner 151 arranged to cross the active portion 160 in the X axis direction. A structure of the spacing portion 170 is similar to that of the examples described with reference to FIGS. 1 to 16, but the trench bottom region 201 is also provided in the spacing portion 170. In the spacing portion 170 of the present example, the trench portion of the transistor portion 70 may be provided. The trench bottom region 201 may be provided for each trench portion passing through the spacing portion 170.

In the present example, a well region having the same conductivity type as that of the trench bottom region 201 is not provided below the first active gate runner. Below the first active gate runner, the trench bottom regions 201 are connected to each other as described with reference to FIGS. 17 to 29.

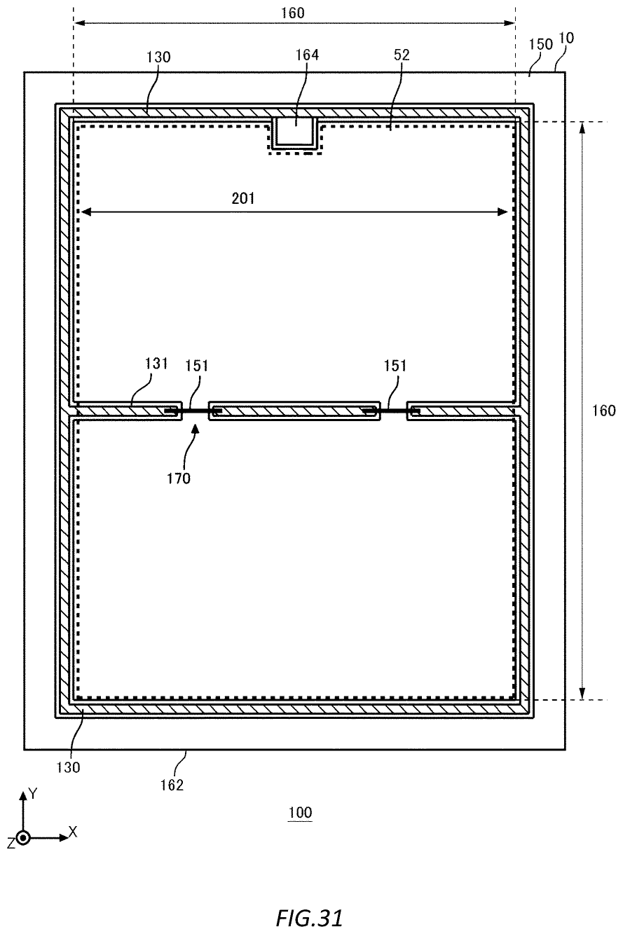

FIG. 31 is a view illustrating another structure example of the region where the trench bottom region 201 can be provided and the first active gate runner. In the present example, arrangement of the semiconductor gate runners 151 is different from that of the example of FIG. 30. Other structures are similar to those of the example of FIG. 30. The semiconductor gate runner 151 connects two first metal gate runners 131 sandwiching the spacing portion 170. The semiconductor gate runner 151 of the present example is provided only in a vicinity of the spacing portion 170.

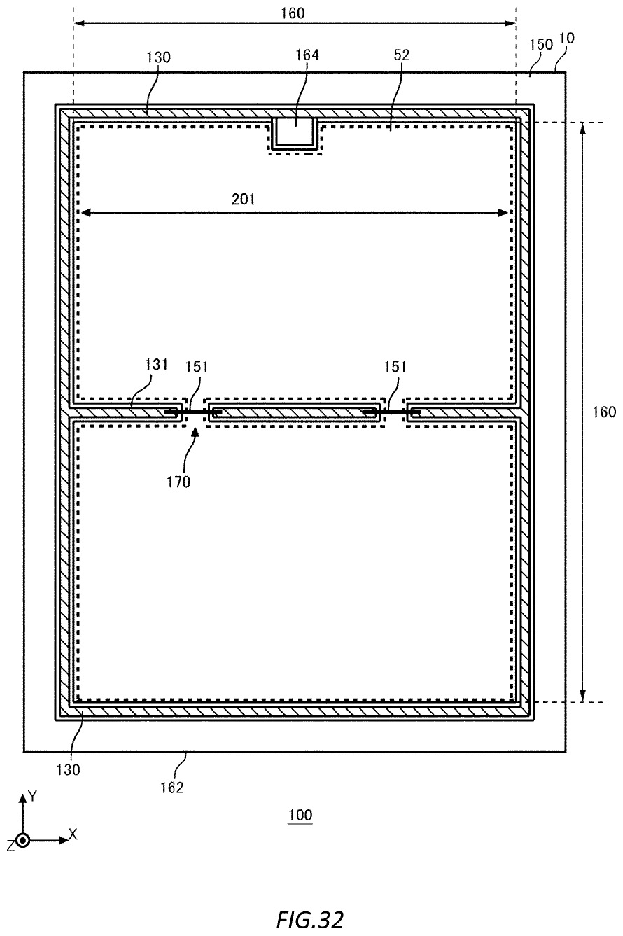

FIG. 32 is a view illustrating another structure example of the region where the trench bottom region 201 can be provided and the first active gate runner. The ground well region 11 may be provided below the first metal gate runner 131 of the present example. The trench bottom region 201 is not connected to the ground well region 11. Therefore, in the present example, the trench bottom regions 201 are not connected below the first metal gate runner 131. In the spacing portion 170, the ground well region 11 is not provided. The trench bottom region 201 is provided to pass below the semiconductor gate runner 151 in the spacing portion 170 in the Y axis direction.

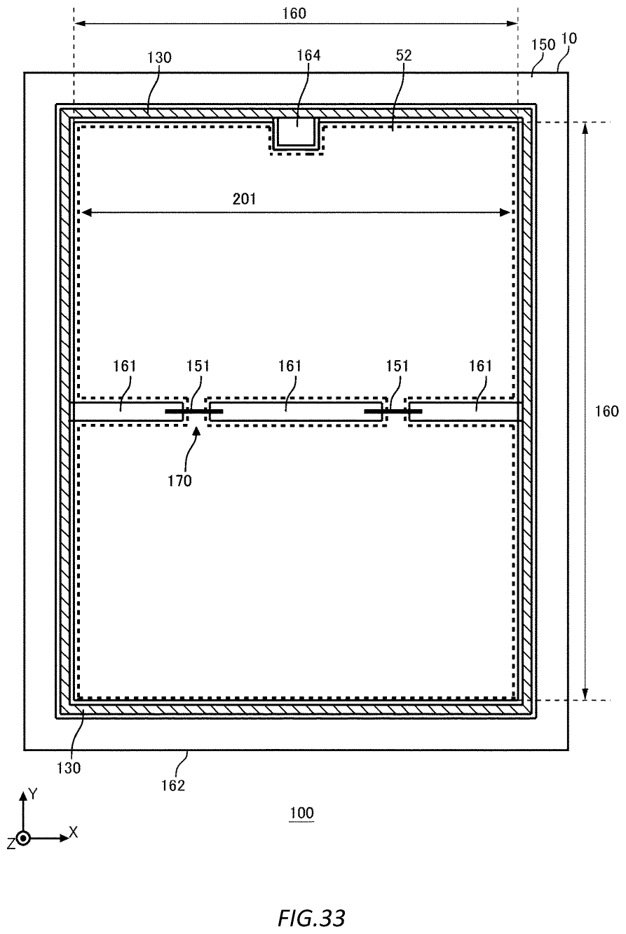

FIG. 33 is a view illustrating another structure example of the region where the trench bottom region 201 can be provided and the first active gate runner. The first active gate runner of the present example includes a semiconductor gate runner 161 and the semiconductor gate runner 151. The semiconductor gate runner 161 is provided instead of the first metal gate runner 131 in the example of FIG. 31. The ground well region 11 is provided below the semiconductor gate runner 161. A range of the trench bottom region 201 of the present example is similar to that of the example of FIG. 31. In each example of FIGS. 30 to 33, the trench wiring 141 may be provided instead of the semiconductor gate runner 151. In each example of FIGS. 30 to 33, the diode portion 80 may not be provided in the active portion 160.

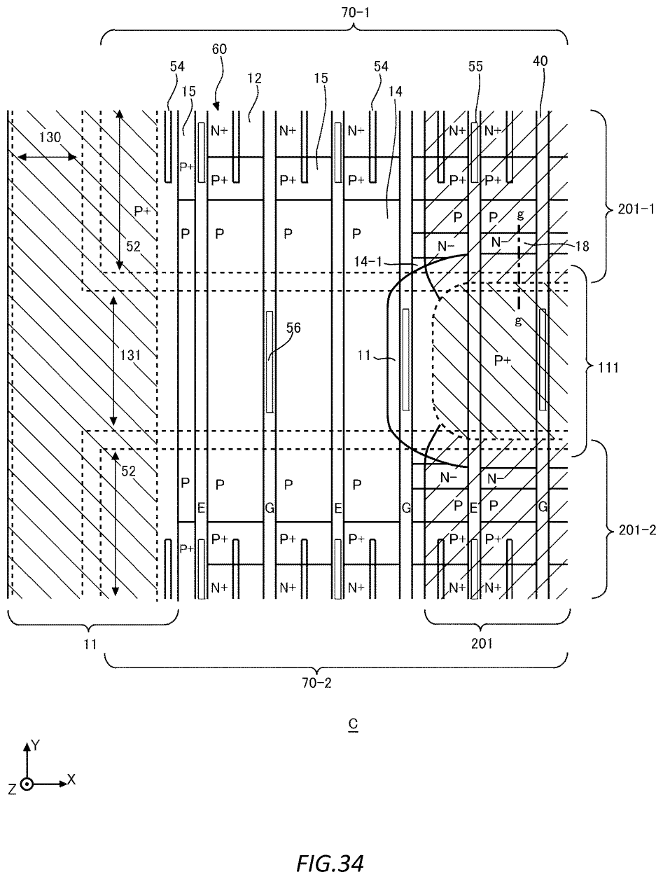

FIG. 34 is a view illustrating another structure example of the region C. In the present example, compared to the example illustrated in FIG. 18, a floating well region 111 is provided instead of the trench bottom region 201-1. In each drawing, the floating well region 111 at the upper surface 21 of the semiconductor substrate 10 may be indicated by a solid line, and the floating well region 111 at the depth position of the lower end of the trench portion may be indicated by a broken line. A region where the floating well region 111 is provided at the depth position of the lower end of the trench portion is indicated by hatching with oblique lines having a direction different from that of the trench bottom region 201.

The floating well region 111 has the same conductivity type as that of the trench bottom region 201, and is provided in a depth range different from that of the trench bottom region 201. That is, the floating well region 111 includes a part provided at a depth different from that of the trench bottom region 201. The floating well region 111 is electrically floating. The floating well region 111 is provided in a region overlapping the first metal gate runner 131 in top view. The floating well region 111 may be provided to an outside of the first metal gate runner 131 in the Y axis direction. In addition, a region of the N type such as the drift region 18 or a trench portion is provided between the floating well region 111 and the base region 14 continuous from the active portion 160.

In the present example, a part of the floating well region 111 separated by the trench portion is provided as the ground well region 11 in contact with the base region 14. Even in such a case, the floating well region 111 connected to the trench bottom regions 201-1 and 201-2 is electrically separated from the base region 14 continuous from the active portion 160.

In another example, the ground well region 11 may not be formed. That is, in the floating well region 111, a well region which is separated by the trench portion and not connected to the trench bottom regions 201-1 and 201-2 may also be separated from the base region 14 continuous from the active portion 160. A region of the N type such as the drift region 18 or a trench portion may be provided between the well region and the base region 14. With this configuration, the well region may be floating. In addition, a part of the floating well region 111 may not be separated by the trench portion, or the well region not connected to the trench bottom regions 201-1 and 201-2 may not be formed. In addition, the floating well region 111 may be in contact with another region of a same conductivity type that is not electrically connected to the emitter electrode 52. In the present example, a floating base region 14-1 not connected to the active portion 160 is in contact with the floating well region 111. The floating base region 14-1 in the present example is detached from the base region 14 continuous from the active portion 160 by the drift region 18 and the trench portion. Not limited to the floating base region 14-1, for example, a floating surface region 202-1 may be provided in contact with the floating well region 111. The surface region 202-1 may be formed by performing, on the upper surface 21, the ion implantation when the trench bottom region 201 is formed. In another example, the floating well region 111 may not be in contact with another region of the same conductivity type that is not electrically connected to the emitter electrode 52.

In the examples of FIGS. 18 to 33, the well region of the same conductivity type as that of the trench bottom region 201 is not provided in a region overlapping the first active gate runner, the well region being exposed on the upper surface 21 of the semiconductor substrate 10 and formed to a depth greater than that of the trench portion. Then, two trench bottom regions 201-1 and 201-2 sandwiching the first active gate runner in the Y axis direction are connected to each other by the trench bottom region 201-3 below the first active gate runner. In the present example, the two trench bottom regions 201-1 and 201-2 sandwiching the first active gate runner in the Y axis direction are connected via the floating well region 111.

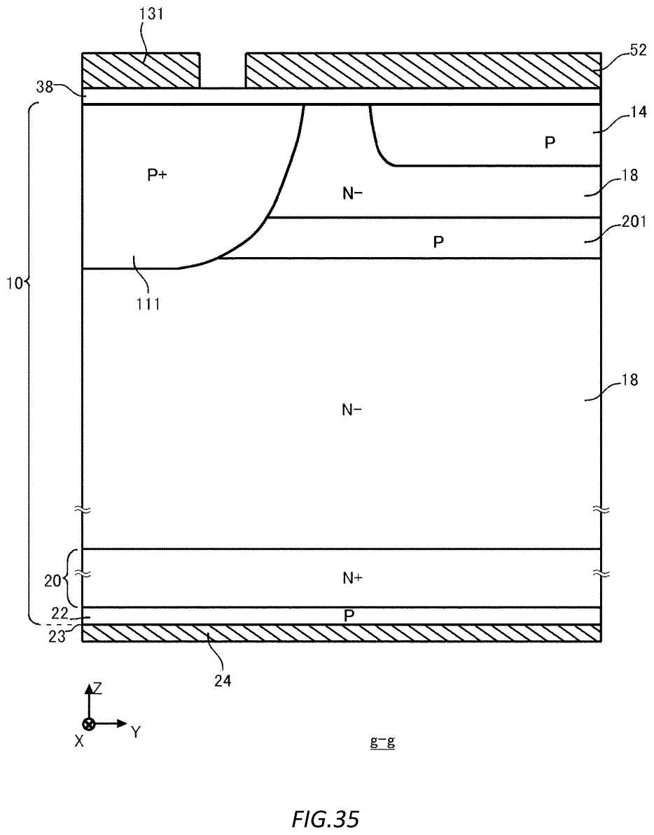

FIG. 35 is a view illustrating an example of a cross section g-g in FIG. 34. The cross section g-g is a YZ cross section including the floating well region 111, the trench bottom region 201, and the base region 14. As described above, the trench bottom region 201 is connected to the floating well region 111. In addition, the floating well region 111 has a part provided in a depth range different from that of the trench bottom region 201. For example, the floating well region 111 is in contact with the upper surface 21 of the semiconductor substrate 10, but the trench bottom region 201 is not in contact with the upper surface 21 of the semiconductor substrate 10. The floating well region 111 may have a doping concentration which is different from or the same as that of the trench bottom region 201.

The floating well region 111 is separated from the base region 14 continuous with the active portion 160. A region of the N type may be interposed between the floating well region 111 and the base region 14 continuous with the active portion 160. In the present example, the drift region 18 is provided between the floating well region 111 and the base region 14 continuous with the active portion 160.

The trench bottom region 201 and the base region 14 are also separated. A region of the N type may be interposed between the trench bottom region 201 and the base region 14. In the present example, the drift region 18 is provided between the trench bottom region 201 and the base region 14. With this configuration, the floating well region 111 and the trench bottom region 201 can be electrically floating.

The floating well region 111 may be provided in a same depth range as that of the ground well region 11. With this configuration, an additional step for forming the floating well region 111 may not be provided. The floating well region 111 may have a same doping concentration as that of the ground well region 11.

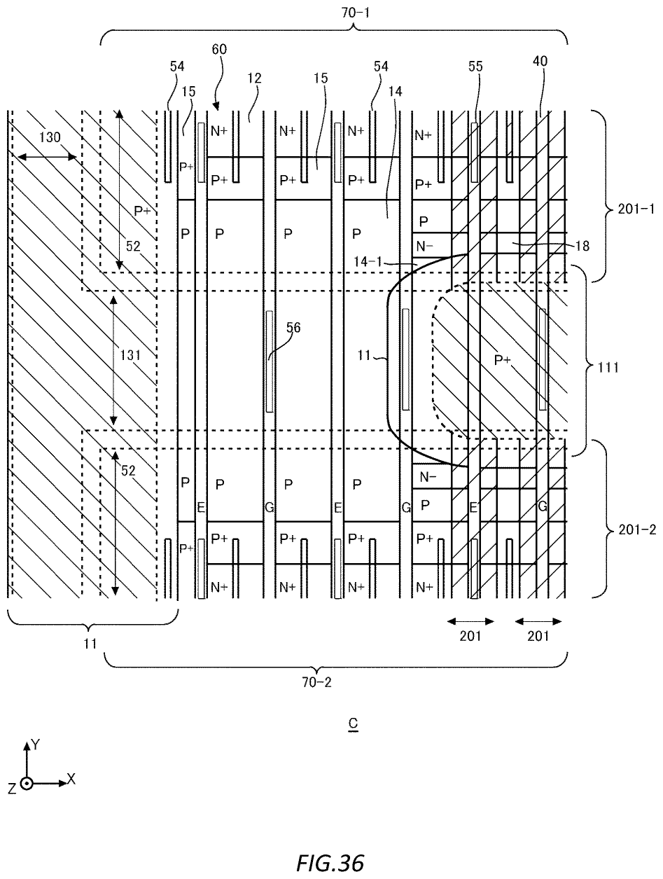

FIG. 36 is a view illustrating another structure example of the region C. In the present example, the trench bottom region 201 is arranged in the vicinity of the trench portion in the X axis direction, and is not arranged at the center of the mesa portion 60 in the X axis direction. Other structures are similar to those of the examples of FIGS. 34 and 35. As described above, when the diffusion length of the dopants forming the trench bottom region 201 is short, the structure as illustrated in FIG. 36 is obtained.

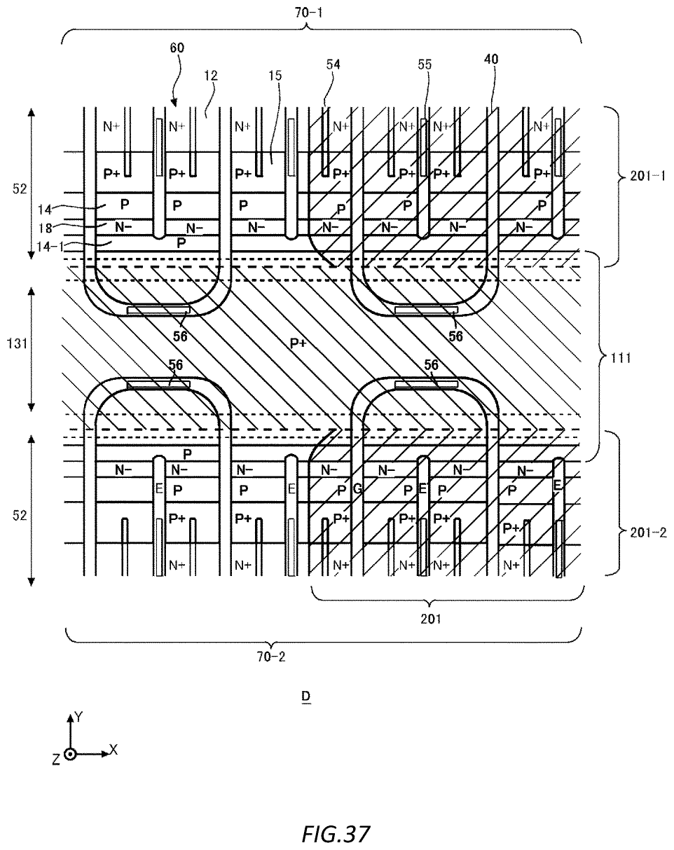

FIG. 37 is a view illustrating another structure example of the region D. In the present example, the floating well region 111 is provided instead of the trench bottom region 201-3 in the example illustrated in FIG. 21. In addition, the floating base region 14-1 and the drift region 18 are provided between the floating well region 111 and the base region 14. The floating base region 14-1 in contact with the floating well region 111 may not be provided. Other structures are similar to those of the example of FIG. 21.

As illustrated in FIG. 37, a width of the floating well region 111 in the X axis direction may be larger than widths of the trench bottom region 201-1 and the trench bottom region 201-2. The floating well region 111 may be provided continuously in the X axis direction within a range not connected to the ground well region 11. As illustrated in FIG. 34, the width of the floating well region 111 in the X axis direction may be the same as or smaller than the widths of the trench bottom region 201-1 and the trench bottom region 201-2. In this case, when a plurality of trench bottom regions 201-1 and a plurality of trench bottom regions 201-2 are discretely arranged in the X axis direction, a plurality of floating well regions 111 may also be discretely arranged in the X axis direction along the first active gate runner.

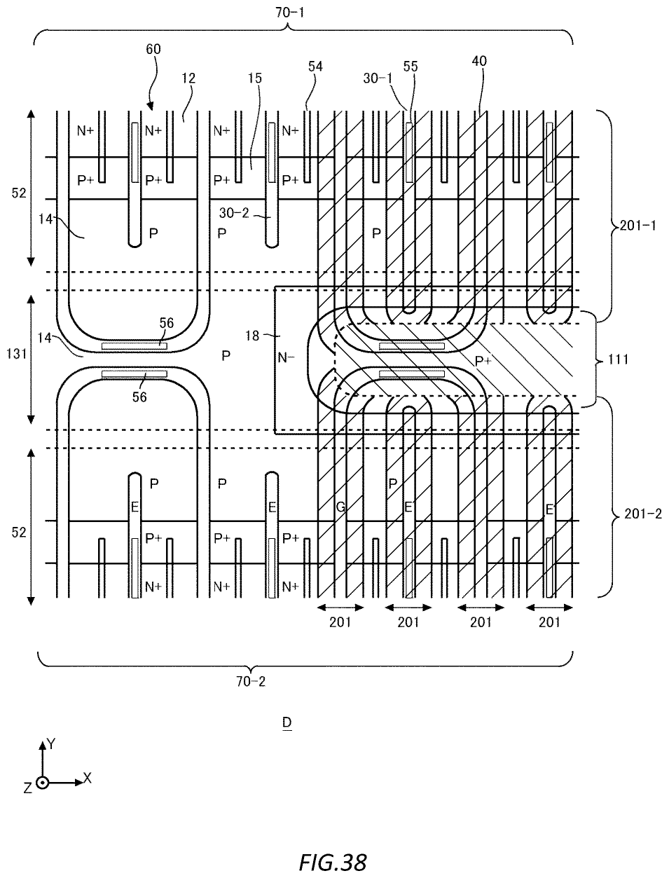

FIG. 38 is a view illustrating another structure example of the region D. In the present example, the floating well region 111 is provided instead of the trench bottom region 201-3 in the example illustrated in FIG. 22. In addition, the drift region 18 is provided between the floating well region 111 and the base region 14. In FIG. 34, the floating well region 111 and the base region 14 are detached from each other by the trench portion in the X axis direction. In the present example, the floating well region 111 and the base region 14 are detached from each other by the drift region 18. In addition, in the present example, the width of the floating well region 111 is narrower than the first metal gate runner 131 in the Y axis direction, and the lower end of the dummy trench portion 30 is not covered with the floating well region 111. In another example, the width of the floating well region 111 may be wider than the first metal gate runner 131 in the Y axis direction, or the lower end of the dummy trench portion 30 may be covered with the floating well region 111. Other structures are similar to those of the example of FIG. 22.

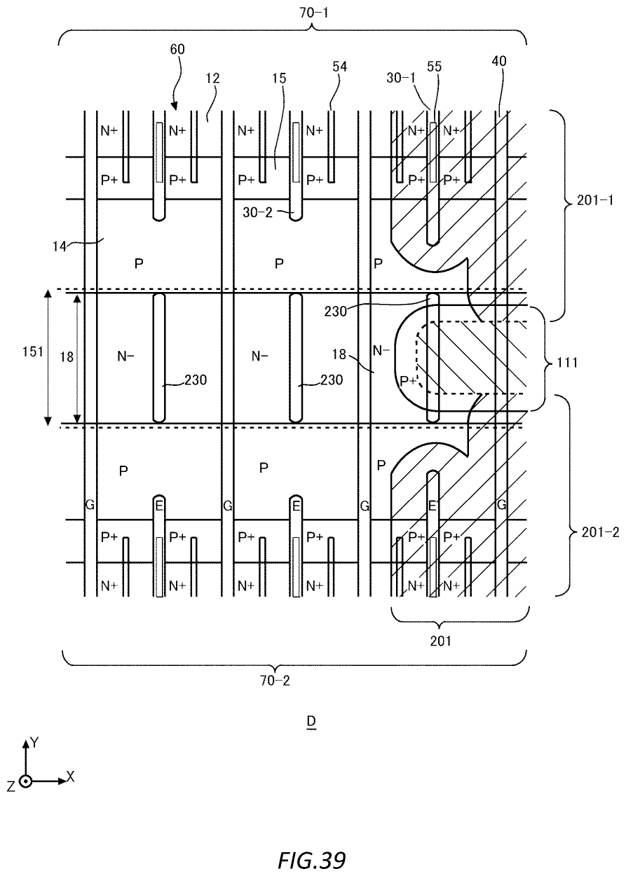

FIG. 39 is a view illustrating another structure example of the region D. In the present example, the floating well region 111 is provided instead of the trench bottom region 201-3 in the example illustrated in FIG. 23. In addition, the drift region 18 is provided between the floating well region 111 and the base region 14. In the present example, the floating well region 111 is formed to be narrower than the semiconductor gate runner 151. By forming the base region 14 after forming the semiconductor gate runner 151, the base region 14 can be formed using the semiconductor gate runner 151 as a mask. With this configuration, the drift region 18 remains below the semiconductor gate runner 151. Therefore, it is possible to form a region in which the drift region 18 surrounds the floating well region 111 and is exposed to the upper surface 21. In another example, the floating well region 111 may be formed to be wider than the semiconductor gate runner 151. In the present example, the trench bottom regions 201 of the dummy trench portions 30 are connected via the trench bottom region 201 of the gate trench portion 40. However, the trench bottom region 201 of the dummy trench portion 30 may take various forms depending on a forming method and a shape of the floating well region 111 and a position of a terminal end of the dummy trench portion 30. Other structures are similar to those of the example of FIG. 23.

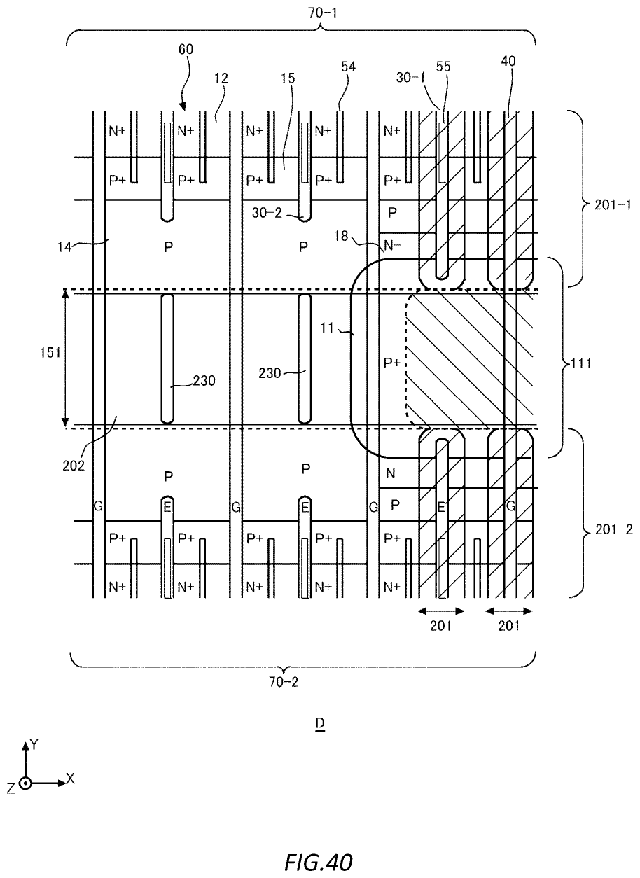

FIG. 40 is a view illustrating another structure example of the region D. In the present example, the floating well region 111 is provided instead of the trench bottom region 201-3 in the example illustrated in FIG. 24. In addition, the drift region 18 or the trench portion is provided between the floating well region 111 and the base region 14. In addition, since the trench bottom regions 201-1 and 201-2 are connected by the floating well region 111, the electric field relaxation trench portion 230 may not be provided inside the floating well region 111. Other structures are similar to those of the example of FIG. 24.

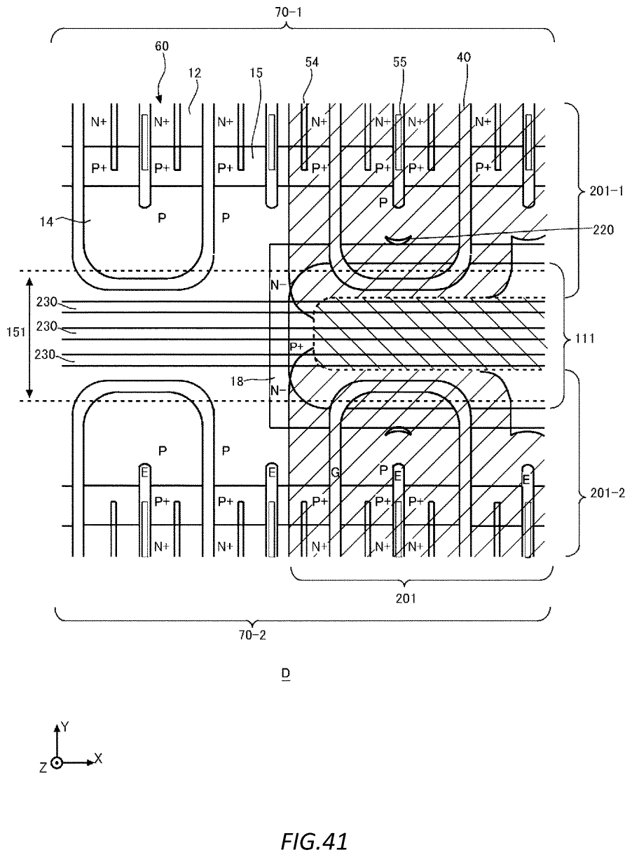

FIG. 41 is a view illustrating another structure example of the region D. In the present example, the floating well region 111 is provided instead of the trench bottom region 201-3 in the example illustrated in FIG. 26. In addition, the drift region 18 is provided between the floating well region 111 and the base region 14. Other structures are similar to those of the example of FIG. 26.

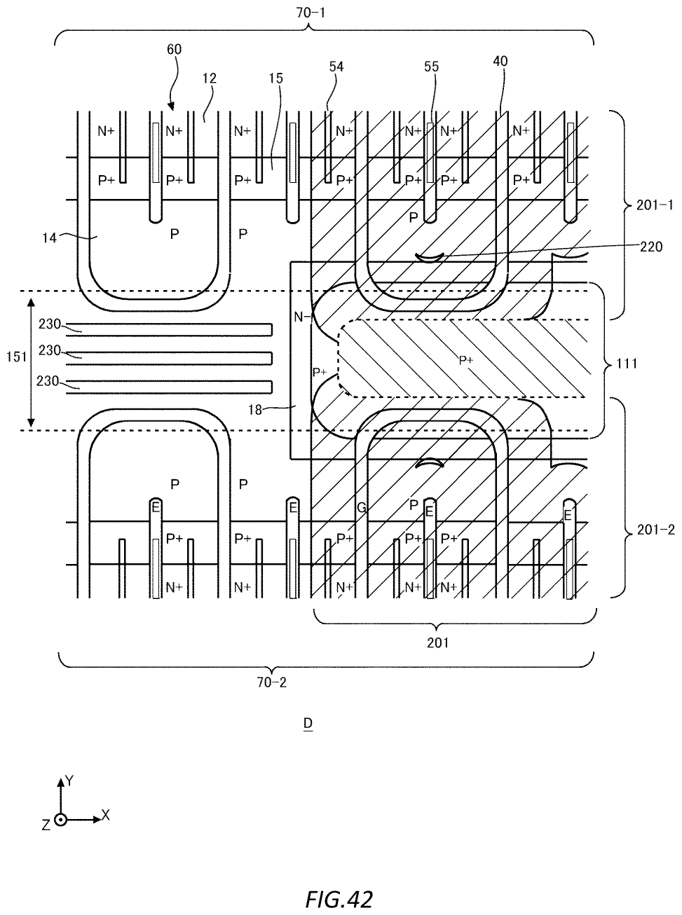

FIG. 42 is a view illustrating another structure example of the region D. In the present example, arrangement of the electric field relaxation trench portion 230 is different from that of the example of FIG. 41. Other structures are similar to those of the example of FIG. 41. The electric field relaxation trench portion 230 of the present example is provided in a range not overlapping the floating well region 111.

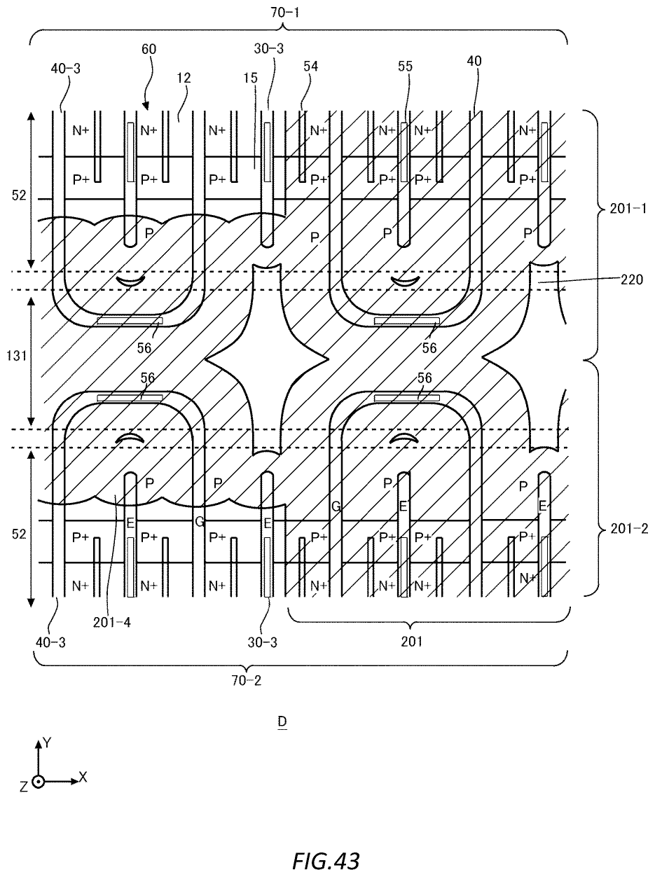

FIG. 43 is a view illustrating another structure example of the region D. The transistor portion 70 of the present example includes a gate trench portion 40-3 in which the trench bottom region 201 is provided at an end portion on a first active gate runner side and the trench bottom region 201 is not provided in at least a partial region other than the end portion.

The gate trench portion 40-3 of transistor portion 70-1 and the gate trench portion 40-3 of transistor portion 70-2 are arranged below the first metal gate runner 131 so as to oppose each other in the Y axis direction. In the present example, the trench bottom regions 201 at the end portions of two gate trench portions 40-3 are connected in a region of a same conductivity type (the trench bottom region 201-3 in the present example) below the first metal gate runner 131.

The trench bottom region 201 provided at the end portion of the gate trench portion 40-3 may be connected to the trench bottom region 201 of another trench portion (the dummy trench portion 30-3 in the present example) adjacent in the X axis direction. Also in the dummy trench portion 30-3, the trench bottom region 201 may not be provided in at least a partial region other than the end portion. The trench bottom region 201 at the end portion of the dummy trench portion 30-3 of the transistor portion 70-1 and the trench bottom region 201 at the end portion of the dummy trench portion 30-3 of the transistor portion 70-2 may be connected below the first metal gate runner 131. As described above, even in the gate trench portion 40 and the dummy trench portion 30 in which the trench bottom region 201 is not provided other than the end portion in the Y axis direction arranged in the active portion 160, providing the trench bottom region 201 at the end portion can reduce the electric field strength at the lower end of the end portion of the trench portion.

The trench bottom region 201 selectively provided at the end portion of the trench portion may be connected in the X axis direction to the trench bottom region 201 provided over an entire length of the trench portion in the Y axis direction. The length of the trench bottom region 201 in the Y axis direction may be different depending on a position in the X axis direction.

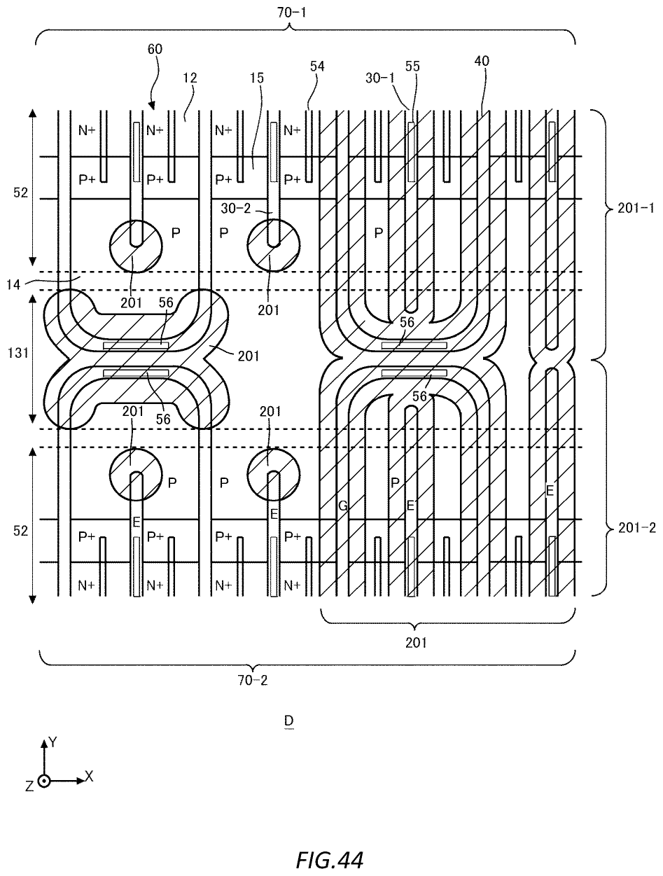

FIG. 44 is a view illustrating another structure example of the region D. In the present example, a plurality of trench bottom regions 201 are discretely arranged in top view. In each example described in the present specification, the trench bottom regions 201 may be discretely arranged.

In the present example, the trench bottom region 201 selectively formed at the end portion of the dummy trench portion 30 in the Y axis direction is not connected to another trench bottom region 201. In addition, the trench bottom regions 201 provided at respective end portions of two gate trench portions 40 opposing each other in the Y axis direction are connected to each other, but are not connected to the trench bottom region 201 of another trench portion. Also in the present example, even in the gate trench portion 40 and the dummy trench portion 30 in which the trench bottom region 201 is not provided other than the end portion in the Y axis direction arranged in the active portion 160, providing the trench bottom region 201 at the end portion can reduce the electric field strength at the lower end of the end portion of the trench portion.

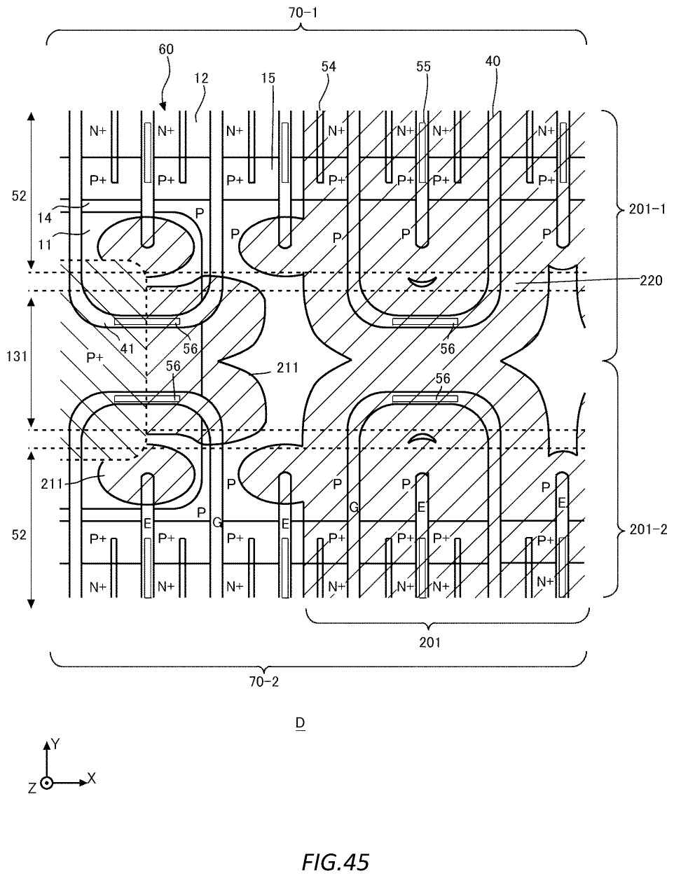

FIG. 45 is a view illustrating another structure example of the region D. The semiconductor device 100 of the present example has the trench bottom region 211 connected to an emitter potential. The trench bottom region 211 has a structure similar to that of the trench bottom region 201, but differs in applied potential from the trench bottom region 201. The trench bottom region 201 is electrically floating.

The trench bottom region 211 may be selectively provided at the end portion of the trench portion in the Y axis direction. The trench bottom region 211 may be provided at end portions of two trench portions sandwiching the first active gate runner in the Y axis direction. In the trench portion, the trench bottom region 211 may not be provided in at least a partial region other than the end portion. The trench bottom region 211 of the present example may be connected to the ground well region 11. As described above, providing the ground well region 11 and the trench bottom region 211 at the end portions of the gate trench portion 40 and the dummy trench portion 30 can reduce the electric field strength at the lower end of the end portion of the trench portion. In another example, the electric field strength may be reduced by the floating well region 111 and the trench bottom region 201 instead of the ground well region 11 and the trench bottom region 211. Note that the reduction of the electric field strength at the lower end of the end portion of the trench portion described with reference to FIGS. 44 and 45 may be applied not only in a vicinity of the first active gate runner but also in the vicinity of the outer circumferential gate runner 130.

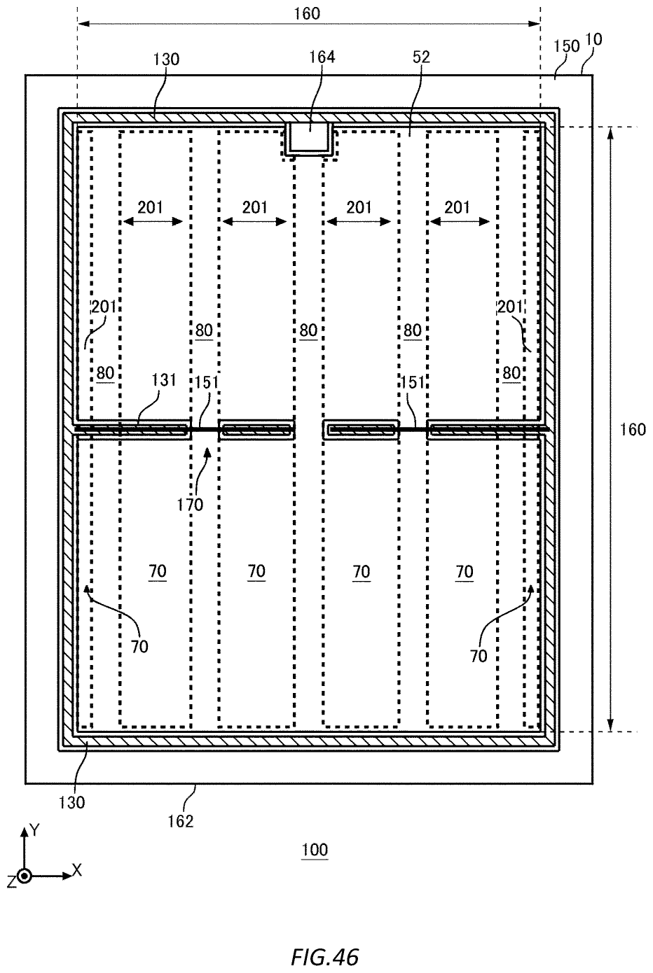

FIG. 46 is a view illustrating another structure example of the region where the trench bottom region 201 can be provided and the first active gate runner. The active portion 160 in the present example is provided with the transistor portion 70 and the diode portion 80. The ground well region 11 is not provided below the first metal gate runner 131 of the present example. In addition, the semiconductor gate runner 151 is provided below the first metal gate runner 131. The trench bottom region 201 of the present example may be provided over substantially the entire transistor portion 70. The trench bottom region 201 may not be provided in the diode portion 80. The trench bottom region 201 of the present example passes below the first metal gate runner 131 and the semiconductor gate runner 151. In addition, the diode portion 80 is provided at a position opposing the spacing portion 170 in the Y axis direction. Therefore, the trench bottom region 201 is not provided in the spacing portion 170. Note that the trench bottom regions 201 of the transistor portions 70 adjacent to each other in the X axis direction may be connected to each other in a region in contact with an end portion of the diode portion 80 in the Y axis direction. The collector region 22 may be formed on a lower surface side of a region which is in contact with the end portion of the diode portion 80 and continuous to the trench bottom region 201. The region which is in contact with the end portion of the diode portion 80 and continuous to the trench bottom region 201 may be in the vicinity of the first active gate runner or in the vicinity of the outer circumferential gate runner 130. In addition, the trench bottom region 201 connecting the transistor portions 70 adjacent to each other in the X axis direction may be arranged so as to cross a central portion of the diode portion 80 in the Y axis direction. In the present example, since the ground well region 11 is not provided below the first active gate runner, the trench bottom region 201 may be connected in the X axis direction below the first active gate runner.

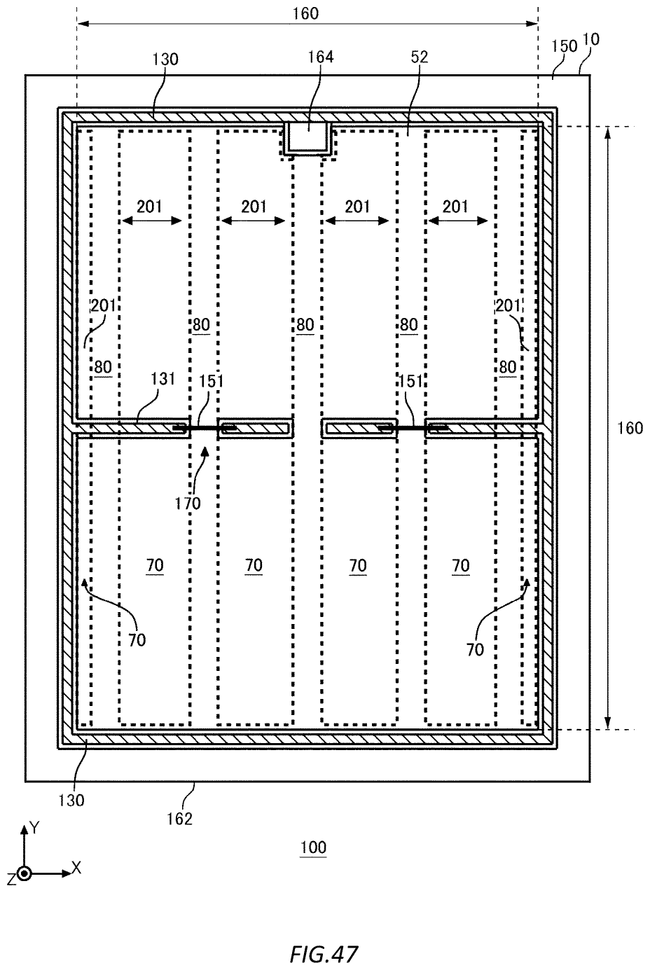

FIG. 47 is a view illustrating another structure example of the region where the trench bottom region 201 can be provided and the first active gate runner. In the present example, arrangement of the semiconductor gate runner 151 is different from that of the example of FIG. 46. Other structures are similar to those of the example of FIG. 46. The semiconductor gate runner 151 connects two first metal gate runners 131 sandwiching the spacing portion 170. The semiconductor gate runner 151 of the present example is provided only in the vicinity of the spacing portion 170.

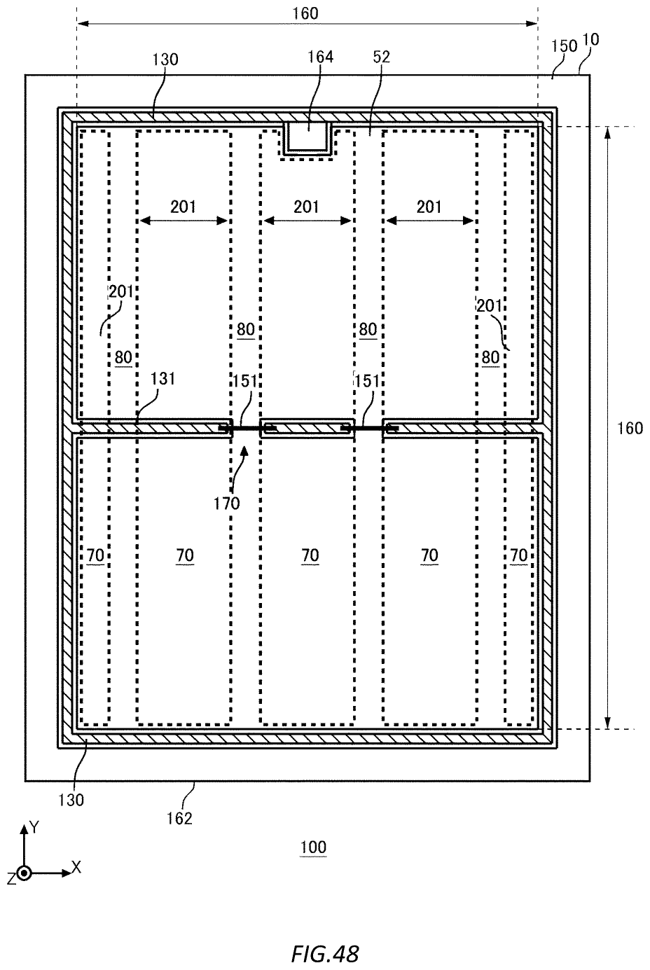

FIG. 48 is a view illustrating another structure example of the region where the trench bottom region 201 can be provided and the first active gate runner. In the present example, a number of at least one spacing portion 170 discretely arranged in the X axis direction is different from that in the example of FIG. 47. Other structures are similar to those of the example of FIG. 47. Note that the spacing portion 170 in the present example is not located at a center of the first active gate runner in the X axis direction. In addition, the semiconductor gate runner 151 may not be provided in one of the spacing portions 170. In addition, as in the example of FIG. 46, the semiconductor gate runner 151 may be provided entirely below the first metal gate runner 131.

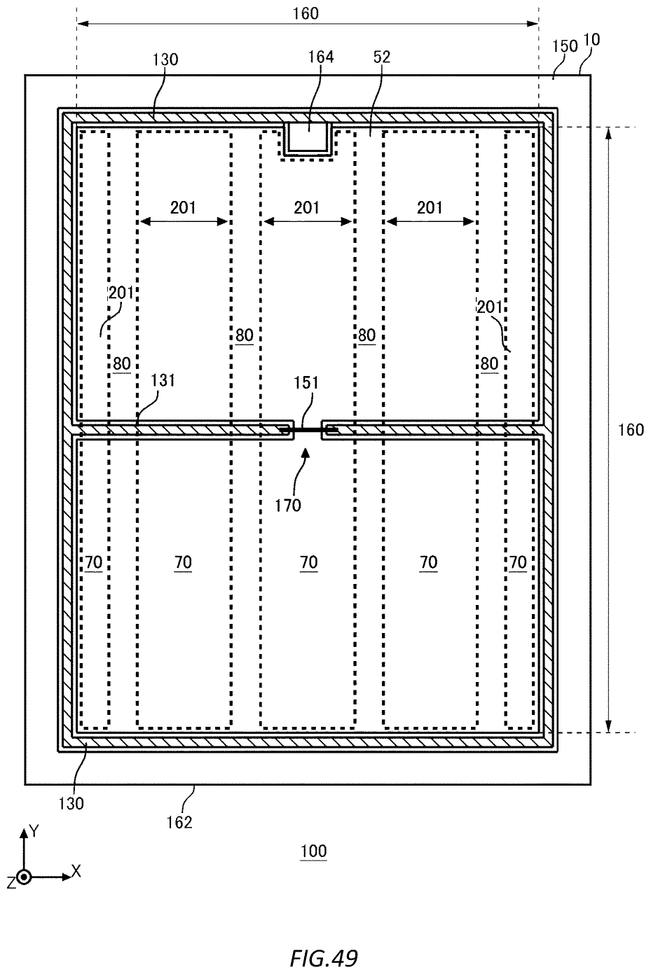

FIG. 49 is a view illustrating another structure example of the region where the trench bottom region 201 can be provided and the first active gate runner. In the present example, the transistor portion 70 is provided at the position opposing the spacing portion 170 in the Y axis direction. In the present example, the spacing portion 170 is also provided with the trench bottom region 201.

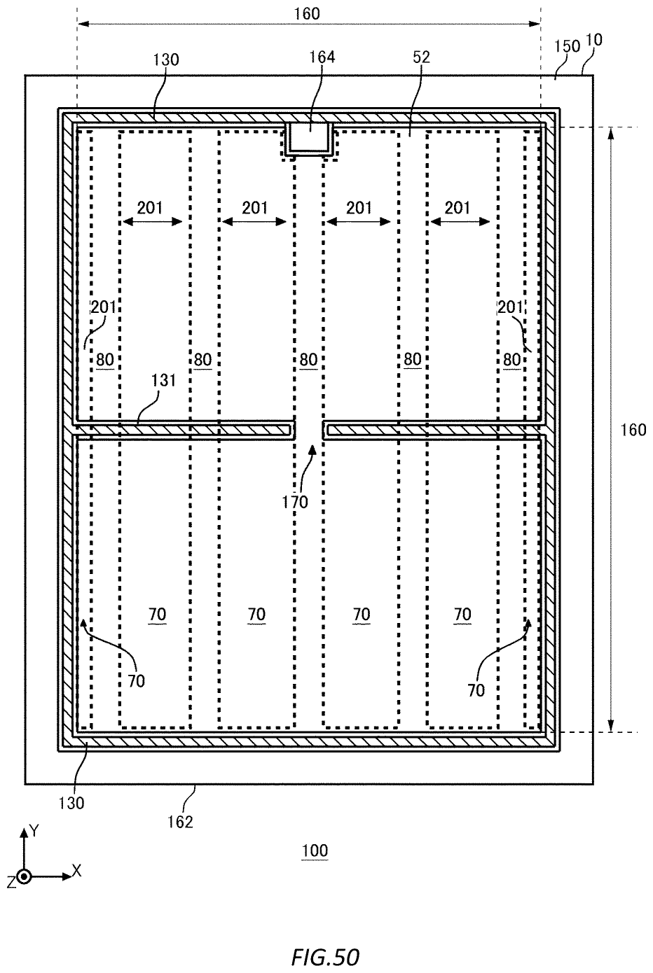

FIG. 50 is a view illustrating another structure example of the region where the trench bottom region 201 can be provided and the first active gate runner. In the present example, only one spacing portion 170 is provided. Each of two first metal gate runners 131 sandwiching the spacing portion 170 is connected to the outer circumferential gate runner 130. Since the spacing portion 170 of the present example is provided between the diode portions 80, the semiconductor gate runner 151 connecting the two first metal gate runners 131 may not be provided. Arrangement of the trench bottom region 201 is similar to that in any of the examples of FIGS. 46 to 49. In another example, the semiconductor gate runner 151 may be provided in the spacing portion 170, or the first metal gate runner 131 may be provided to cross the active portion 160 in the X axis direction without providing the spacing portion 170.

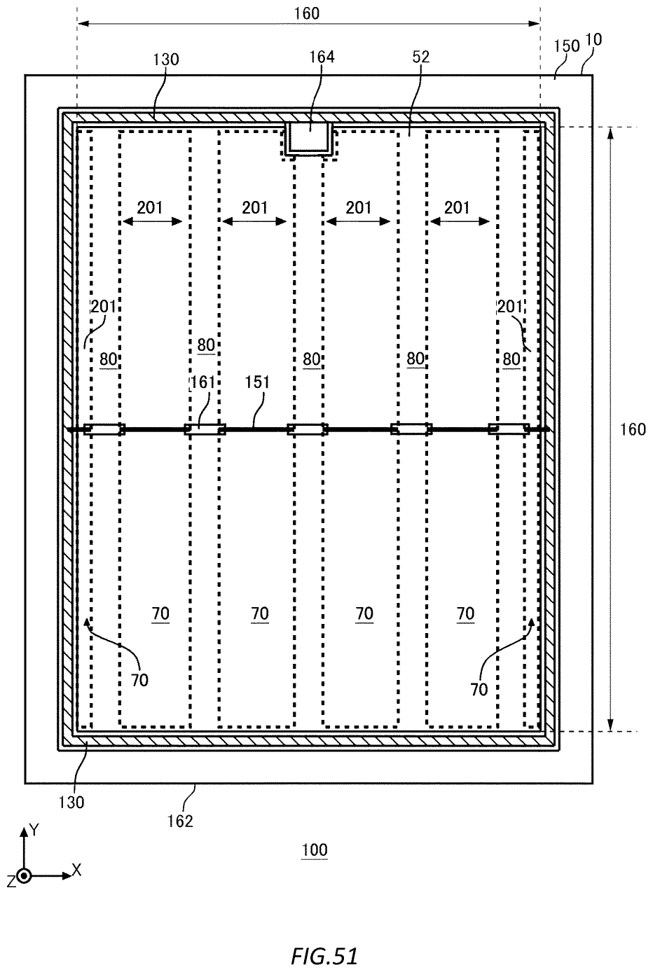

FIG. 51 is a view illustrating another structure example of the region where the trench bottom region 201 can be provided and the first active gate runner. In the present example, the first active gate runner includes the semiconductor gate runner 151 and the semiconductor gate runner 161. As described above, the ground well region 11 is provided below the semiconductor gate runner 161. The trench bottom region 201 is provided in a region overlapping the semiconductor gate runner 151 in the Y axis direction, and is not provided in a region overlapping the semiconductor gate runner 161 in the Y axis direction. The semiconductor gate runner 161 may be provided at a position opposing the diode portion 80 in the Y axis direction. The semiconductor gate runner 151 may be provided at a position opposing the transistor portion 70 in the Y axis direction. In another example, the semiconductor gate runner 151 may be provided to cross the active portion 160 in the X axis direction without providing the semiconductor gate runner 161.

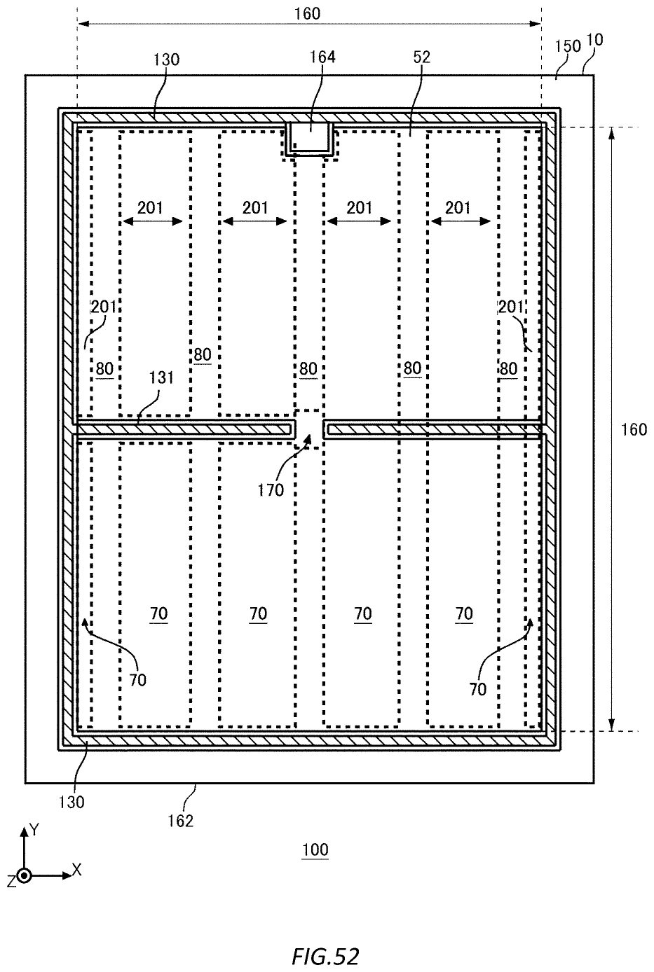

FIG. 52 is a view illustrating another structure example of the region where the trench bottom region 201 can be provided and the first active gate runner. The ground well region 11 is provided below the first metal gate runner 131 of the present example, and the ground well region 11 is not provided in the spacing portion 170. The trench bottom regions 201 of the transistor portions 70 are not connected to each other across the first metal gate runner 131. The trench bottom regions 201 of the transistor portions 70 are connected to each other in a region in contact with the end portion of the diode portion 80 in the Y axis direction, and the trench bottom regions 201 on both sides of the first active gate runner are connected at the spacing portion 170. The collector region 22 may be formed on the lower surface side of the region which is in contact with the end portion of the diode portion 80 and continuous to the trench bottom region 201, to be an invalid region (that is, a region which does not function as the diode portion 80). The region which is in contact with the end portion of the diode portion 80 and continuous to the trench bottom region 201 may be in the vicinity of the first active gate runner, may be in the vicinity of the outer circumferential gate runner, or may be arranged so as to cross the central portion of the diode portion 80. The semiconductor gate runner 151 may be arranged in the first metal gate runner 131 and the spacing portion 170.

In each example of FIGS. 46 to 52, the trench wiring 141 may be provided instead of the semiconductor gate runner 151. In each example of FIGS. 46 to 52, the ground well region 11 may be provided below the first active gate runner in a range not in contact with the trench bottom region 201.

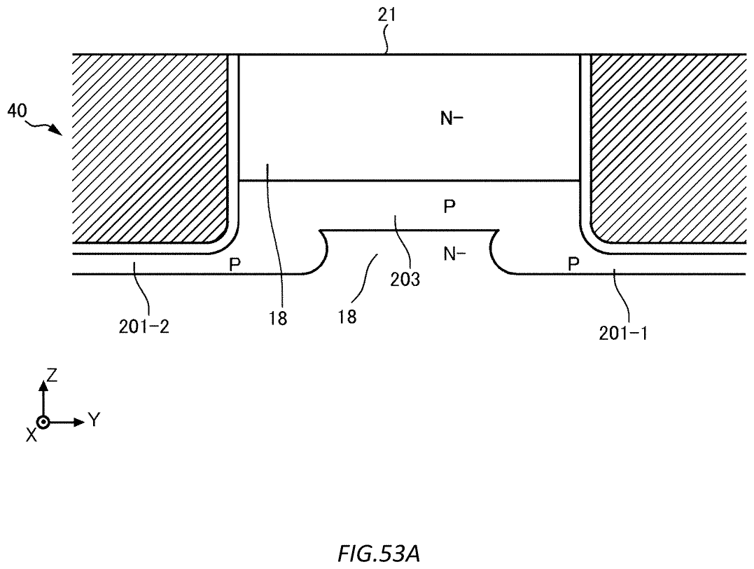

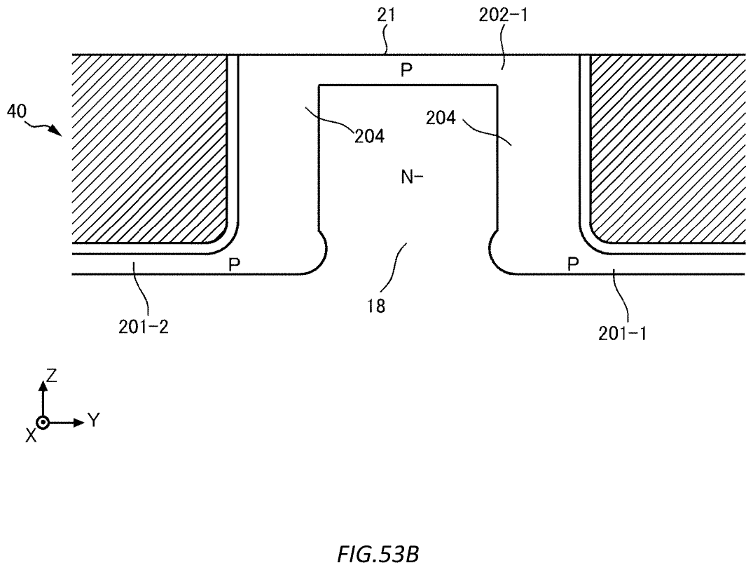

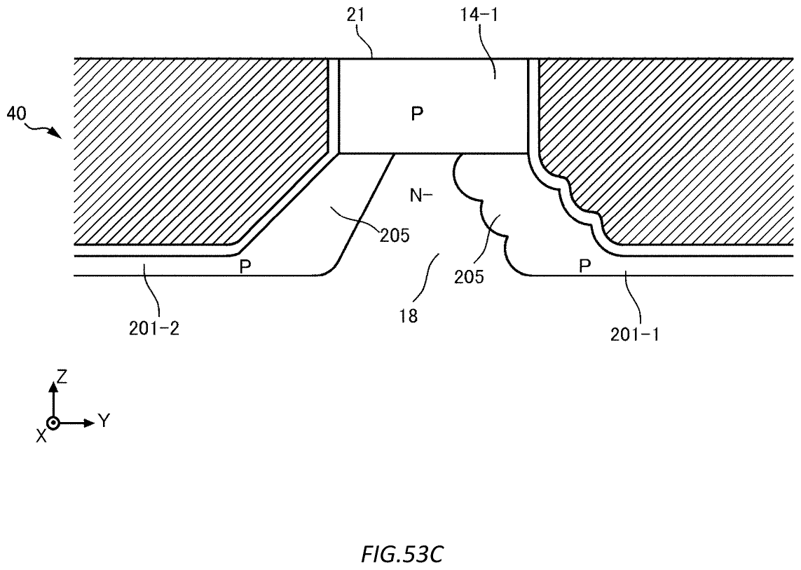

FIGS. 53A, 53B, and 53C are other connection examples of the trench bottom region 201. In FIGS. 53A, 53B, and 53C, description will be given using an example of a cross-sectional view of a YZ plane of two trench portions extending in a Y direction. In FIGS. 53A, 53B, and 53C, description of a structure above the upper surface 21 of the semiconductor substrate 10 and a structure below the trench bottom region 201 is omitted. In FIG. 53A, each trench bottom region 201 is connected by an impurity region 203 of a same conductivity type (the P type in the present example) formed by an ion implantation step different from that of the trench bottom region 201.

The impurity region 203 is not connected to the base region 14 and is electrically floating. A region of the N type such as the drift region 18 may be arranged on the impurity region 203. The drift region 18 may be provided below the impurity region 203 and the trench bottom region 201.

In FIG. 53B, each trench bottom region 201 is connected to an impurity region 204 of the same conductivity type via an electrically floating region of the same conductivity type provided in the upper surface 21 of the semiconductor substrate 10. The impurity region 204 may be formed by an ion implantation step different from the trench bottom region 201.

The impurity region 204 may be formed by performing ion implantation obliquely to a side wall of the trench portion. In another example, the impurity region 204 may be formed by varying implantation energy and implanting dopant ions into the semiconductor substrate 10 multiple times. That is, the impurity region 204 may be formed by implanting dopant ions into a plurality of depth positions. The floating region formed in the upper surface 21 may be, for example, the surface region 202-1 formed by ion implantation into the upper surface 21 at a same time when the trench bottom region 201 is formed. Alternatively, the floating region formed in the upper surface 21 may be the base region 14-1 or the like. The base region 14-1 or the surface region 202-1 are separated from the base region 14 or the like by the trench portion or the drift region 18, and are electrically floating.

In FIG. 53C, a part having different depths, such as a tapered portion or a multistage portion, is formed on each end surface of two trench portions opposing each other in the Y axis direction. The trench bottom region 201 is formed by ion implantation via the trench portion before filling the conductive portion. By the ion implantation, the trench bottom region 201 is formed, and at the same time, an impurity region 205 which becomes gradually shallower is formed along each end surface. With this configuration, the trench bottom region 201 is connected via the impurity region 205 to the electrically floating region formed in the upper surface 21, for example, the base region 14-1 or the surface region 202-1. The electrically floating region formed in the upper surface 21 may be formed up to a vicinity of a part having a depth different from that of the trench portion, or may be formed up to a region below the part having a depth different from that of the trench portion. As described above, it is also possible to connect the trench bottom regions 201-1 and 201-2 regardless of whether the trench bottom region 201-3 or the floating well region 111 is provided below the first active gate runner.

In the above description, the trench bottom region 201 has been described as a region of the P type, but may be a region of the N type having a higher concentration than the drift region. Even in this case, the trench bottom regions 201 of respective portions may be connected as described above within a range without inconsistency. For example, since the trench bottom region 201 has a same conductivity type as that of the drift region 18, the trench bottom regions 201 does not become electrically floating. In addition, it is not possible to connect each portion via the floating well region 111 or the ground well region 11. Since the electric field at the lower end of the trench becomes strong, attention is required to be paid to the breakdown voltage. By paying attention to the above, a structure connecting each portion can be achieved even in a case of the trench bottom region 201 having the same conductivity type as that of the drift region 18.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such changes or improvements are made may be included in the technical scope of the present invention.

It should be noted that each process of the operations, procedures, steps, stages, and the like performed by the device, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

Following contents are also disclosed in the present specification.

### (Item 1)

A semiconductor device which is provided in a semiconductor substrate having an upper surface and a lower surface and includes one or more transistor portions and one or more diode portions, including:
an emitter electrode which is provided above the upper surface of the semiconductor substrate;
a gate pad which is provided above the upper surface of the semiconductor substrate;
a first active gate runner which is provided above the upper surface of the semiconductor substrate so as to be sandwiched between emitter electrodes equivalent to the emitter electrode and extend in a first direction, and is connected to the gate pad; and
one or more trench portions which are provided in each of the transistor portions and the diode portions, formed from the upper surface of the semiconductor substrate to an inside of the semiconductor substrate, and provided to extend in a second direction intersecting the first direction at the upper surface of the semiconductor substrate, in which
the first active gate runner includes two or more separation parts arranged with at least one spacing portion sandwiched therebetween in the first direction,
the emitter electrode includes a bridge portion arranged in the spacing portion, and
at least one of the trench portions provided in the diode portions extends below the bridge portion.

### (Item 2)

The semiconductor device according to item 1, in which
two diode portions equivalent to the diode portions are arranged with the spacing portion sandwiched therebetween in the second direction, and
at least one trench portion, equivalent to the trench portions, provided in one of the two diode portions passes below the bridge portion and is connected to a trench portion, equivalent to the trench portions, of another of the two diode portions.

### (Item 3)

The semiconductor device according to item 2, in which
a plurality of the trench portions are arranged at intervals in the first direction,
a mesa portion is provided between two of the trench portions,
an anode region of a first conductivity type is provided in the mesa portion of the diode portion,
the mesa portion is also provided below the bridge portion, and
the anode region is also provided in the mesa portion below the bridge portion.

### (Item 4)

The semiconductor device according to item 3, further including
an interlayer dielectric film which is provided between the upper surface of the semiconductor substrate and the emitter electrode, in which
a contact hole connecting the mesa portion and the emitter electrode is provided in the interlayer dielectric film below the bridge portion.

### (Item 5)

The semiconductor device according to any one of items 1 to 4, in which
a wiring electrically connected to the gate pad is not provided below the bridge portion.

### (Item 6)

The semiconductor device according to any one of items 1 to 4, further including
a second active gate runner of metal which is provided above the upper surface of the semiconductor substrate so as to be sandwiched between emitter electrodes equivalent to the emitter electrode and extend in a second direction, and is connected to the gate pad, in which
the second active gate runner is connected to the first active gate runner.

### (Item 7)

The semiconductor device according to item 6, further including
a temperature sense portion which is provided above the upper surface of the semiconductor substrate; and
a temperature sense wiring which is provided above the upper surface of the semiconductor substrate so as to be sandwiched between emitter electrodes equivalent to the emitter electrode and extend in the second direction, and is connected to the temperature sense portion, in which
at least a part of the second active gate runner is provided between the temperature sense wiring and the emitter electrode.

### (Item 8)

The semiconductor device according to item 6, further including
an outer circumferential gate runner of metal which is arranged outside the emitter electrode above the upper surface of the semiconductor substrate and connected to the gate pad, in which
any part of the first active gate runner is connected to the outer circumferential gate runner or the second active gate runner.

### (Item 9)

The semiconductor device according to item 1, in which
the first active gate runner includes
one or more trench wirings which are formed from the upper surface of the semiconductor substrate to an inside of the semiconductor substrate and provided to extend in parallel with each other in the first direction, and
a metal gate runner which overlaps the trench wirings, and
a number of at least one trench wiring, equivalent to the trench wirings, in parallel in a first trench wiring region not overlapping the metal gate runner is larger than a number of at least one trench wiring, equivalent to the trench wirings, in parallel in a second trench wiring region overlapping the metal gate runner.

### (Item 10)

The semiconductor device according to item 1, in which
a drift region of a first conductivity type is provided in the semiconductor substrate,
the semiconductor device further comprises a trench bottom region which is provided for at least one trench portion equivalent to the trench portions, is in contact with a lower end of the trench portion, and is of the first conductivity type and has a doping concentration different from that of the drift region, and
two trench bottom regions, equivalent to the trench bottom region, which sandwich the first active gate runner in the second direction are connected in a region of a same conductivity type as that of the trench bottom region in a region where the first active gate runner is provided.

### (Item 11)

A semiconductor device which is provided in a semiconductor substrate having an upper surface and a lower surface and includes one or more transistor portions and one or more diode portions, including:
an emitter electrode which is provided above the upper surface of the semiconductor substrate;
a gate pad which is provided above the upper surface of the semiconductor substrate; and
a first active gate runner which is provided to extend in a first direction in top view and connected to the gate pad, in which
the first active gate runner includes
one or more trench wirings which are formed from the upper surface of the semiconductor substrate to an inside of the semiconductor substrate and provided to extend in parallel with each other in the first direction, and
a metal gate runner which overlaps the trench wirings, and
a number of at least one trench wiring, equivalent to the trench wirings, in parallel in a first trench wiring region not overlapping the metal gate runner is larger than a number of at least one trench wiring, equivalent to the trench wirings, in parallel in a second trench wiring region overlapping the metal gate runner.

### (Item 12)

The semiconductor device according to item 11, further including
an outer circumferential gate runner which is arranged outside the emitter electrode above the upper surface of the semiconductor substrate and connected to the gate pad, in which
the metal gate runner includes two or more separation parts arranged with one or more spacing portions sandwiched therebetween in the first direction, and
at least a part of the trench wirings is provided continuously from the outer circumferential gate runner over a region including at least one of the spacing portions and at least two of the separation parts.

### (Item 13)

The semiconductor device according to item 11 or 12, in which
at least one of the trench wirings in the first trench wiring region is connected to any one of the trench wirings in the second trench wiring region.

### (Item 14)

A semiconductor device which is provided in a semiconductor substrate having an upper surface and a lower surface and having a drift region of a first conductivity type and includes an active portion including a transistor portion or a diode portion, including:
a gate pad which is provided above the upper surface of the semiconductor substrate;
a first active gate runner which is provided to extend in a first direction in the active portion and electrically connected to the gate pad;
one or more trench portions which are provided in each of the transistor portion and the diode portion, formed from the upper surface of the semiconductor substrate to an inside of the semiconductor substrate, and provided to extend in a second direction intersecting the first direction at the upper surface of the semiconductor substrate; and
a trench bottom region which is provided for at least one trench portion equivalent to the trench portions, is in contact with a lower end of the trench portion, and is of the first conductivity type and has a doping concentration different from that of the drift region, in which
two trench bottom regions, equivalent to the trench bottom region, which sandwich the first active gate runner in the second direction are connected in a region of a same conductivity type as that of the trench bottom region in a region where the first active gate runner is provided.

### (Item 15)

The semiconductor device according to item 14, in which
the first active gate runner is provided above the upper surface of the semiconductor substrate,
the trench portions include a gate trench portion which is electrically connected to the gate pad and a dummy trench portion to which a potential different from that of the gate trench portion is applied,
two active portions equivalent to the active portion are arranged with the first active gate runner sandwiched therebetween in the second direction,
at least one gate trench portion, equivalent to the gate trench portion, provided in one active portion of the two active portions sandwiching the first active gate runner passes below the first active gate runner and is connected to the gate trench portion of another active portion of the two active portions, and
the trench bottom region is provided in the gate trench portion passing below the first active gate runner.

### (Item 16)

The semiconductor device according to item 14, in which
the first active gate runner is provided above the upper surface of the semiconductor substrate,
the trench portions include a gate trench portion which is electrically connected to the gate pad and a dummy trench portion to which a potential different from that of the gate trench portion is applied,
two active portions equivalent to the active portion are arranged with the first active gate runner sandwiched therebetween in the second direction,
at least one gate trench portion, equivalent to the gate trench portion, provided in one active portion of the two active portions sandwiching the first active gate runner is separated from the gate trench portion of another active portion of the two active portions, and
the trench bottom region is also provided in a region between the two gate trench portions having been separated.

### (Item 17)

The semiconductor device according to item 15 or 16, in which
the dummy trench portion provided in the one active portion sandwiching the first active gate runner is separated from the dummy trench portion of the another active portion.

### (Item 18)

The semiconductor device according to item 17, in which
an electric field relaxation trench portion is provided between the dummy trench portion of the one active portion sandwiching the first active gate runner and the dummy trench portion of the another active portion, and
the trench bottom region is provided in the electric field relaxation trench portion.

### (Item 19)

The semiconductor device according to item 18, in which
an entirety of the electric field relaxation trench portion overlaps the first active gate runner.

### (Item 20)

The semiconductor device according to item 18, in which
the electric field relaxation trench portion has a part extending in the second direction.

### (Item 21)

The semiconductor device according to item 20, in which
the electric field relaxation trench portion extends to an outside of the first active gate runner in the second direction.

### (Item 22)

The semiconductor device according to item 17, in which
the dummy trench portion of the one active portion sandwiching the first active gate runner and the dummy trench portion of the another active portion do not overlap the first active gate runner.

### (Item 23)

The semiconductor device according to item 16, in which
the trench bottom region is provided for at least one of dummy trench portions equivalent to the dummy trench portion,
the trench bottom region is not provided for at least one of the dummy trench portions, and
the dummy trench portion in which the trench bottom region is provided extends to a vicinity of the first active gate runner in top view compared to the dummy trench portion in which the trench bottom region is not provided.

### (Item 24)

The semiconductor device according to item 16, in which
a well region of a same conductivity type as that of the trench bottom region is not provided in a region overlapping the first active gate runner, the well region being exposed on the upper surface of the semiconductor substrate and formed to a depth greater than that of the trench portion, and
two trench bottom regions, equivalent to the trench bottom region, which sandwich the first active gate runner in the second direction are connected to each other below the first active gate runner.

### (Item 25)

The semiconductor device according to item 16, in which
a floating well region of a same conductivity type as that of the trench bottom region is provided in a region overlapping the first active gate runner, the floating well region being provided in a depth range different from that of the trench bottom region, and
two trench bottom regions, equivalent to the trench bottom region, which sandwich the first active gate runner in the second direction are connected via the floating well region.

### (Item 26)

The semiconductor device according to item 25, further including
a ground well region of a second conductivity type which is provided to surround the active portion in top view, in which
the floating well region is provided in a same depth range as that of the ground well region.

### (Item 27)

The semiconductor device according to item 16, in which
a floating well region which has a doping concentration different from that of the trench bottom region and is of a same conductivity type as that of the trench bottom region is provided in a region overlapping the first active gate runner,
two trench bottom regions, equivalent to the trench bottom region, which sandwich the first active gate runner in the second direction are connected via the floating well region.

### (Item 28)

The semiconductor device according to item 27, further including
a ground well region of a second conductivity type which is provided to surround the active portion in top view, in which
the floating well region has a same doping concentration as that of the ground well region.

### (Item 29)

The semiconductor device according to item 25, in which
the transistor portion has a base region of a second conductivity type between the drift region and the upper surface of the semiconductor substrate, and
the floating well region is separated from the base region.

### (Item 30)

The semiconductor device according to item 25, in which
a plurality of floating well regions equivalent to the floating well region are discretely arranged along the first active gate runner in the first direction.

### (Item 31)

The semiconductor device according to item 16, in which
the trench bottom region is provided at end portions, on a side of the first active gate runner, of two trench portions, equivalent to the trench portions, arranged on both sides of the first active gate runner, and the two trench bottom regions are connected in a region of a same conductivity type as that of the trench bottom region below the first active gate runner, and
at least a part of the two trench portions in the second direction is not provided with the trench bottom region.

### (Item 32)

The semiconductor device according to item 31, in which
the two trench portions each are the dummy trench portion.

### (Item 33)

The semiconductor device according to item 31, in which
the trench bottom region of the two trench portions is connected to the trench bottom region of the trench portion adjacent in the first direction.

### (Item 34)

The semiconductor device according to item 31, in which
the trench bottom region of the two trench portions is connected to an emitter potential.

### (Item 35)

The semiconductor device according to item 34, further including
a ground well region of a second conductivity type which is provided to surround the active portion in top view, in which
the trench bottom region of the two trench portions is connected to the ground well region.

### (Item 36)

The semiconductor device according to item 14, in which
the first active gate runner includes a trench wiring provided from the upper surface of the semiconductor substrate to an inside of the semiconductor substrate.

What is claimed is:

1. A semiconductor device which is provided in a semiconductor substrate having an upper surface and a lower surface and includes one or more transistor portions and one or more diode portions, comprising:
an emitter electrode which is provided above the upper surface of the semiconductor substrate;
a gate pad which is provided above the upper surface of the semiconductor substrate;
a first active gate runner which is provided above the upper surface of the semiconductor substrate so as to be sandwiched between emitter electrodes equivalent to the emitter electrode and extend in a first direction, and is connected to the gate pad; and
one or more trench portions which are provided in each of the transistor portions and the diode portions, formed from the upper surface of the semiconductor substrate to an inside of the semiconductor substrate, and provided to extend in a second direction intersecting the first direction at the upper surface of the semiconductor substrate, wherein
the first active gate runner includes two or more separation parts arranged with at least one spacing portion sandwiched therebetween in the first direction,
the emitter electrode includes a bridge portion arranged in the spacing portion, and
at least one of the trench portions provided in the diode portions extends below the bridge portion.

2. The semiconductor device according to claim 1, wherein
two diode portions equivalent to the diode portions are arranged with the spacing portion sandwiched therebetween in the second direction, and
at least one trench portion, equivalent to the trench portions, provided in one of the two diode portions passes below the bridge portion and is connected to a trench portion, equivalent to the trench portions, of another of the two diode portions.

3. The semiconductor device according to claim 2, wherein
a plurality of the trench portions are arranged at intervals in the first direction,
a mesa portion is provided between two of the trench portions,
an anode region of a first conductivity type is provided in the mesa portion of the diode portion,
the mesa portion is also provided below the bridge portion, and
the anode region is also provided in the mesa portion below the bridge portion.

4. The semiconductor device according to claim 3, further comprising:
an interlayer dielectric film which is provided between the upper surface of the semiconductor substrate and the emitter electrode, wherein
a contact hole connecting the mesa portion and the emitter electrode is provided in the interlayer dielectric film below the bridge portion.

5. The semiconductor device according to claim 1, wherein
a wiring electrically connected to the gate pad is not provided below the bridge portion.

6. The semiconductor device according to claim 1, further comprising:
a second active gate runner of metal which is provided above the upper surface of the semiconductor substrate so as to be sandwiched between emitter electrodes equivalent to the emitter electrode and extend in a second direction, and is connected to the gate pad, wherein
the second active gate runner is connected to the first active gate runner.

7. The semiconductor device according to claim 1, wherein
the first active gate runner includes
one or more trench wirings which are formed from the upper surface of the semiconductor substrate to an inside of the semiconductor substrate and provided to extend in parallel with each other in the first direction, and
a metal gate runner which overlaps the trench wirings, and
a number of at least one trench wiring, equivalent to the trench wirings, in parallel in a first trench wiring region not overlapping the metal gate runner is larger than a number of at least one trench wiring, equivalent to the trench wirings, in parallel in a second trench wiring region overlapping the metal gate runner.

8. The semiconductor device according to claim 1, wherein
a drift region of a first conductivity type is provided in the semiconductor substrate,
the semiconductor device further comprises a trench bottom region which is provided for at least one trench portion equivalent to the trench portions, is in contact with a lower end of the trench portion, and is of the first conductivity type and has a doping concentration different from that of the drift region, and
two trench bottom regions, equivalent to the trench bottom region, which sandwich the first active gate runner in the second direction are connected in a region of a same conductivity type as that of the trench bottom region in a region where the first active gate runner is provided.

9. A semiconductor device which is provided in a semiconductor substrate having an upper surface and a lower surface and includes one or more transistor portions and one or more diode portions, comprising:
an emitter electrode which is provided above the upper surface of the semiconductor substrate;
a gate pad which is provided above the upper surface of the semiconductor substrate; and
a first active gate runner which is provided to extend in a first direction in top view and connected to the gate pad, wherein
the first active gate runner includes
one or more trench wirings which are formed from the upper surface of the semiconductor substrate to an inside of the semiconductor substrate and provided to extend in parallel with each other in the first direction, and
a metal gate runner which overlaps the trench wirings, and
a number of at least one trench wiring, equivalent to the trench wirings, in parallel in a first trench wiring region not overlapping the metal gate runner is larger than a number of at least one trench wiring, equivalent to the trench wirings, in parallel in a second trench wiring region overlapping the metal gate runner.

10. The semiconductor device according to claim 9, further comprising:
an outer circumferential gate runner which is arranged outside the emitter electrode above the upper surface of the semiconductor substrate and connected to the gate pad, wherein
the metal gate runner includes two or more separation parts arranged with one or more spacing portions sandwiched therebetween in the first direction, and
at least a part of the trench wirings is provided continuously from the outer circumferential gate runner over a region including at least one of the spacing portions and at least two of the separation parts.

11. The semiconductor device according to claim 9, wherein
at least one of the trench wirings in the first trench wiring region is connected to any one of the trench wirings in the second trench wiring region.

12. A semiconductor device which is provided in a semiconductor substrate having an upper surface and a lower surface and having a drift region of a first conductivity type and includes an active portion including a transistor portion or a diode portion, comprising:
a gate pad which is provided above the upper surface of the semiconductor substrate;
a first active gate runner which is provided to extend in a first direction in the active portion and electrically connected to the gate pad;
one or more trench portions which are provided in each of the transistor portion and the diode portion, formed from the upper surface of the semiconductor substrate to an inside of the semiconductor substrate, and provided to extend in a second direction intersecting the first direction at the upper surface of the semiconductor substrate; and
a trench bottom region which is provided for at least one trench portion equivalent to the trench portions, is in contact with a lower end of the trench portion, and is of the first conductivity type and has a doping concentration different from that of the drift region, wherein
two trench bottom regions, equivalent to the trench bottom region, which sandwich the first active gate runner in the second direction are connected in a region of a same conductivity type as that of the trench bottom region in a region where the first active gate runner is provided.

13. The semiconductor device according to claim 12, wherein
the first active gate runner is provided above the upper surface of the semiconductor substrate,
the trench portions include a gate trench portion which is electrically connected to the gate pad and a dummy trench portion to which a potential different from that of the gate trench portion is applied,
two active portions equivalent to the active portion are arranged with the first active gate runner sandwiched therebetween in the second direction,
at least one gate trench portion, equivalent to the gate trench portion, provided in one active portion of the two active portions sandwiching the first active gate runner passes below the first active gate runner and is connected to the gate trench portion of another active portion of the two active portions, and
the trench bottom region is provided in the gate trench portion passing below the first active gate runner.

14. The semiconductor device according to claim 12, wherein
the first active gate runner is provided above the upper surface of the semiconductor substrate,
the trench portions include a gate trench portion which is electrically connected to the gate pad and a dummy trench portion to which a potential different from that of the gate trench portion is applied,
two active portions equivalent to the active portion are arranged with the first active gate runner sandwiched therebetween in the second direction,
at least one gate trench portion, equivalent to the gate trench portion, provided in one active portion of the two active portions sandwiching the first active gate runner is separated from the gate trench portion of another active portion of the two active portions, and
the trench bottom region is also provided in a region between the two gate trench portions having been separated.

15. The semiconductor device according to claim 13, wherein
the dummy trench portion provided in the one active portion sandwiching the first active gate runner is separated from the dummy trench portion of the another active portion.

16. The semiconductor device according to claim 15, wherein
an electric field relaxation trench portion is provided between the dummy trench portion of the one active portion sandwiching the first active gate runner and the dummy trench portion of the another active portion, and
the trench bottom region is provided in the electric field relaxation trench portion.

17. The semiconductor device according to claim 14, wherein
the trench bottom region is provided for at least one of dummy trench portions equivalent to the dummy trench portion,
the trench bottom region is not provided for at least one of the dummy trench portions, and
the dummy trench portion in which the trench bottom region is provided extends to a vicinity of the first active gate runner in top view compared to the dummy trench portion in which the trench bottom region is not provided.

18. The semiconductor device according to claim 14, wherein
a well region of a same conductivity type as that of the trench bottom region is not provided in a region overlapping the first active gate runner, the well region being exposed on the upper surface of the semiconductor substrate and formed to a depth greater than that of the trench portion, and
two trench bottom regions, equivalent to the trench bottom region, which sandwich the first active gate runner in the second direction are connected to each other below the first active gate runner.

19. The semiconductor device according to claim 14, wherein
a floating well region of a same conductivity type as that of the trench bottom region is provided in a region overlapping the first active gate runner, the floating well region being provided in a depth range different from that of the trench bottom region, and
two trench bottom regions, equivalent to the trench bottom region, which sandwich the first active gate runner in the second direction are connected via the floating well region.

20. The semiconductor device according to claim 12, wherein
the first active gate runner includes a trench wiring provided from the upper surface of the semiconductor substrate to an inside of the semiconductor substrate.
